(19) United States
(12) Patent Application Publication
(10) Pub. No.: US 2021/0155803 A1
(43) Pub. Date: May 27, 2021

(54) COLORING COMPOSITION, CURED FILM, METHOD FOR FORMING PATTERN, COLOR FILTER, SOLID-STATE IMAGING ELEMENT, AND IMAGE DISPLAY DEVICE

(71) Applicant: FUJIFILM Corporation, Tokyo (JP)

(72) Inventors: Hiromu KOIZUMI, Haibara-gun (JP); Kazuya OOTA, Haibara-gun (JP); Akio MIZUNO, Haibara-gun (JP); Takahiro OKAWARA, Haibara-gun (JP); Haruki INABE, Haibara-gun (JP)

(73) Assignee: FUJIFILM Corporation, Tokyo (JP)

(21) Appl. No.: 17/164,110

(22) Filed: Feb. 1, 2021

Related U.S. Application Data
(63) Continuation of application No. PCT/JP2019/032093, filed on Aug. 16, 2019.

(30) Foreign Application Priority Data
Aug. 22, 2018 (JP) 2018-155312
Sep. 6, 2018 (JP) 2018-166681
Jun. 6, 2019 (JP) 2019-105818
Jul. 19, 2019 (JP) 2019-133611

(51) Int. Cl. C09B 57/00; G03F 7/00; G03F 7/027; G03F 7/105; G02B 5/22; C09B 45/22; C09B 57/04

(52) U.S. Cl. CPC C09B 57/004; G03F 7/0007; G03F 7/027; C09B 57/04; G02B 5/223; C09B 45/22; G03F 7/105

(57) ABSTRACT

Provided are a coloring composition including a pigment A having a structure in which an aromatic ring group in which an electron-donating group is introduced into an aromatic ring is bonded to a diketopyrrolopyrrole skeleton, and a compound having a curable group, in which a content of the pigment A in a total solid content of the coloring composition is 35 mass % or more; a cured film formed of the coloring composition; a method for forming a pattern; a color filter; a solid-state imaging element; and an image display device.

### CROSS-REFERENCE TO RELATED APPLICATIONS

This application is a Continuation of PCT International Application No. PCT/JP2019/032093 filed on Aug. 16, 2019, which claims priority under 35 U.S.C § 119(a) to Japanese Patent Application No. 2018-155312 filed on Aug. 22, 2018, Japanese Patent Application No. 2018-166681 filed on Sep. 6, 2018, Japanese Patent Application No. 2019-105818 filed on Jun. 6, 2019, and Japanese Patent Application No. 2019-133611 filed on Jul. 19, 2019. Each of the above application(s) is hereby expressly incorporated by reference, in its entirety, into the present application.

### BACKGROUND OF THE INVENTION

### 1. Field of the Invention

The present invention relates to a coloring composition including a diketopyrrolopyrrole pigment. The present invention further relates to a cured film formed of the coloring composition, a method for forming a pattern, a color filter, a solid-state imaging element, and an image display device.

### 2. Description of the Related Art

As a digital camera, a mobile phone with a camera, and the like have been further spreading, there has been a greatly increasing demand for a solid-state imaging element such as a charge coupled device (CCD) image sensor. As a key device of a display or an optical element, a color filter has been used. The color filter normally includes pixels (colored patterns) of three primary colors of red, green, and blue, and acts to separate transmitted light into the three primary colors. The color filter is formed using a coloring composition including a coloring material such as a pigment. In addition, in a coloring composition for forming a red pixel, a diketopyrrolopyrrole pigment or the like is used as a coloring material (for example, JP2016-065115A, WO2016/103994A, and the like).

### SUMMARY OF THE INVENTION

In recent years, there has been an increase in requirement for a cured film used in the color filter and the like. As one of such required characteristics, further improvement in moisture resistance is desired.

Accordingly, an object of the present invention is to provide a coloring composition with which a cured film having excellent moisture resistance can be formed. Another object of the present invention is to provide a cured film formed of this coloring composition, a method for forming a pattern, a color filter, a solid-state imaging element, and an image display device.

According to the intensive studies conducted by the present inventor, it has been found that the above-described objects can be achieved by the coloring composition described later, thereby leading to the completion of the present invention. Therefore, the present invention provides the following.

<1> A coloring composition comprising:

a pigment A having a structure in which an aromatic ring group in which an electron-donating group is introduced into an aromatic ring is bonded to a diketopyrrolopyrrole skeleton; and

a compound having a curable group,

in which a content of the pigment A in a total solid content of the coloring composition is 35 mass % or more.

<2> The coloring composition according to <1>,

in which the electron-donating group is at least one selected from a hydroxy group, an alkyl group, an alkoxy group, an alkylthio group, an aryloxy group, or an amino group.

<3> The coloring composition according to <1> or <2>,

in which the aromatic ring group is a group represented by Formula (AR-1),

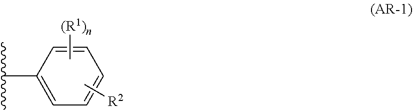

in the formula, R¹ represents a substituent,

R² represents an electron-donating group,

n represents an integer of 0 to 4, and

a wave line represents a bonding site to the diketopyrrolopyrrole skeleton.

<4> The coloring composition according to any one of <1> to <3>,

wherein the pigment A is a compound represented by Formula (1),

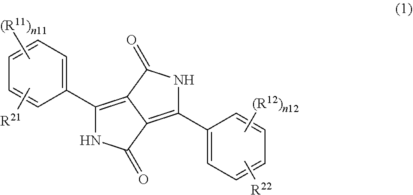

in the formula, R¹¹ and R¹² each independently represent a substituent,

R²¹ and R²² each independently represent an electron-donating group, and

n11 and n12 each independently represent an integer of 0 to 4.

<5> The coloring composition according to any one of <1> to <3>,

wherein the pigment A is a compound represented by Formula (2),

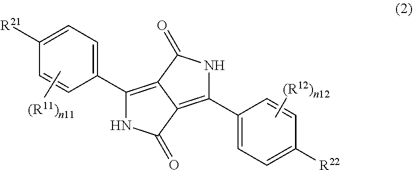

in the formula, R¹¹ and R¹² each independently represent a substituent,

R²¹ and R²² each independently represent an electron-donating group, and

n11 and n12 each independently represent an integer of 0 to 4.

<6> The coloring composition according to any one of <1> to <5>,

in which the pigment A includes Color Index Pigment Red 272.

<7> The coloring composition according to any one of <1> to <6>, further comprising:

a yellow colorant selected from an isoindoline compound, an azo compound, and a quinophthalone compound.

<8> The coloring composition according to <7>,

wherein the yellow colorant is at least one selected from Color Index Pigment Yellow 139 or Color Index Pigment Yellow 150.

<9> The coloring composition according to any one of <1> to <8>,

in which the compound having a curable group includes at least one compound selected from a compound having an ethylenically unsaturated group and a compound having an epoxy group.

<10> The coloring composition according to any one of <1> to <8>,

in which the compound having a curable group includes a resin having an ethylenically unsaturated group.

<11> The coloring composition according to any one of <1> to <10>, further comprising:

a photopolymerization initiator

in which the compound having a curable group includes a compound having an ethylenically unsaturated group.

<12> The coloring composition according to any one of <1> to <11>, further comprising:

a monomer having an ethylenically unsaturated group; and

a resin,

in which a ratio M¹/B¹ of a mass M¹ of the monomer having an ethylenically unsaturated group included in the coloring composition to a mass B¹ of the resin included in the coloring composition is 0.35 or less.

<13> The coloring composition according to any one of <1> to <12>,

in which the content of the pigment A in the total solid content of the coloring composition is 40 mass % or more.

<14> The coloring composition according to any one of <1> to <13>,

in which the coloring composition is used for a solid-state imaging element.

<15> The coloring composition according to any one of <1> to <13>,

in which the coloring composition is used for a color filter.

<16> A cured film which is formed from the coloring composition according to any one of <1> to <15>.

<17> A method for forming a pattern, comprising:

a step of forming a coloring composition layer on a support using the coloring composition according to any one of <1> to <15>; and

a step of forming a pattern on the coloring composition layer by a photolithography method or a dry etching method.

<18> A color filter comprising:

the cured film according to <16>.

<19> A solid-state imaging element comprising:

the cured film according to <16>.

<20> An image display device comprising:

the cured film according to <16>.

According to the present invention, it is possible to provide a coloring composition with which a cured film having excellent moisture resistance can be formed. It is also possible to provide a cured film formed of the coloring composition, a method for forming a pattern, a color filter, a solid-state imaging element, and an image display device.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, a weight-average molecular weight and a number-average molecular weight are values in terms of polystyrene measured by gel permeation chromatography (GPC) method.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, a total solid content denotes the total mass of all the components of the composition excluding a solvent.

In the present specification, the term “step” denotes not only an individual step but also a step which is not clearly distinguishable from another step as long as an effect expected from the step can be achieved.

A coloring composition according to an embodiment of the present invention includes a pigment A having a structure in which an aromatic ring group in which an electron-donating group is introduced into an aromatic ring is bonded to a diketopyrrolopyrrole skeleton, and a compound having a curable group, in which a content of the pigment A in a total solid content of the coloring composition is 35 mass % or more.

By using the coloring composition according to the embodiment of the present invention, a cured film having excellent moisture resistance can be formed. In addition, generally, as the pigment concentration in the film is higher, the moisture resistance tends to decrease more easily. However, the coloring composition according to the embodiment of the present invention can form a cured film having excellent moisture resistance even though the content of the pigment A in the total solid content is 35 mass % or more. The reason for obtaining such an effect is assumed as follows. In a case where a cured film formed using a coloring composition including a pigment is exposed to a high humidity environment, water or the like which has penetrated into the cured film acts as a nucleophile to nucleophilically attack the pigment, and as a result, spectral fluctuation of the pigment may occur. However, since the pigment A used in the present invention has a structure in which the above-described aromatic ring group is bonded to the diketopyrrolopyrrole skeleton, and it is assumed that the electron density of the diketopyrrolopyrrole skeleton which is the mother nucleus of the pigment A is high, it is assumed that the pigment A is less susceptible to nucleophilic attack even in a case where the cured film is exposed to a high humidity environment. Therefore, it is assumed that, by using the coloring composition according to the embodiment of the present invention, a cured film having excellent moisture resistance can be formed.

In addition, since the pigment A used in the coloring composition according to the embodiment of the present invention has a higher red color value than red pigments in the related art, it is possible to form a cured film having desired spectral characteristics even a thin film. It is assumed that, since the pigment A has a structure in which the above-described aromatic ring group is bonded to the diketopyrrolopyrrole skeleton, a Highest Occupied Molecular Orbital (HOMO)-Lowest Unoccupied Molecular Orbital (LUMO) transition extends, the transition moment thus increases, and as a result, due to an increase of molar absorption coefficient F of the pigment A in a red wavelength range (for example, 450 to 600 nm), the red color value is high. In addition, since the pigment A has a higher red color value than red pigments in the related art, desired spectral diffraction can be achieved with a smaller formulation amount than a formulation amount required to achieve the same spectral characteristics as the red pigments in the related art. Thus, formulation amounts of components other than the pigment can also be increased, and the degree of freedom in formulation design is high.

In addition, in the coloring composition according to the embodiment of the present invention, in a case where a resin having an ethylenically unsaturated group is used as the compound having a curable group, it is also possible to improve heat resistance of the obtained cured film. The reason for obtaining such an effect is assumed as follows. It is assumed that, in the composition, the resin is close to the pigment A due to the interaction between the pigment A and the ethylenically unsaturated group of the resin. Therefore, it is assumed that the pigment A is present in the composition so as to be wrapped in the above-described resin. Accordingly, in a case of forming the cured film, it is assumed that the above-described resin polymerizes in the vicinity of the pigment A and the pigment A can be firmly retained in the film. Thus, it is assumed that the thermal diffusion of the pigment A due to heating can be suppressed. As a result, it is assumed that a cured film having excellent heat resistance can be formed.

The coloring composition according to the embodiment of the present invention can be preferably used as a coloring composition for a solid-state imaging element. In addition, the coloring composition according to the embodiment of the present invention can be preferably used as a coloring composition for a color filter. Specifically, the coloring composition according to the embodiment of the present invention can be preferably used as a coloring composition for forming a pixel of a color filter, and can be more preferably used as a coloring composition for forming a pixel of a color filter used in solid-state imaging elements.

Hereinafter, the respective components used in the coloring composition according to the embodiment of the present invention will be described.

<<Pigment A>>

The coloring composition according to the embodiment of the present invention contains a pigment A (hereinafter, referred to as a Pigment A) having a structure in which an aromatic ring group having an electron-donating group introduced into an aromatic ring is bonded to a diketopyrrolopyrrole skeleton. The pigment A is a pigment having a diketopyrrolopyrrole skeleton.

In organic electron theory, an electron-donating group is an atomic group which donates an electron to the substituted atomic group by an inductive effect or a resonance effect. Examples of the electron-donating group include groups having a negative value as the substituent constant (σp (para)) of Hammett's law. The substituent constant of Hammett's law can be quoted from the 5th edition of the Basics of Chemistry Handbook (page 380 of II). Specific examples of the electron-donating group is a hydroxy group, an alkyl group, an alkoxy group, an alkylthio group, an aryloxy group, or an amino group.

The number of carbon atoms in the alkyl group, alkoxy group, and alkylthio group is preferably 1 to 10 and more preferably 1 to 5. These groups may be linear, branched, or cyclic, and are preferably linear or branched.

The number of carbon atoms in the aryloxy group is preferably 6 to 20 and more preferably 6 to 10.

Examples of the amino group include a group represented by —NRa¹Ra². Ra¹ and Ra² each independently represent a hydrogen atom, an alkyl group, an aryl group, or a heterocyclic group. Ra¹ and Ra² may be bonded to each other to form a ring. The number of carbon atoms in the alkyl group represented by Ra¹ and Ra² is preferably 1 to 30, more preferably 1 to 15, and still more preferably 1 to 8. The alkyl group may be linear, branched, or cyclic, and is preferably linear or branched and more preferably linear. The number of carbon atoms in the aryl group represented by Ra¹ and Ra² is preferably 6 to 30, more preferably 6 to 20, and still more preferably 6 to 12. The heterocyclic group represented by Ra¹ and Ra² may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

As the electron-donating group, from the reason that the effects of the present invention are easily obtained more significantly, an alkyl group, an alkoxy group, or an amino group is preferable, and from the reason that, in addition to the above-described reason, it is easy to obtain spectral characteristics suitable for red, an alkyl group or an alkoxy group is more preferable and an alkyl group is particularly preferable.

The aromatic ring group is preferably a group represented by Formula (AR-1).

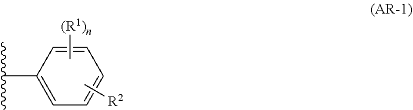

In the formula, R¹ represents a substituent, R² represents an electron-donating group, n represents an integer of 0 to 4, and a wave line represents a bonding site to the diketopyrrolopyrrole skeleton.

In Formula (AR-1), examples of the substituent represented by R¹ include groups exemplified in the substituent T described later and the above-described electron-donating groups, and the electron-donating group is preferable. In a case where n is 2 or more, n R's may be the same or different from each other.

In Formula (AR-1), examples of the electron-donating group represented by R² include the above-described groups, and the preferred range is also the same.

In Formula (AR-1), n represents an integer of 0 to 4, is preferably an integer of 0 to 3, more preferably an integer of 0 to 2, still more preferably 0 or 1, and particularly preferably 1.

In Formula (AR-1), the wave line represents a bonding site to the diketopyrrolopyrrole skeleton. The diketopyrrolopyrrole skeleton means the following structure. The wave line represents a bonding position to the substituent such as the group represented by Formula (AR-1). Examples of the substituent other than the group represented by Formula (AR-1) include an aryl group. The aryl group may have a substituent. Examples of the substituent include groups exemplified in the substituent T described later.

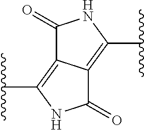 [SMILES: *C1=C2C(=O)NC(*)=C2C(=O)N1]

The pigment A is preferably a compound represented by Formula (1), and from the reason that more excellent moisture resistance can be easily obtained, more preferably a compound represented by Formula (2).

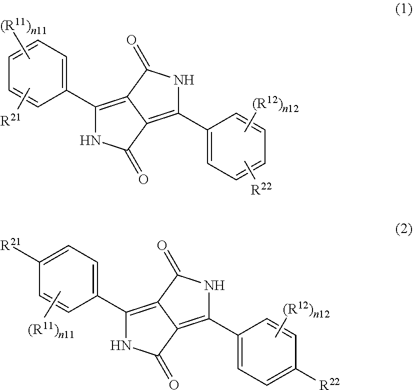

In the formulae. R¹¹ and R¹² each independently represent a substituent. R²¹ and R²² each independently represent an electron-donating group, and n11 and n12 each independently represent an integer of 0 to 4.

Examples of the substituent represented by R¹¹ and R¹² include groups exemplified in the substituent T described later and the above-described electron-donating groups, and the electron-donating group is preferable. In a case where n11 is 2 or more, n11 R¹¹'s may be the same or different from each other. In addition, in a case where n12 is 2 or more, n12 R¹²'s may be the same or different from each other.

Examples of the electron-donating group represented by R²¹ and R²² include the above-described groups, and the preferred range is also the same.

n11 and n12 each independently represent an integer of 0 to 4, and preferably an integer of 0 to 3, more preferably an integer of 0 to 2, still more preferably 0 or 1, and particularly preferably 1.

(Substituent T)

Examples of a substituent T include a halogen atom, a cyano group, a nitro group, an alkyl group, an aryl group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an aryl group, or a heterocyclic group. Rt¹ and Rt² may be bonded to each other to form a ring.

Examples of the halogen atom include a fluorine atom, a chlorine atom, a bromine atom, and an iodine atom.

The number of carbon atoms in the alkyl group is preferably 1 to 30, more preferably 1 to 15, and still more preferably 1 to 8. The alkyl group may be linear, branched, or cyclic, and is preferably linear or branched and more preferably linear.

The number of carbon atoms in the aryl group is preferably 6 to 30, more preferably 6 to 20, and still more preferably 6 to 12.

The heterocyclic group may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the aryl group, and the heterocyclic group may have a substituent or may be unsubstituted. Examples of the substituent include the substituents described in the substituent T.

Specific examples of the pigment A include compounds having the following structures. The compound having the structure represented by Formula (R1) is C. I. Pigment Red 272. It is preferable that the pigment A includes Color Index Pigment Red 272.

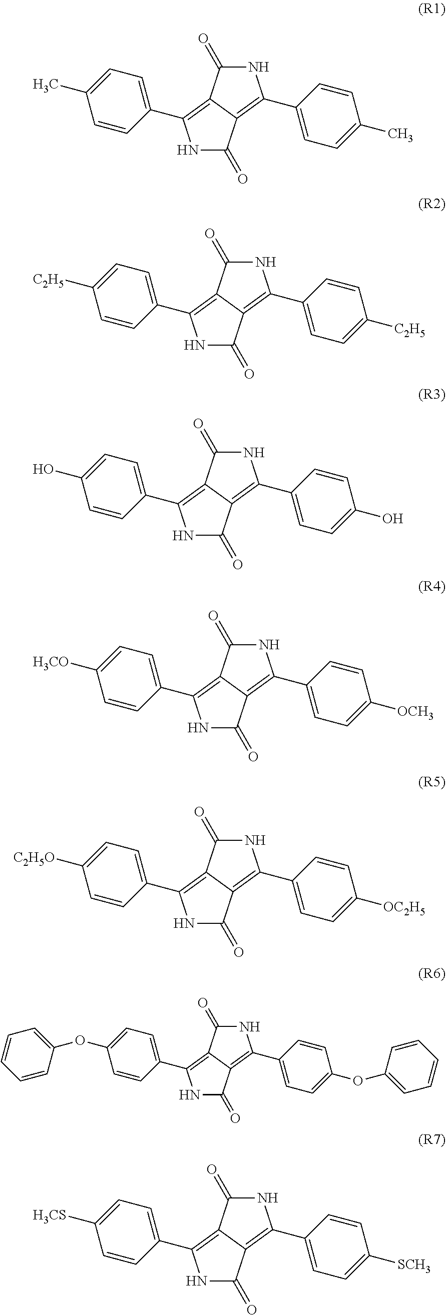

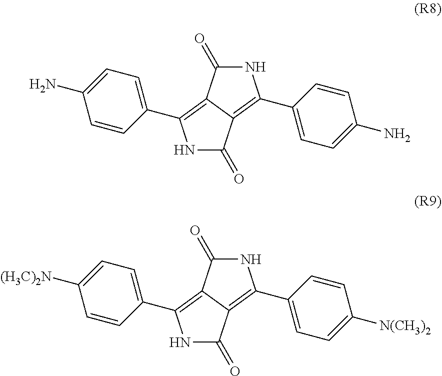

The content of the pigment A in the total solid content of the coloring composition is 35 mass % or more, preferably 40 mass % or more, more preferably 45 mass % or more, and still more preferably 50 mass % or more. The upper limit may be 80 mass % or less.

In addition, the proportion of the pigment A in the total mass of the compound having a diketopyrrolopyrrole skeleton included in the coloring composition is preferably 80 mass % or more, more preferably 90 mass % or more, and still more preferably 95 mass % or more, and it is particularly preferable that the pigment A is substantially the only compound having a diketopyrrolopyrrole skeleton included in the coloring composition. The case where the pigment A is substantially the only compound having a diketopyrrolopyrrole skeleton included in the coloring composition means that the proportion of the pigment A in the total mass of the compound having a diketopyrrolopyrrole skeleton included in the coloring composition is 99 mass % or more, preferably 99.5 mass % or more and still more preferably 99.9 mass % or more, and it is particularly preferable that the compound having a diketopyrrolopyrrole skeleton consists only of the pigment A.

In addition, the proportion of the pigment A in the total mass of colorant included in the coloring composition is preferably 60 mass % or more, more preferably 70 mass % or more, and still more preferably 80 mass % or more. The upper limit may be 90 mass % or less.

<<Other Colorants>>

The coloring composition according to the embodiment of the present invention can contain a colorant (hereinafter, also referred to as other colorants) other than the pigment A. The other colorants may be either a pigment or a dye. The pigment and the dye may be used in combination. The other colorants used in the present invention preferably include the pigment. In addition, the pigment may be an organic pigment or an inorganic pigment. In addition, as the pigment, a material in which a part of an inorganic pigment or an organic-inorganic pigment is replaced with an organic chromophore can also be used. By substituting an inorganic pigment or an organic-inorganic pigment with an organic chromophore, color tone design can be easily performed.

The content of the pigment in the other colorants is preferably 50 mass % or more, more preferably 70 mass % or more, still more preferably 80 mass % or more, and particularly preferably 90 mass % or more. In addition, the other colorants may be only constituted with the pigment.

The coloring composition according to the embodiment of the present invention preferably includes a yellow colorant as the other colorants, and more preferably includes a yellow pigment. According to this aspect, it is easy to form a cured film having spectral characteristics suitable for a red pixel. In addition, in a case where a yellow pigment is used as the other colorants, dispersibility of the pigment A can also be improved.

Examples of the yellow colorant include an azo compound, a quinophthalone compound, an isoindolinone compound, an isoindoline compound, and an anthraquinone compound. Among these, an isoindoline compound, an azo compound, or a quinophthalone compound is preferable, an isoindoline compound or an azo compound is more preferable, and from the reason that it is easy to form a cured film having spectral characteristics more suitable for red, an isoindoline compound is particularly preferable.

Examples of the yellow colorant include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine/polymethine-based), 233 (quinoline-based), 234 (aminoketone-based), 235 (aminoketone-based), 236 (aminoketone-based) (all of which are yellow pigments).

In addition, as the yellow colorant, pigments described in JP2017-201003A and pigments described in JP2017-197719A can be used. In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can also be used.

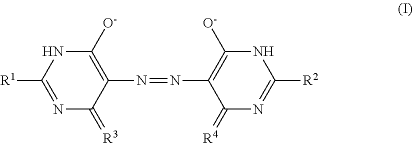

In the formula, R¹ and R² each independently represent —OH or —NR⁵R⁶, R³ and R⁴ each independently represent ═O or ═NR⁷, and R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

With regard to the metal azo pigment, reference can be made to the description in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915A, the contents of which are incorporated herein by reference.

In addition, as the yellow colorant, quinophthalone compounds described in paragraphs “0011” to “0034” of JP2013-054339A, or quinophthalone compounds described in paragraphs “0013” to “0058” of JP2014-026228A can also be used. In addition, as the yellow colorant, compounds described in JP2018-062644A can also be used. These compounds can also be used as a pigment derivative.

As the yellow colorant, one or more pigment selected from C. I. Pigment Yellow 138, C. I. Pigment Yellow 139, C. I. Pigment Yellow 150, or C. I. Pigment Yellow 185 is still more preferable, one or more pigment selected from C. I. Pigment Yellow 139 or C. I. Pigment Yellow 150 is even more preferable, and C. I. Pigment Yellow 139 is particularly preferable.

Examples of the colorant other than the yellow colorant include the following.

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments);

C. I. Pigment Blue 1, 2, 15, 15:1, 15:2, 15:3, 15:4, 15:6, 16, 22, 29, 60, 64, 66, 79, 80, 87 (monoazo-based), 88 (methine/polymethine-based), and the like (all of which are blue pigments); and

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 279, 291, 294 (xanthene-based, Organo Ultramarine, Bluish Red), 295 (monoazo-based), 296 (diazo-based), 297 (aminoketone-based), and the like (all of which are red pigments).

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green pigment, a compound described in CN2010-6909027A, a phthalocyanine compound having phosphoric acid ester as a ligand, a phthalocyanine compound described in JP2019-008014A, a phthalocyanine compound described in JP2018-180023A, a compound described in JP2019-038958A, and the like can also be used.

In addition, as the blue pigment, an aluminum phthalocyanine compound having a phosphorus atom can also be used. Specific examples thereof include compounds described in paragraphs “0022” to “0030” of JP2012-247591A and paragraph “0047” of JP2011-157478A.

In addition, as the red pigment, a red pigment described in JP6516119B, a red pigment described in JP6525101B, and the like can also be used.

As the dye, a known dye can be used without any particular limitation. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

In addition, as the other colorants, thiazole compounds described in JP2012-158649A, azo compounds described in JP2011-184493A, or azo compounds described in JP2011-145540A can also be used.

In addition, a coloring agent multimer can be used as the other colorants. The coloring agent multimer is preferably a dye which is used after being dissolved in a solvent, but the coloring agent multimer may form a particle. In a case where the coloring agent multimer is the particle, it is usually used in a state of being dispersed in a solvent. The coloring agent multimer in the particle state can be obtained by, for example, emulsion polymerization, and specific examples thereof include the compounds and production methods described in JP2015-214682A. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structures or different coloring agent structures. The weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. In addition, as the coloring agent multimer, the compounds described in JP2011-213925A, JP2013-041097A, JP2015-028144A, JP2015-030742A, and the like can also be used.

It is also preferable that C. I. Pigment Red 272 is used as the pigment A and C. I. Pigment Red 254 is used as the other colorants. In this case, the proportion of C. I. Pigment Red 254 with respect to 100 parts by mass of C. I. Pigment Red 272 is preferably 10 to 100 parts by mass, more preferably 20 to 90 parts by mass, and still more preferably 30 to 80 parts by mass.

In addition, it is also preferable that C. I. Pigment Red 272 is used as the pigment A and C. I. Pigment Red 254 and C. I. Pigment Yellow 139 are used as the other colorants. In this case, the proportion of C. I. Pigment Red 254 and C. I. Pigment Yellow 139 with respect to 100 parts by mass of C. I. Pigment Red 272 is preferably 10 to 100 parts by mass of C. I. Pigment Red 254 and 1 to 70 parts by mass of C. I. Pigment Yellow 139. The amount of C. I. Pigment Red 254 is more preferably 20 to 90 parts by mass and still more preferably 30 to 80 parts by mass. The amount of C. I. Pigment Yellow 139 is more preferably 3 to 60 parts by mass and still more preferably 5 to 50 parts by mass.

The content of the other colorants is preferably 40 parts by mass or less with respect to 100 parts by mass of the pigment A. The lower limit is preferably 1 part by mass or more, more preferably 3 parts by mass or more, and still more preferably 5 parts by mass or more. The upper limit is preferably 30 parts by mass or less and more preferably 20 parts by mass or less.

In addition, the content of the yellow colorant is preferably 40 parts by mass or less with respect to 100 parts by mass of the pigment A. The lower limit is preferably 1 part by mass or more, more preferably 3 parts by mass or more, and still more preferably 5 parts by mass or more. The upper limit is preferably 30 parts by mass or less and more preferably 20 parts by mass or less.

In addition, the total content of the pigment A and the other colorants in the total solid content of the coloring composition is preferably 40 to 90 mass %. The lower limit is preferably 45 mass % or more and more preferably 50 mass % or more. The upper limit is preferably 85 mass % or less and more preferably 80 mass % or less.

In addition, the total content of the pigment A and the yellow colorant in the total solid content of the coloring composition is preferably 40 to 90 mass %. The lower limit is preferably 45 mass % or more and more preferably 50 mass % or more. The upper limit is preferably 85 mass % or less and more preferably 80 mass % or less.

<<Compound Having Curable Group>>

The coloring composition according to the embodiment of the present invention contains a compound having a curable group. The reaction mechanism in the curing of the compound having a curable group is not particularly limited. Examples thereof include a radical polymerization reaction, a cationic polymerization reaction, a condensation polymerization reaction, a nucleophilic addition reaction, and a crosslinking reaction by a substitution reaction. The compound having a curable group is preferably a compound which is cured by a radical polymerization reaction. Examples of the curable group include an ethylenically unsaturated group and an epoxy group. Examples of the ethylenically unsaturated group include a vinyl group, a vinyloxy group, an allyl group, a methallyl group, a (meth)acryloyl group, a styrene group, a cinnamoyl group, and a maleimide group. Among these, a (meth)acryloyl group, a styrene group, or a maleimide group is preferable, a (meth)acryloyl group is more preferable, and an acryloyl group is particularly preferable.

The compound having a curable group (hereinafter, also referred to as a curable compound) may be a monomer, or a resin such as a polymer. It is also possible to use a monomer type curable compound and a resin type curable compound in combination.

(Compound having Ethylenically Unsaturated Group)

In the present invention, a compound having an ethylenically unsaturated group used as the curable compound may be a monomer or a resin. From the reason that it is easy to form a cured film having excellent heat resistance, it is preferable to include a resin type compound. Hereinafter, the compound having an ethylenically unsaturated group is also referred to as a polymerizable compound. In addition, the monomer having an ethylenically unsaturated group is also referred to as a polymerizable monomer. In addition, the resin having an ethylenically unsaturated group is also referred to as a polymerizable resin.

The molecular weight of the polymerizable monomer is preferably less than 3000. The upper limit is more preferably 2000 or less and still more preferably 1500 or less. The lower limit is preferably 100 or more, more preferably 150 or more, and still more preferably 250 or more. The polymerizable monomer is preferably a compound including 3 or more ethylenically unsaturated groups, more preferably a compound including 3 to 15 ethylenically unsaturated groups, and still more preferably a compound having 3 to 6 ethylenically unsaturated groups. In addition, the polymerizable monomer is preferably a 3- to 15-functional (meth)acrylate compound and more preferably a 3- to 6-functional (meth)acrylate compound. Specific examples of the polymerizable monomer include compounds described in paragraphs “0095” to “0108” of JP2009-288705A, paragraph “0227” of JP2013-029760A, paragraphs “0254” to “0257” of JP2008-292970A, paragraphs “0034” to “0038” of JP2013-253224A, paragraph “0477” of JP2012-208494A, JP2017-048367A, JP6057891B, and JP6031807B, the contents of which are incorporated herein by reference.

As the polymerizable monomer, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable monomer, NK ESTER A-TMMT (manufactured by Shin-Nakamura Chemical Co., Ltd.) and KAYARAD RP-1040 and DPCA-20 (manufactured by Nippon Kayaku Co., Ltd.) can also be used. In addition, as the polymerizable monomer, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable monomer, a compound having an acid group can also be used. By using a polymerizable monomer having an acid group, a coloring composition layer in an unexposed area is easily removed during development and the generation of the development residue can be suppressed. Examples of the acid group include a carboxyl group, a sulfo group, and a phosphoric acid group, and a carboxyl group is preferable. Examples of the polymerizable monomer having an acid group include succinic acid-modified dipentaerythritol penta(meth)acrylate. Examples of a commercially available product of the polymerizable monomer having an acid group include ARONIX M-510, M-520, and ARONIX TO-2349 (manufactured by TOAGOSEI CO., LTD.). The acid value of the polymerizable monomer having an acid group is preferably 0.1 to 40 mgKOH/g and more preferably 5 to 30 mgKOH/g. In a case where the acid value of the polymerizable monomer is 0.1 mgKOH/g or more, solubility in a developer is good, and in a case where the acid value of the polymerizable monomer is 40 mgKOH/g or less, it is advantageous in production and handling.

The polymerizable monomer is also preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable monomer, a compound having an alkyleneoxy group can also be used. The polymerizable monomer having an alkyleneoxy group is preferably a compound having an ethyleneoxy group and/or a propyleneoxy group, more preferably a compound having an ethyleneoxy group, and still more preferably a 3- to 6-functional (meth)acrylate compound having 4 to 20 ethyleneoxy groups. Examples of a commercially available product of the polymerizable monomer having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd, which is a trifunctional (meth)acrylate having three isobutyleneoxy groups.

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable monomer. In addition, compounds having an amino structure or a sulfide structure in the molecule, described in JP1988-277653A (JP-S63-277653A), JP1988-260909A (JP-S63-260909A), and JP1989-105238A (JP-H01-105238A), are also preferably used. In addition, as the polymerizable monomer, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The weight-average molecular weight of the polymerizable resin is preferably 3000 or more, more preferably 5000 or more, still more preferably 7000 or more, and particularly preferably 10000 or more. In addition, the weight-average molecular weight of the polymerizable resin is preferably 50000 or less, more preferably 40000 or less, and still more preferably 30000 or less.

The amount of the ethylenically unsaturated group (hereinafter, also referred to as a C═C value) of the polymerizable resin is preferably 0.05 to 5.0 mmol/g. The upper limit is more preferably 4.0 mmol/g or less, still more preferably 3.0 mmol/g or less, even more preferably 2.0 mmol/g or less, and particularly preferably 1.0 mmol/g or less. The lower limit is preferably 0.1 mmol/g or more and more preferably 0.2 mmol/g or more. The C═C value of the polymerizable resin is a numerical value representing a molar amount of C═C group per 1 g of the solid content of the polymerizable resin. With regard to the C═C value of the polymerizable resin, a low-molecular-weight component (a) of C═C group site is extracted from the polymerizable resin by an alkali treatment, a content of the low-molecular-weight component is measured by high-performance liquid chromatography (HPLC), and the C═C value of the polymerizable resin can be calculated by the following expression. In a case where the C═C group site cannot be extracted from the polymerizable resin by the alkali treatment, a value measured by a nuclear magnetic resonance (NMR) method is used.

C═C Value [mmol/g] of Polymerizable Resin=(Content [ppm] of Low-Molecular-Weight Component (a)/Molecular Weight [g/mol] of Low-Molecular-Weight Component (a)/(Weighed Value [g] of Polymerizable Resin)×(Concentration of Solid Contents [mass %] of Polymerizable Resin/100)×10)

The polymerizable resin preferably includes a repeating unit having an ethylenically unsaturated group in the side chain, more preferably include a repeating unit represented by Formula (A-1-1). In addition, in the polymerizable resin, the repeating unit having an ethylenically unsaturated group is preferably contained in an amount of 10 mol % or more, more preferably 10 to 80 mol %, and still more preferably 20 to 70 mol % in total repeating units of the polymerizable resin.

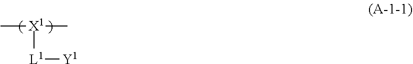

In Formula (A-1-1), X¹ represents the main chain of the repeating unit, L¹ represents a single bond or a divalent linking group, and Y¹ represents an ethylenically unsaturated group.

In Formula (A-1-1), the main chain of the repeating unit represented by X¹ is not particularly limited. It is not particularly limited as long as it is a linking group formed from a known polymerizable monomer. Examples thereof include a poly(meth)acrylic linking group, a polyalkyleneimine-based linking group, a polyester-based linking group, a polyurethane-based linking group, a polyuria-based linking group, a polyamide-based linking group, a polyether-based linking group, and a polystyrene-based linking group. Among these, a poly(meth)acrylic linking group or a polyalkyleneimine-based linking group is preferable, and a poly(meth)acrylic linking group is more preferable from the viewpoint of availability of raw materials and production suitability.

In Formula (A-1-1), examples of the divalent linking group represented by L¹ include an alkylene group (preferably an alkylene group having 1 to 12 carbon atoms), an alkyleneoxy group (preferably an alkyleneoxy group having 1 to 12 carbon atoms), an oxyalkylenecarbonyl group (preferably an oxyalkylenecarbonyl group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more of these groups. The alkylene group, the alkylene group in the alkyleneoxy group, and the alkylene group in the oxyalkylenecarbonyl group may be linear, branched, or cyclic, and are preferably linear or branched. In addition, the alkylene group, the alkylene group in the alkyleneoxy group, and the alkylene group in the oxyalkylenecarbonyl group may have a substituent or may be unsubstituted. Examples of the substituent include a hydroxy group and an alkoxy group, and a hydroxy group is preferable from the viewpoint of production suitability.

In Formula (A-1-1), examples of the ethylenically unsaturated group represented by Y¹ include a vinyl group, a vinyloxy group, an allyl group, a methallyl group, a (meth)acryloyl group, a styrene group, a cinnamoyl group, and a maleimide group. Among these, a (meth)acryloyl group, a styrene group, or a maleimide group is preferable, a (meth)acryloyl group is more preferable, and an acryloyl group is particularly preferable.

Specific examples of the repeating unit represented by Formula (A-1-1) include a repeating unit represented Formula (A-1-1a) and a repeating unit represented by Formula (A-1-1b).

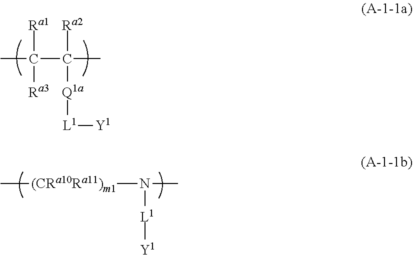

In Formula (A-1-1a), R^{a1} to R^{a5} each independently represent a hydrogen atom or an alkyl group, Q^{1a} represents —CO—, —COO—, —OCO—, —CONH—, or a phenylene group, L¹ represents a single bond or a divalent linking group, and Y¹ represents an ethylenically unsaturated group. The number of carbon atoms in the alkyl group represented by R^{a1} to R^{a3} is preferably 1 to 10, more preferably 1 to 3, and still more preferably 1. Q^{1a} is preferably —COO— or —CONH— and more preferably —COO—.

In Formula (A-1-1b), R^{a10} and R^{a11} each independently represent a hydrogen atom or an alkyl group, m1 represents an integer of 1 to 5, L¹ represents a single bond or a divalent linking group, and Y¹ represents an ethylenically unsaturated group. The number of carbon atoms in the alkyl group represented by R^{a10} and R^{a11} is preferably 1 to 10 and more preferably 1 to 3.

The polymerizable resin preferably further includes a repeating unit having a graft chain. In a case where the polymerizable resin includes a repeating unit having a graft chain, aggregation of the pigment A and the like can be more effectively suppressed due to steric hindrance by the graft chain. In addition, in a case of forming the cured film, the polymerizable resin polymerizes in the vicinity of the pigment A and the pigment A can be firmly retained in the film, the thermal diffusion of the pigment A due to heating can be suppressed more effectively, and a cured film having excellent heat resistance can also be formed. In the polymerizable resin, the repeating unit having a graft chain is preferably contained in an amount of 1.0 to 60 mol %, and more preferably 1.5 to 50 mol % in total repeating units of the polymerizable resin. The polymerizable resin including the repeating unit having a graft chain is preferably used as a dispersant.

In the present invention, the graft chain means a polymer chain branched and extended from the main chain of the repeating unit. The length of the graft chain is not particularly limited, and in a case where the graft chain gets longer, a steric repulsion effect is enhanced, and thus, the dispersibility of the pigment A or the like can be increased. As the graft chain, the number of atoms excluding the hydrogen atoms is preferably 40 to 10000, the number of atoms excluding the hydrogen atoms is more preferably 50 to 2000, and the number of atoms excluding the hydrogen atoms is still more preferably 60 to 500.

It is preferable that the graft chain includes at least one structural repeating unit selected from a polyester repeating unit, a polyether repeating unit, a poly(meth)acrylic repeating unit, a polyurethane repeating unit, a polyurea repeating unit, or a polyamide repeating unit, it is more preferable that the graft chain includes at least one structural repeating unit selected from a polyester repeating unit, a polyether repeating unit, or a poly(meth)acrylic repeating unit, and it is still more preferable that the graft chain includes a polyester repeating unit. Examples of the polyester repeating unit include a repeating unit having a structure represented by Formula (G-1), Formula (G-4), or Formula (G-5). In addition, examples of the polyether repeating unit include a repeating unit having a structure represented by Formula (G-2). In addition, examples of the poly(meth)acrylic repeating unit include a repeating unit having a structure represented by Formula (G-3).

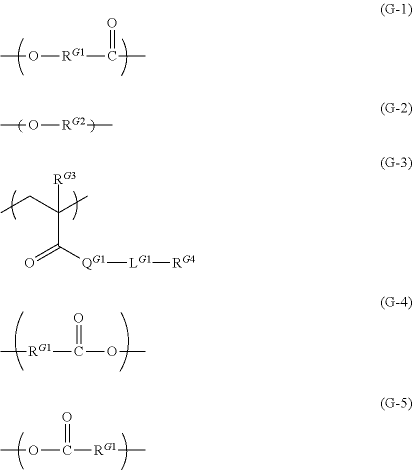

In the formulae, R^{G1} and R^{G2} each represent an alkylene group. The alkylene group represented by R^{G1} and R^{G2} is not particularly limited, but is preferably a linear or branched alkylene group having 1 to 20 carbon atoms, more preferably a linear or branched alkylene group having 2 to 16 carbon atoms, and still more preferably a linear or branched alkylene group having 3 to 12 carbon atoms.

In the formulae, R^{G3} represents a hydrogen atom or a methyl group.

In the formulae, Q^{G1} represents —O— or —NH—, and L^{G1} represents a single bond or a divalent linking group. Examples of the divalent linking group include an alkylene group (preferably an alkylene group having 1 to 12 carbon atoms), an alkyleneoxy group (preferably an alkyleneoxy group having 1 to 12 carbon atoms), an oxyalkylenecarbonyl group (preferably an oxyalkylenecarbonyl group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more of these groups.

R^{G4} represents a hydrogen atom or a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group.

A terminal structure of the graft chain is not particularly limited. The terminal structure of the graft chain may be a hydrogen atom or a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group. Among these, from the viewpoint of improvement of the dispersibility of the coloring material or the like, a group having a steric repulsion effect is preferable, and an alkyl group or alkoxy group having 5 to 24 carbon atoms is preferable. The alkyl group and the alkoxy group may be linear, branched, or cyclic, and are preferably linear or branched.

In the present invention, the graft chain is preferably a structure represented by Formula (G-1a), Formula (G-2a), Formula (G-3a), Formula (G-4a), or Formula (G-5a).

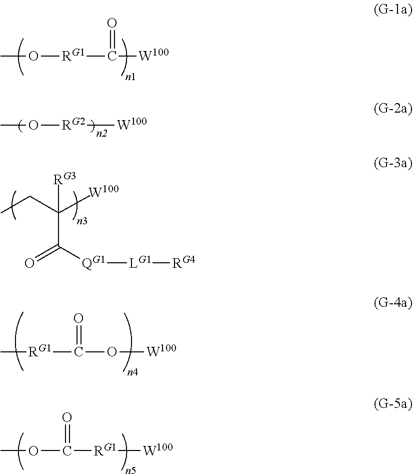

In the formulae, R^{G1} and R^{G2} each independently represent an alkylene group, R^{G3} represents a hydrogen atom or a methyl group, Q^{G}1 represents —O— or —NH—, L^{G}1 represents a single bond or a divalent linking group, R^{G4} represents a hydrogen atom or a substituent, and W¹⁰⁰ represents a hydrogen atom or a substituent. n1 to n5 each independently represent an integer of 2 or more. R^{G1} to R^{G4}, Q^{G1} and L^{G1} have the same meaning as R^{G1} to R^{G4} , Q^{G1} , and L^{G1} described in Formulae (G-1) to (G-5), and the preferred ranges are also the same.

In Formulae (G-1a) to (G-5a), it is preferable that W¹⁰⁰ represents a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group. Among these, from the viewpoint of improvement of the dispersibility of the coloring material or the like, a group having a steric repulsion effect is preferable, and an alkyl group or alkoxy group having 5 to 24 carbon atoms is preferable. The alkyl group and the alkoxy group may be linear, branched, or cyclic, and are preferably linear or branched.

In Formulae (G-1a) to (G-5a), each of n1 to n5 is preferably an integer of 2 to 100, more preferably an integer of 2 to 80, and still more preferably an integer of 8 to 60.

In Formula (G-1a), in a case where n1 is 2 or more, a plurality of R^{G1} in each repeating unit may be the same or different from each other. In addition, in a case where R^{G1} includes two or more kinds of repeating units different from each other, the arrangement of the repeating units is not particularly limited, and may be performed in any of a random manner, an alternative manner, and a blocked manner. The same applies to Formulae (G-2a) to (G-5a).

Examples of the repeating unit having a graft chain include a repeating unit represented by Formula (A-1-2).

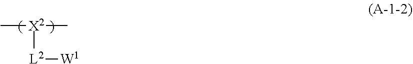

In Formula (A-1-2), X² represents the main chain of the repeating unit, L² represents a single bond or a divalent linking group, and W¹ represents a graft chain.

Examples of the main chain of the repeating unit represented by X² in Formula (A-1-2) include the structures described in the description of X¹ of Formula (A-1-1), and the preferred range is also the same. Examples of the divalent linking group represented by L² in Formula (A-1-2) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more of these groups. Examples of the graft chain represented by W¹ in Formula (A-1-2) include the graft chains described above.

Specific examples of the repeating unit represented by Formula (A-1-2) include a repeating unit represented Formula (A-1-2a) and a repeating unit represented by Formula (A-1-2b).

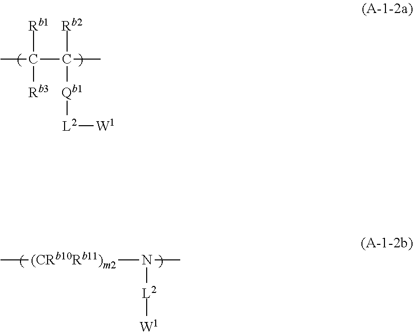

In Formula (A-1-2a), R^{b1} to R^{b3} each independently represent a hydrogen atom or an alkyl group, Q^{b1} represents —CO—, —COO—, —OCO—, —CONH—, or a phenylene group, L² represents a single bond or a divalent linking group, and W¹ represents a graft chain. The number of carbon atoms in the alkyl group represented by R^{b1} to R^{b3} is preferably 1 to 10, more preferably 1 to 3, and still more preferably 1. Q^{b1} is preferably —COO— or —CONH— and more preferably —COO—.

In Formula (A-1-2b), R^{b10} and R^{b11} each independently represent a hydrogen atom or an alkyl group, m2 represents an integer of 1 to 5, L² represents a single bond or a divalent linking group, and W¹ represents a graft chain. The number of carbon atoms in the alkyl group represented by R^{b10} and R^{b11} is preferably 1 to 10 and more preferably 1 to 3.

In a case where the polymerizable resin includes a repeating unit having a graft chain, the weight-average molecular weight (Mw) of the repeating unit having a graft chain is preferably 1000 or more, more preferably 1000 to 10000, and still more preferably 1000 to 7500. In the present invention, the weight-average molecular weight of the repeating unit having a graft chain is a value calculated from the weight-average molecular weight of the raw material monomer used for the polymerization of the repeating unit. For example, the repeating unit having a graft chain can be formed by polymerizing a macromonomer. Here, the macromonomer means a polymer compound in which a polymerizable group is introduced at a polymer terminal. In a case where the repeating unit having a graft chain is formed using a macromonomer, the weight-average molecular weight of the macromonomer corresponds to the repeating unit having a graft chain.

It is also preferable that the polymerizable resin further includes a repeating unit having an acid group. In a case where the polymerizable resin further includes a repeating unit having an acid group, the dispersibility of the pigment A or the like can be further improved. Furthermore, developability can also be improved. Examples of the acid group include a carboxyl group, a sulfo group, and a phosphoric acid group.

The repeating unit having an acid group include a repeating unit represented by Formula (A-1-3).

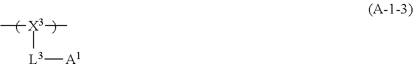

In Formula (A-1-3), X³ represents the main chain of the repeating unit, L³ represents a single bond or a divalent linking group, and A¹ represents an acid group. Examples of the main chain of the repeating unit represented by X³ in Formula (A-1-3) include the structures described in the description of X¹ of Formula (A-1-1), and the preferred range is also the same. Examples of the divalent linking group represented by L³ in Formula (A-1-3) include an alkylene group (preferably an alkylene group having 1 to 12 carbon atoms), an alkenylene group (preferably an alkenylene group having 2 to 12 carbon atoms), an alkyleneoxy group (preferably an alkyleneoxy group having 1 to 12 carbon atoms), an oxyalkylenecarbonyl group (preferably an oxyalkylenecarbonyl group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more of these groups. The alkylene group, the alkylene group in the alkyleneoxy group, and the alkylene group in the oxyalkylenecarbonyl group may be linear, branched, or cyclic, and are preferably linear or branched. In addition, the alkylene group, the alkylene group in the alkyleneoxy group, and the alkylene group in the oxyalkylenecarbonyl group may have a substituent or may be unsubstituted. Examples of the substituent include a hydroxy group. Examples of the acid group represented by A¹ in Formula (A-1-3) include a carboxyl group, a sulfo group, and a phosphoric acid group.

Specific examples of the repeating unit represented by Formula (A-1-3) include a repeating unit represented Formula (A-1-3a) and a repeating unit represented by Formula (A-1-3b).

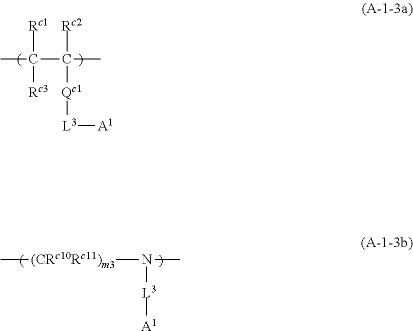

In Formula (A-1-3a), R^{c1} to R^{c3} each independently represent a hydrogen atom or an alkyl group, Q represents —CO—, —COO—, —OCO—, —CONH—, or a phenylene group, L³ represents a single bond or a divalent linking group, and A represents an acid group. The number of carbon atoms in the alkyl group represented by R^{c1} to R^{c3} is preferably 1 to 10, more preferably 1 to 3, and still more preferably 1. Q^{c1} is preferably —COO— or —CONH— and more preferably —COO—.

In Formula (A-1-3b), R^{c10} and R^{c11} each independently represent a hydrogen atom or an alkyl group, m3 represents an integer of 1 to 5, L³ represents a single bond or a divalent linking group, and A¹ represents an acid group. The number of carbon atoms in the alkyl group represented by R^{c10} and R^{c11} is preferably 1 to 10 and more preferably 1 to 3.

In a case where the polymerizable resin includes a repeating unit having an acid group, the content of the repeating unit having an acid group is preferably 80 mol % or less and more preferably 10 to 80 mol % in total repeating units of the polymerizable resin.

The acid value of the polymerizable resin is preferably 20 to 150 mgKOH/g. The upper limit is more preferably 100 mgKOH/g or less. The lower limit is preferably 30 mgKOH/g or more and more preferably 35 mgKOH/g or more. In a case where the acid value of the polymerizable resin is within the above-described range, particularly excellent dispersibility is easily obtained. Furthermore, excellent developability is also easily obtained.

As other repeating units, the polymerizable resin may further include a repeating unit derived from a monomer component including a compound represented by Formula (ED1) and/or a compound represented by Formula (ED2) (hereinafter, these compounds may be referred to as an “ether dimer”).

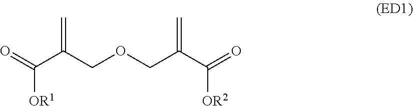

In Formula (ED1), R¹ and R² each independently represent a hydrogen atom or a hydrocarbon group having 1 to 25 carbon atoms which may have a substituent.

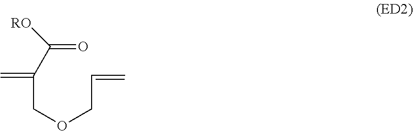

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

In the present invention, as the polymerizable resin, a compound (hereinafter, also referred to as a compound (SP-1)) represented by Formula (SP-1) can also be used. The compound (SP-1) can be preferably used as a dispersant.

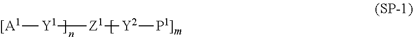

In the formula, Z¹ represents an (m+n)-valent linking group;

Y¹ and Y² each independently represent a single bond or a linking group;

A¹ represents a group including a pigment absorbing portion;

P¹ represents a polymer chain;

n represents 1 to 20, m represents 1 to 20, and m+n is 3 to 21;

n Y¹'s and n A¹'s each may be the same or different from each other;

m Y²'s and m P¹'s each may be the same or different from each other; and

at least one of Z¹, A¹, or P¹ represents an ethylenically unsaturated group.

Examples of the ethylenically unsaturated group represented by the compound (SP-1) include a vinyl group, a vinyloxy group, an allyl group, a methallyl group, a (meth)acryloyl group, a styrene group, a cinnamoyl group, and a maleimide group. Among these, a (meth)acryloyl group, a styrene group, or a maleimide group is preferable, a (meth)acryloyl group is more preferable, and an acryloyl group is particularly preferable.

In the compound (SP-1), the ethylenically unsaturated group may be included in any of Z¹, A¹, and P¹, but it is preferable to be included in P¹. In addition, in a case where P¹ includes an ethylenically unsaturated group, P¹ is preferably a polymer chain having a repeating unit including the ethylenically unsaturated group in the side chain.

In Formula (SP-1), A¹ represents a group including a pigment absorbing portion. Examples of the pigment absorbing portion include an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group. Among these, a heterocyclic structure, an acid group, a group having a basic nitrogen atom, a hydrocarbon group having 4 or more carbon atoms, or a hydroxy group is preferable, and from the viewpoint of dispersibility of the coloring material, an acid group is more preferable. Examples of the acid group include a carboxyl group, a sulfo group, and a phosphoric acid group, and a carboxyl group is preferable.

One A¹ may include at least one pigment absorbing portion, or two or more pigment absorbing portions. A¹ preferably includes 1 to 10 pigment absorbing portions and more preferably includes 1 to 6 pigment absorbing portions. In addition, examples of the group including a pigment absorbing portion, which is represented by A¹, include a group formed by bonding the above-described pigment absorbing portion to a linking group composed of 1 to 200 carbon atoms, 0 to 20 nitrogen atoms, 0 to 100 oxygen atoms, 1 to 400 hydrogen atoms, and 0 to 40 sulfur atoms. Examples thereof include a group formed by bonding one or more pigment absorbing portions with each other through a chain saturated hydrocarbon group having 1 to 10 carbon atoms, a cyclic saturated hydrocarbon group having 3 to 10 carbon atoms, or an aromatic hydrocarbon group having 5 to 10 carbon atoms. The above-described chain saturated hydrocarbon group, cyclic saturated hydrocarbon group, and aromatic hydrocarbon group may further have a substituent. Examples of the substituent include an alkyl group having 1 to 20 carbon atoms, an aryl group having 6 to 16 carbon atoms, a hydroxy group, an amino group, a carboxyl group, a sulfonic acid amide group, an N-sulfonylamide group, an acyloxy group having 1 to 6 carbon atoms, an alkoxy group having 1 to 20 carbon atoms, a halogen atom, an alkoxycarbonyl group having 2 to 7 carbon atoms, a cyano group, a carbonate ester group, and a photocurable group. In addition, in a case where the pigment absorbing portion itself can form a monovalent group, the pigment absorbing portion itself may be A¹.

In addition, the formula weight of A¹ is preferably 30 to 2000. The upper limit is preferably 1000 or less and more preferably 800 or less. The lower limit is preferably 50 or more and more preferably 100 or more. In a case where the formula weight of A1 is within the above-described range, adsorptivity to the coloring material is good. The formula weight of A¹ is a value calculated from the structural formula.

In Formula (SP-1), Z¹ represents an (m+n)-valent linking group. Examples of the (m+n)-valent linking group include a group composed of 1 to 100 carbon atoms, 0 to 10 nitrogen atoms, 0 to 50 oxygen atoms, 1 to 200 hydrogen atoms, and 0 to 20 sulfur atoms. Examples of the (m+n)-valent linking group also include a group (which may form a ring structure) composed of the following structural unit or a combination of two or more the following structural units.

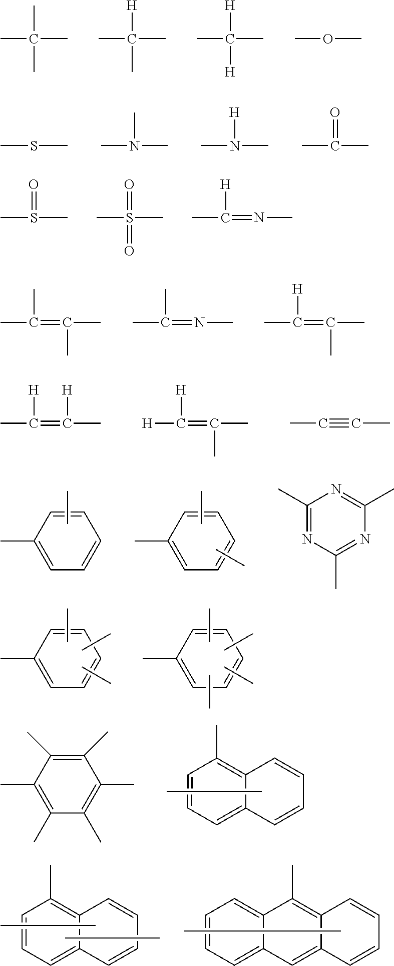

The formula weight of Z¹ is preferably 20 to 3000. The upper limit is preferably 2000 or less and more preferably 1500 or less. The lower limit is preferably 50 or more and more preferably 100 or more. The formula weight of Z¹ is a value calculated from the structural formula. With regard to specific examples of the (m+n)-valent linking group, reference can be made to the description in paragraphs “0043” to “0055” of JP2014-177613A, the contents of which are incorporated herein by reference.

In Formula (SP-1), Y¹ and Y² each independently represent a single bond or a linking group. Examples of the linking group include a group composed of 1 to 100 carbon atoms, 0 to 10 nitrogen atoms, 0 to 50 oxygen atoms, 1 to 200 hydrogen atoms, and 0 to 20 sulfur atoms. The above-described group may further have the above-described substituent. Examples of the linking group represented by Y¹ and Y² include a group composed of the following structural unit or a combination of two or more the following structural units.

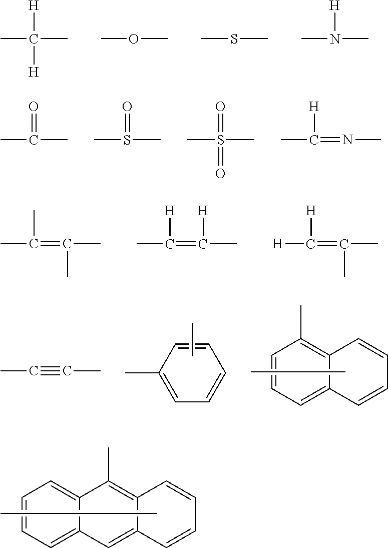

In Formula (SP-1), P¹ represents a polymer chain. As the polymer chain represented by P¹, a polymer chain which has, in the main chain, at least one repeating unit selected from a poly(meth)acrylic repeating unit, a polyether repeating unit, a polyester repeating unit, a polyamide repeating unit, a polyimide repeating unit, a polyimine repeating unit, or a polyurethane repeating unit is preferable. In addition, as the polymer chain represented by P¹, a polymer chain including a repeating unit represented by Formulae (P1-1) to (P1-5) is preferable.

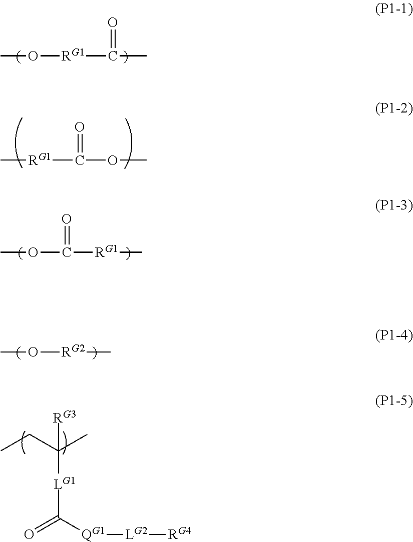

In the formulae, R^{G1} and R^{G2} each represent an alkylene group. As the alkylene group represented by R^{G1} and R^{G2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable. The alkylene group may have a substituent. Examples of the substituent include an aryl group, a heteroaryl group, an alkoxy group, an aryloxy group, a heteroaryloxy group, an alkylthioether group, an arylthioether group, a heteroarylthioether group, and an ethylenically unsaturated group.

In the formulae, R^{G3} represents a hydrogen atom or a methyl group.

In the formulae, Q^{G1} represents —O— or —NH—, L^{G1} represents a single bond or an arylene group, and L^{G2} represents a single bond or a divalent linking group. Q^{G1} is preferably —O—. L^{G1} is preferably a single bond. Examples of the divalent linking group represented by L^{G2} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

R^{G4} represents a hydrogen atom or a substituent. Examples of the substituent include an alkyl group, an aryl group, a heteroaryl group, an alkoxy group, an aryloxy group, a heteroaryloxy group, an alkylthioether group, an arylthioether group, a heteroarylthioether group, an ethylenically unsaturated group, and an acid group.

The number of repetitions of the above-described repeating unit in P¹ is preferably 3 to 2000. The upper limit is preferably 1500 or less and more preferably 1000 or less. The lower limit is preferably 5 or more and more preferably 7 or more. In addition, P¹ is preferably a polymer chain having a repeating unit including an ethylenically unsaturated group in the side chain. In addition, the proportion of the repeating unit including an ethylenically unsaturated group in the side chain with respect to total repeating units constituting P¹ is preferably 1 mol % or more, more preferably 2 mol % or more, and still more preferably 3 mol % or more. The upper limit may be 100 mol %. In addition, in a case where P¹ is a polymer chain having a repeating unit including an ethylenically unsaturated group in the side chain, it is also preferable that P¹ includes other repeating units in addition to the repeating unit including an ethylenically unsaturated group in the side chain. Examples the other repeating units include a repeating unit including an acid group in the side chain. In a case where P¹ includes other repeating units including an acid group in the side chain, in addition to the repeating unit including an ethylenically unsaturated group in the side chain, the generation of the development residue can be effectively suppressed in the formation of a pattern by a photolithography method. In a case where P¹ includes a repeating unit including an acid group in the side chain, the proportion of the repeating unit including an acid group in the side chain with respect to total repeating units constituting P¹ is preferably 50 mol % or less, more preferably 2 to 48 mol %, and still more preferably 4 to 46 mol %.

The weight-average molecular weight of the polymer chain represented by P¹ is preferably 1000 or more and more preferably 1000 to 10000. The upper limit is preferably 9000 or less, more preferably 6000 or less, and still more preferably 3000 or less. The lower limit is preferably 1200 or more and more preferably 1400 or more. The weight-average molecular weight of P¹ is a value calculated from the weight-average molecular weight of a raw material used for introducing into the polymer chain.

It is also preferable that the polymerizable resin is a resin including a repeating unit represented by Formula (b-10).

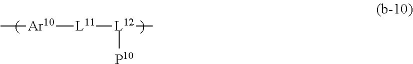

In Formula (b-10), Ar¹⁰ represents a group including an aromatic carboxyl group, L¹¹ represents —COO— or —CONH—, L¹² represents a trivalent linking group, and P¹⁰ represents a polymer chain having an ethylenically unsaturated group.

In Formula (b-10), examples of the group including an aromatic carboxyl group represented by Ar¹⁰ include a structure derived from an aromatic tricarboxylic acid anhydride and a structure derived from an aromatic tetracarboxylic acid dianhydride. Examples of the aromatic tricarboxylic acid anhydride and the aromatic tetracarboxylic acid dianhydride include compounds having the following structures.

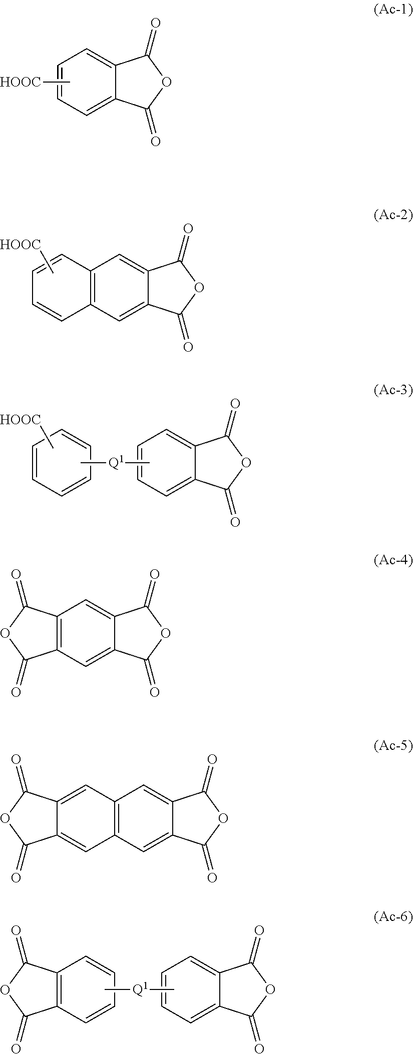

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

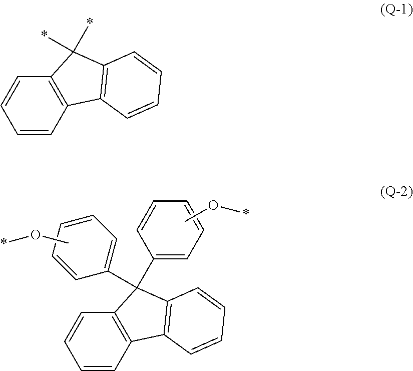

Specific examples of the aromatic tricarboxylic acid anhydride include a benzenetricarboxylic acid anhydride (1,2,3-benzenetricarboxylic acid anhydride, trimellitic acid anhydride [1,2,4-benzenetricarboxylic acid anhydride], and the like), a naphthalenetricarboxylic acid anhydride (1,2,4-naphthalenetricarboxylic acid anhydride, 1,4,5-naphthalenetricarboxylic acid anhydride, 2,3,6-naphthalenetricarboxylic acid anhydride, 1,2,8-naphthalenetricarboxylic acid anhydride, and the like), 3,4,4′-benzophenonetricarboxylic acid anhydride, 3,4,4′-biphenylethertricarboxylic acid anhydride, 3,4,4′-biphenyltricarboxylic acid anhydride, 2,3,2′-biphenyltricarboxylic acid anhydride, 3,4,4′-biphenylmethanetricarboxylic acid anhydride, and 3,4,4′-biphenylsulfonetricarboxylic acid anhydride. Specific examples of the aromatic tetracarboxylic acid dianhydride include pyromellitic acid dianhydride, ethylene glycol dianhydrous trimellitic acid ester, propylene glycol dianhydrous trimellitic acid ester, butylene glycol dianhydrous trimellitic acid ester, 3,3′,4,4′-benzophenonetetracarboxylic acid dianhydride, 3,3′,4,4′-biphenylsulfonetetracarboxylic acid dianhydride,1,4,5,8-naphthalenetetracarboxylic acid dianhydride, 2,3,6,7-naphthalenetetracarboxylic acid dianhydride, 3,3′,4,4′-biphenylethertetracarboxylic acid dianhydride, 3,3′,4,4′-dimethyldiphenylsilanetetracarboxylic acid dianhydride, 3,3′,4,4′-tetraphenylsilanetetracarboxylic acid dianhydride, 1,2,3,4-frantetracarboxylic acid dianhydride, 4,4′-bis(3,4-dicarboxyphenoxy)diphenylsulfide dianhydride, 4,4′-bis(3,4-dicarboxyphenoxy)diphenylsulfonedianhydride,4,4′-bis(3,4-dicarboxyphenoxy) diphenylpropane dianhydride, 3,3′,4,4′-perfluoroisopropyridendiphthalic acid dianhydride, 3,3′,4,4′-biphenyltetracarboxylic acid dianhydride, bis(phthalic acid) phenylphosphineoxide dianhydride, p-phenylene-bis(triphenylphthalic acid) dianhydride, m-phenylene-bis(triphenylphthalic acid) dianhydride, bis(triphenylphthalic acid)-4,4′-diphenylether dianhydride, bis(triphenylphthalic acid)-4,4′-diphenylmethane dianhydride, 9,9-bis(3,4-dicarboxyphenyl)fluorene dianhydride, 9,9-bis[4-(3,4-dicarboxyphenoxy)phenyl]fluorene dianhydride, 3,4-dicarboxy-1,2,3,4-tetrahydro-1-naphthalenesuccinic acid dianhydride, and 3,4-dicarboxy-1,2,3,4-tetrahydro-6-methyl-1-naphthalenesuccinic acid dianhydride.

Specific examples of the group including an aromatic carboxyl group represented by Ar¹⁰ include a group represented by Formula (Ar-1), a group represented by Formula (Ar-2), and a group represented by Formula (Ar-3).

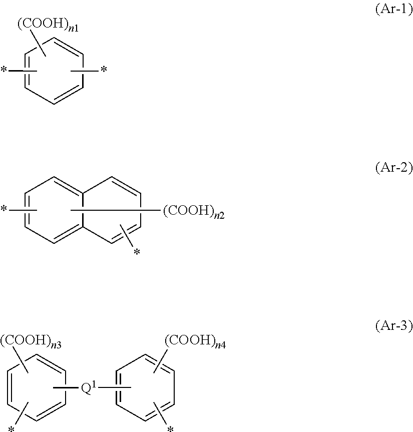

In Formula (Ar-1), n1 represents an integer of 1 to 4, and is preferably an integer of 1 or 2 and more preferably 2.

In Formula (Ar-2), n2 represents an integer of 1 to 8, and is preferably an integer of 1 or 4, more preferably 1 or 2, and still more preferably 2.

In Formula (Ar-3), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-3), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formula (b-10), L¹¹ represents —COO— or —CONH—, preferably —COO—.

In Formula (b-10), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group.

In Formula (b-10), P¹⁰ represents a polymer chain having a (meth)acryloyl group. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 600 or more and more preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. This resin is preferably used as a dispersant.

In Formula (b-10), the polymer chain represented by P¹⁰ is preferably a polymer chain including a repeating unit represented by Formulae (P-1) to (P-5), and more preferably a polymer chain including a repeating unit represented by Formulae (P-5).

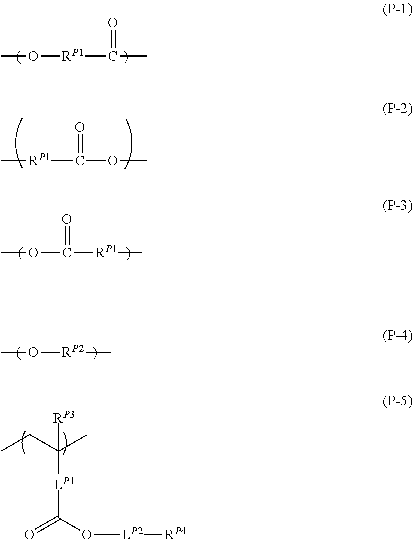

In the formulae, R^{P1} and R^{P2} each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{P3} represents a hydrogen atom or a methyl group.

In the formulae, L^{P1} represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxyl group, an alkyl group, an aryl group, a heteroaryl group, an alkoxy group, an aryloxy group, a heteroaryloxy group, an alkylthioether group, an arylthioether group, a heteroarylthioether group, and an ethylenically unsaturated group.

In addition, the polymer chain represented by P¹⁰ is more preferably a polymer chain having a repeating unit including an ethylenically unsaturated group in the side chain. In addition, the proportion of the repeating unit including an ethylenically unsaturated group in the side chain with respect to total repeating units constituting P¹⁰ is preferably 5 mass % or more, more preferably 10 mass % or more, and still more preferably 20 mass % or more. The upper limit may be 100 mass %, and is preferably 90 mass % or less and still more preferably 60 mass % or less.

In addition, it is also preferable that the polymer chain represented by P¹⁰ has a repeating unit including an acid group. Examples of the acid group include a carboxyl group, a phosphoric acid group, a sulfo group, and a phenolic hydroxy group. According to this aspect, dispersibility of the pigment in the composition can be further improved. Furthermore, developability can also be further improved. The proportion of the repeating unit including an acid group is preferably 1 to 30 mass %, more preferably 2 to 20 mass %, and still more preferably 3 to 10 mass %.

The weight-average molecular weight of the resin including the repeating units, which is represented by Formula (b-10), is preferably 2000 to 35000. The upper limit is preferably 25000 or less, more preferably 20000 or less, and still more preferably 15000 or less. The lower limit is preferably 4000 or more, more preferably 6000 or more, and still more preferably 7000 or more.

The acid value of the resin including the repeating units, which is represented by Formula (b-10), is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more.

Specific examples of the compound including the repeating unit having an ethylenically unsaturated group in the side chain and the repeating unit having a graft chain include the following compounds and compounds described in Examples later.

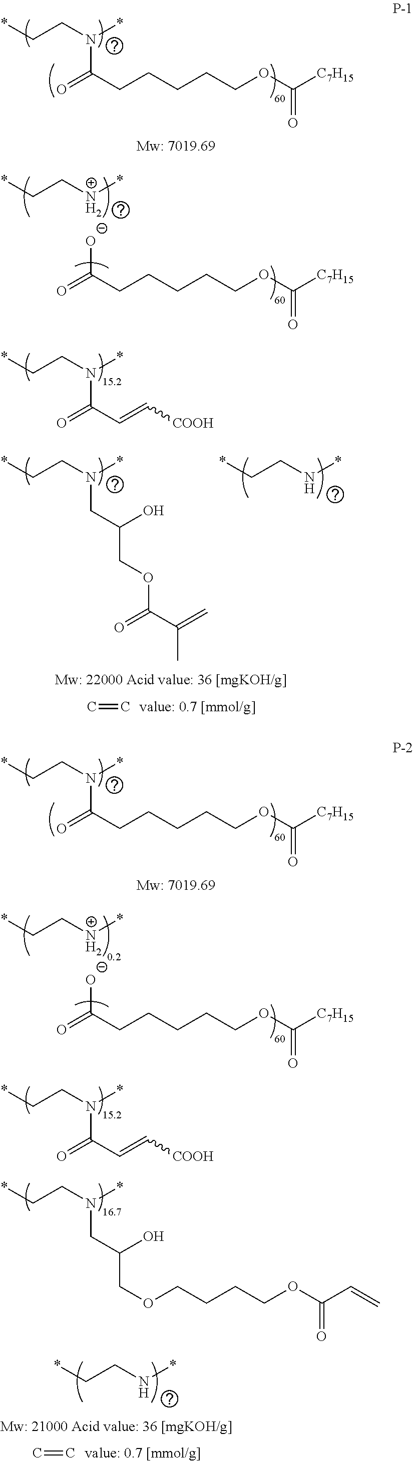

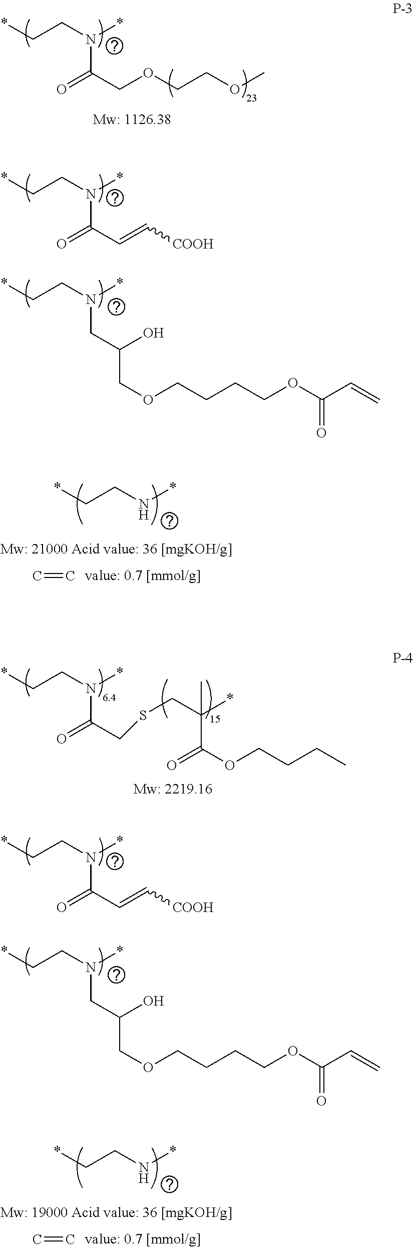

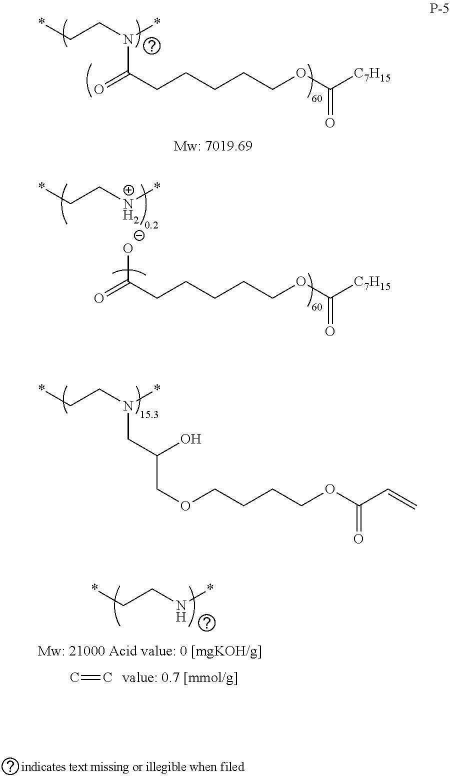

TABLE 1

| | | | | | Characteristics | | | | | |
|---|---|---|---|---|---|---|---|---|---|---|
| | | | | | | Acid | | | | |
| | | | | | | value | C = | | | |
| | Structure | | | | | [mg- | C value | | | |
| | A-1-1 | | | | | KOH/ | [mmol | Molar ratio [mol%] | | |
| | | C = C group structure | A-1-2 | A-1-3 | Mw | g] | /g] | A-1-1 | A-1-2 | A-1-3 |
| P-6 | 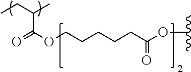 | 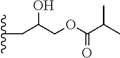 [SMILES: *CC(O)COC(=O)C(C)C] | 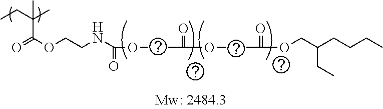 | 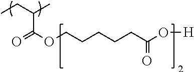 | 22000 | 78 | 0.7 | 32% | 5% | 53% |
| P-7 | 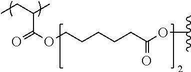 | 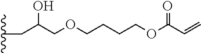 [SMILES: *CC(O)COCCCCOC(=O)C=C] | 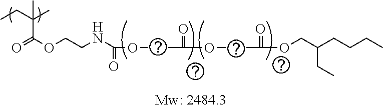 | 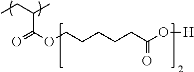 | 18000 | 78 | 0.7 | 32% | 4% | 64% |
| P-8 | 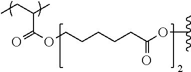 | 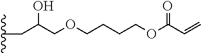 [SMILES: *CC(O)COCCCCOC(=O)C=C] | 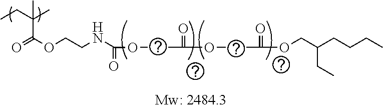 | 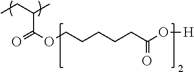 | 20000 | 78 | 0.47 | 25% | 9% | 57% |
| P-9 | 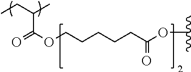 | 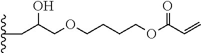 [SMILES: *CC(O)COCCCCOC(=O)C=C] | 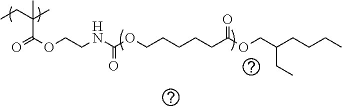 | 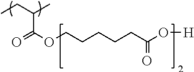 | 19000 | 78 | 0.7 | 32% | 10% | 58% |
| P-10 | 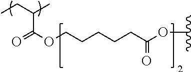 | 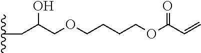 [SMILES: *CC(O)COCCCCOC(=O)C=C] | 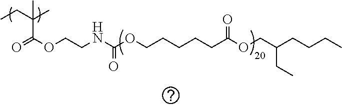 | 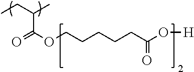 | 21000 | 78 | 0.7 | 34% | 5% | 61% |
| P-11 | 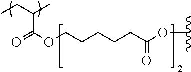 | 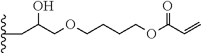 [SMILES: *CC(O)COCCCCOC(=O)C=C] | 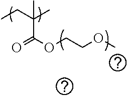 | 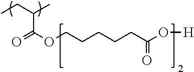 | 18000 | 78 | 0.7 | 32% | 11% | 57% |
| P-12 | 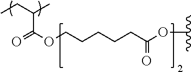 | 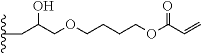 [SMILES: *CC(O)COCCCCOC(=O)C=C] | 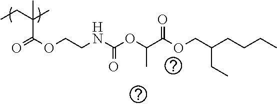 | 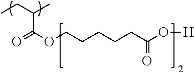 | 17000 | 78 | 0.7 | 32% | 10% | 58% |

TABLE 2

| | | | | | Characteristics | | | | | |
|---|---|---|---|---|---|---|---|---|---|---|
| | | | | | | Acid | | | | |
| | | | | | | value | C = | | | |
| | Structure | | | | | [mg- | C value | | | |
| | A-1-1 | | | | | KOH | [mmol | Molar ratio [mol%] | | |
| | | C = C group structure | A-1-2 | A-1-3 | Mw | /g] | /g] | A-1-1 | A-1-2 | A-1-3 |
| P-13 | 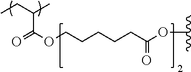 | 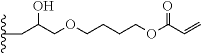 [SMILES: *CC(O)COCCCCOC(=O)C=C] | 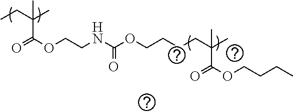 | 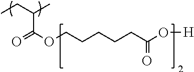 | 23000 | 78 | 0.7 | 32% | 5% | 64% |
| P-14 | 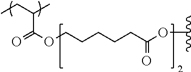 | 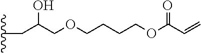 [SMILES: *CC(O)COCCCCOC(=O)C=C] | 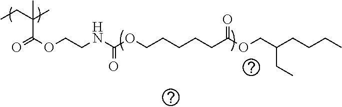 | None | 18000 | 0 | 0.7 | 68% | 42% | 0% |
| P-15 | 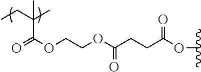 | 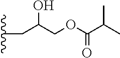 [SMILES: *CC(O)COC(=O)C(C)C] | 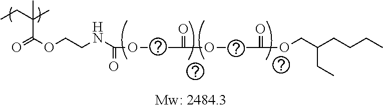 | 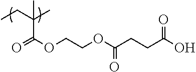 | 21000 | 78 | 0.7 | 31% | 7% | 82% |
| P-16 | 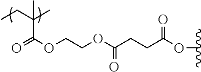 | 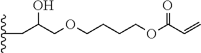 [SMILES: *CC(O)COCCCCOC(=O)C=C] | 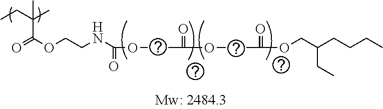 | 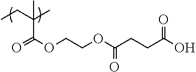 | 22000 | 78 | 0.7 | 31% | 7% | 62% |
| P-17 | 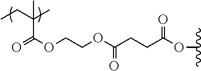 | 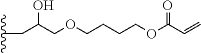 [SMILES: *CC(O)COCCCCOC(=O)C=C] | 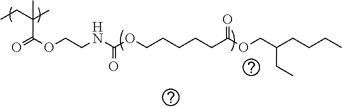 | 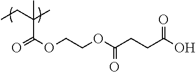 | 19000 | 78 | 0.7 | 29% | 13% | 58% |
| P-18 | 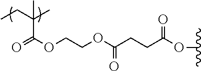 | 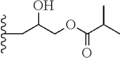 [SMILES: *CC(O)COC(=O)C(C)C] | 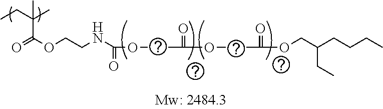 | 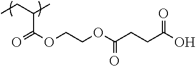 | 20000 | 78 | 0.7 | 31% | 7% | 62% |
| P-19 | 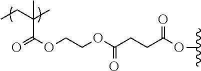 | 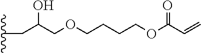 [SMILES: *CC(O)COCCCCOC(=O)C=C] | 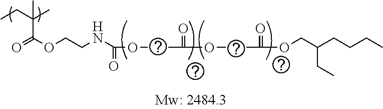 | 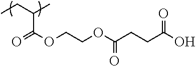 | 21000 | 78 | 0.7 | 31% | 7% | 62% |
| P-20 | 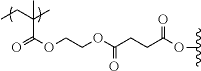 | 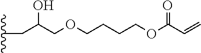 [SMILES: *CC(O)COCCCCOC(=O)C=C] | 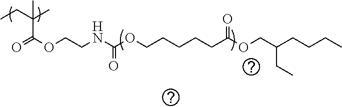 | 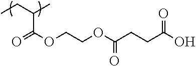 | 20000 | 78 | 0.7 | 29% | 13% | 58% |

TABLE 3

| | Structure | | | | Characteristics | | | | | |
|---|---|---|---|---|---|---|---|---|---|---|
| | A-1-1 | | | | | Acid value | C = C value | Molar ratio [mol%] | | |
| | | C = C group structure | A-1-2 | A-1-3 | Mw | [mgKOH/g] | [mmol/g] | A-1-1 | A-1-2 | A-1-3 |
| P-21 | 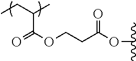 | 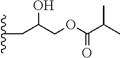 [SMILES: *CC(O)COC(=O)C(C)C] | 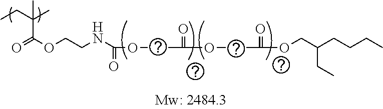 | 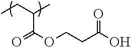 | 22000 | 78 | 0.7 | 30% | 10% | 50% |
| P-22 | 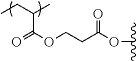 | 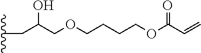 [SMILES: *CC(O)COCCCCOC(=O)C=C] | 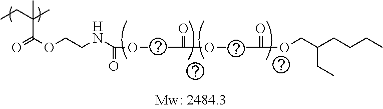 | 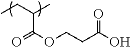 | 20000 | 0 | 0.7 | 30% | 10% | 60% |
| P-23 | 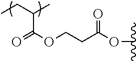 | 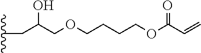 [SMILES: *CC(O)COCCCCOC(=O)C=C] | 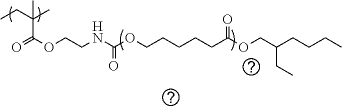 | 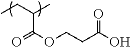 | 21000 | 78 | 0.7 | 28% | 17% | 55% |
| P-24 | 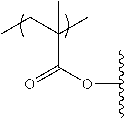 | 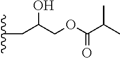 [SMILES: *CC(O)COC(=O)C(C)C] | 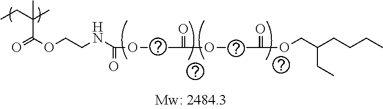 | 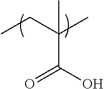 | 18000 | 78 | 0.7 | 31% | 13% | 56% |
| P-25 | 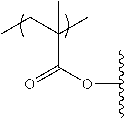 | 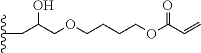 [SMILES: *CC(O)COCCCCOC(=O)C=C] | 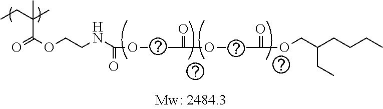 | 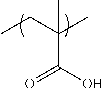 | 21000 | 78 | 0.7 | 31% | 13% | 58% |
| P-26 | 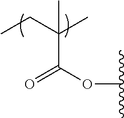 | 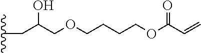 [SMILES: *CC(O)COCCCCOC(=O)C=C] | 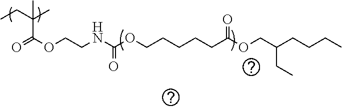 | 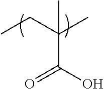 | 22000 | 78 | 0.7 | 28% | 22% | 50% |
| P-27 | 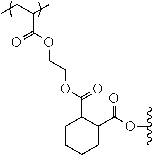 | 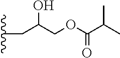 [SMILES: *CC(O)COC(=O)C(C)C] | 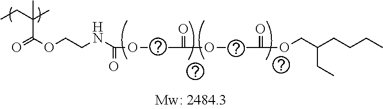 | 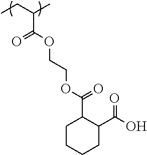 | 20000 | 78 | 0.7 | 32% | 8% | 62% |

TABLE 4

| | Structure | | | | Characteristics | | | | | |
|---|---|---|---|---|---|---|---|---|---|---|
| | A-1-1 | | | | | Acid value | C = C value | Molar ratio [mol%] | | |
| | | C = C group structure | A-1-2 | A-1-3 | Mw | [mgKOH/g] | [mmol/g] | A-1-1 | A-1-2 | A-1-3 |
| P-28 | 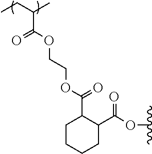 | 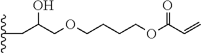 [SMILES: *CC(O)COCCCCOC(=O)C=C] | 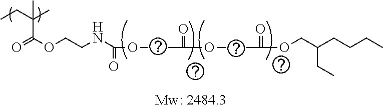 | 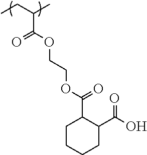 | 21000 | 78 | 0.7 | 32% | 5% | 63% |
| P-29 | 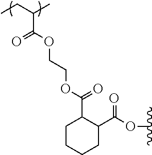 | 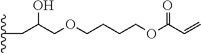 [SMILES: *CC(O)COCCCCOC(=O)C=C] | 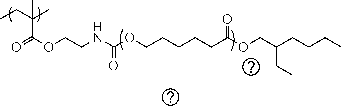 | 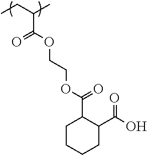 | 20000 | 0 | 0.7 | 30% | 10% | 60% |
| P-30 | 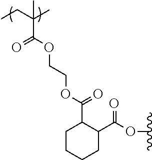 | 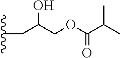 [SMILES: *CC(O)COC(=O)C(C)C] | 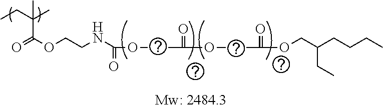 | 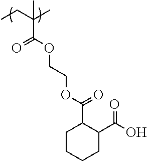 | 23000 | 78 | 0.7 | 32% | 6% | 62% |
| P-31 | 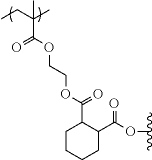 | 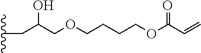 [SMILES: *CC(O)COCCCCOC(=O)C=C] | 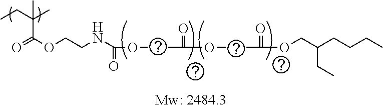 | 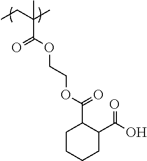 | 22000 | 78 | 0.7 | 32% | 6% | 62% |

TABLE 5

| | Structure | | | | Characteristics | | | | | |
|---|---|---|---|---|---|---|---|---|---|---|
| | A-1-1 | | | | | Acid value | C = C value | Molar ratio [mol%] | | |
| | | C = C group structure | A-1-2 | A-1-3 | Mw | [mgKOH/g] | [mmol/g] | A-1-1 | A-1-2 | A-1-3 |
| P-32 | 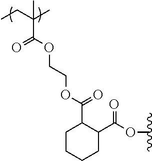 | 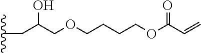 [SMILES: *CC(O)COCCCCOC(=O)C=C] | 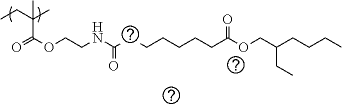 | 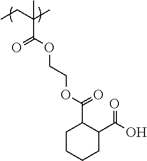 | 19000 | 78 | 0.7 | 31% | 9% | 60% |
| P-33 | 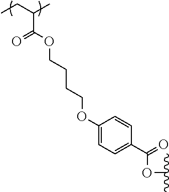 | 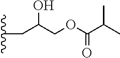 [SMILES: *CC(O)COC(=O)C(C)C] | 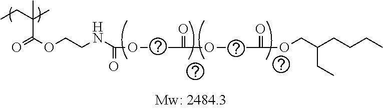 | 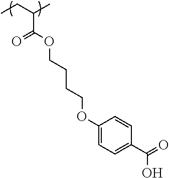 | 21000 | 0 | 0.7 | 31% | 8% | 62% |
| P-34 | 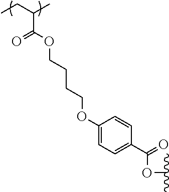 | 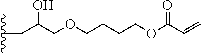 [SMILES: *CC(O)COCCCCOC(=O)C=C] | 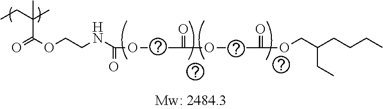 | 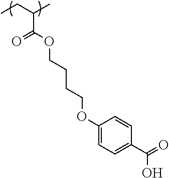 | 22000 | 78 | 0.7 | 32% | 8% | 63% |
| P-35 | 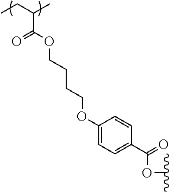 | 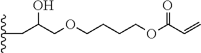 [SMILES: *CC(O)COCCCCOC(=O)C=C] | 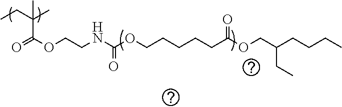 | 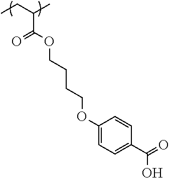 | 20000 | 78 | 0.7 | 30% | 10% | 50% |

TABLE 6

| | | | | | Characteristics | | | Molar ratio | | |
|---|---|---|---|---|---|---|---|---|---|---|
| | | | | | | Acid | C═C | [mol%] | | |
| | | | | | | value | value | A- | A- | A- |
| | A-1-1 | | | | | [mgKOH/ | [mmol/ | 1- | 1- | 1- |
| | | C═C group structure | A-1-2 | A-1-3 | Mw | g] | g] | 1 | 2 | 3 |
| P-36 | 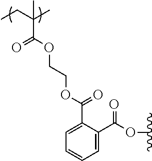 | 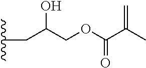 [SMILES: *CC(O)COC(=O)C(=C)C] | 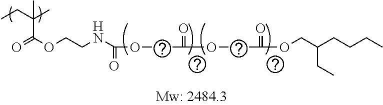 | 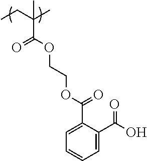 | 21000 | 78 | 0.7 | 32% | 6% | 82% |
| P-37 | 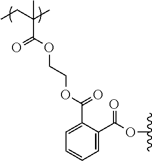 | 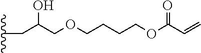 [SMILES: *CC(O)COCCCCOC(=O)C=C] | 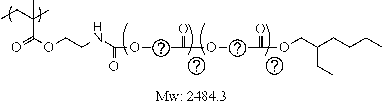 | 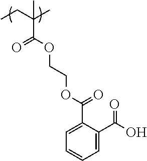 | 20000 | 78 | 0.7 | 32% | 5% | 53% |
| P-38 | 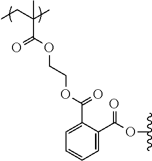 | 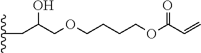 [SMILES: *CC(O)COCCCCOC(=O)C=C] | 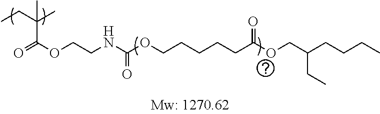 | 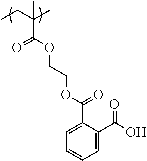 | 19000 | 78 | 0.7 | 30% | 10% | 60% |
| P-39 | 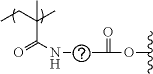 | 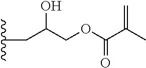 [SMILES: *CC(O)COC(=O)C(=C)C] | 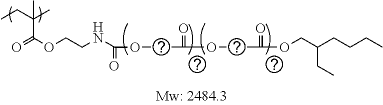 | 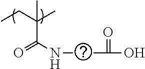 | 20000 | 78 | 0.7 | 32% | 6% | 63% |
| P-40 | 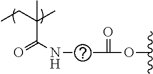 | 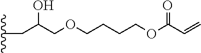 [SMILES: *CC(O)COCCCCOC(=O)C=C] | 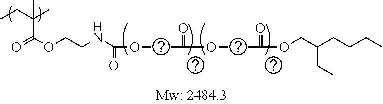 | 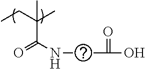 | 21000 | 78 | 0.7 | 32% | 5% | 63% |
| P-41 | 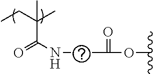 | 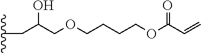 [SMILES: *CC(O)COCCCCOC(=O)C=C] | 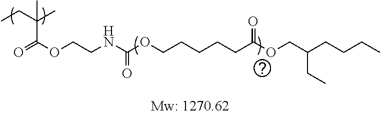 | 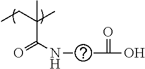 | 18000 | 78 | 0.7 | 30% | 9% | 60% |

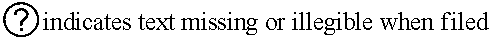

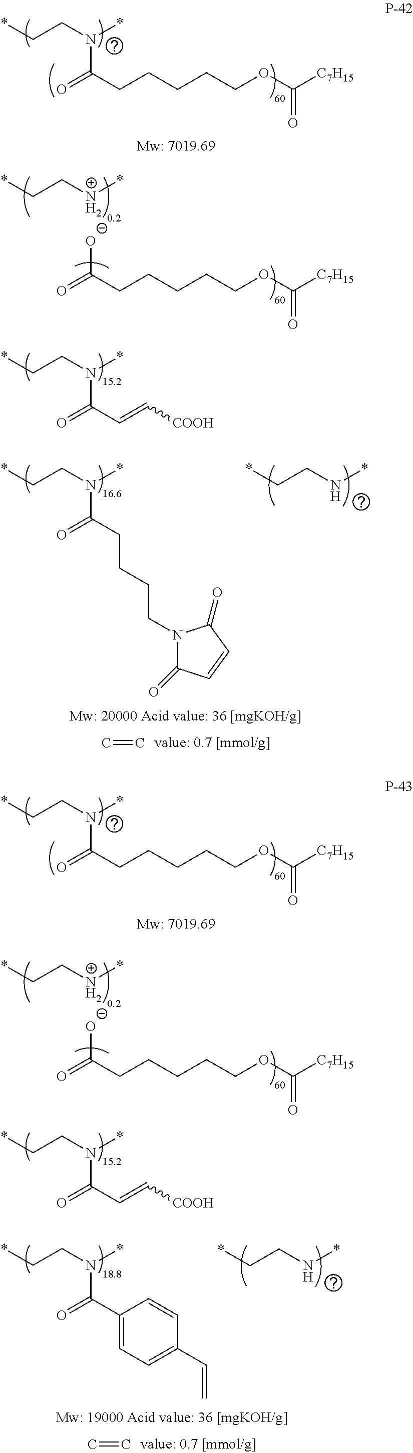

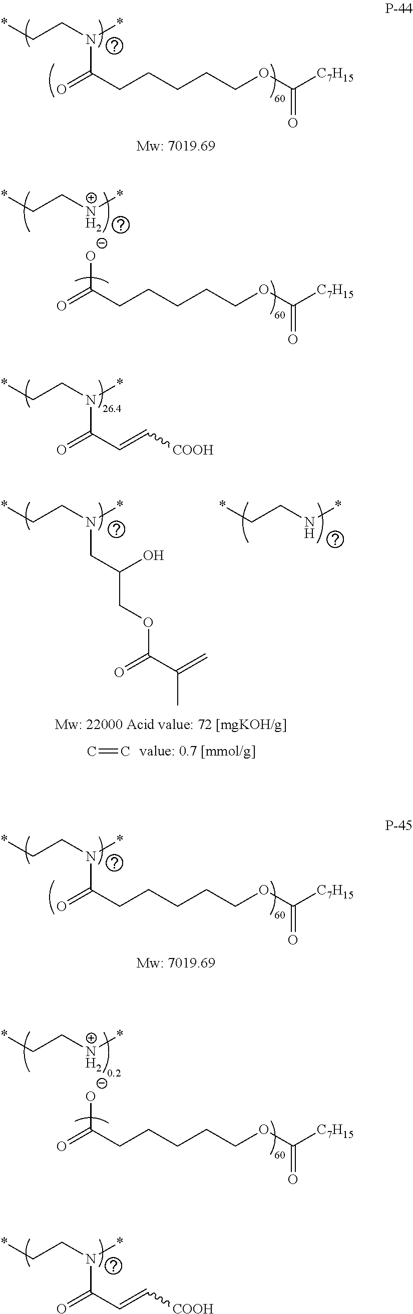

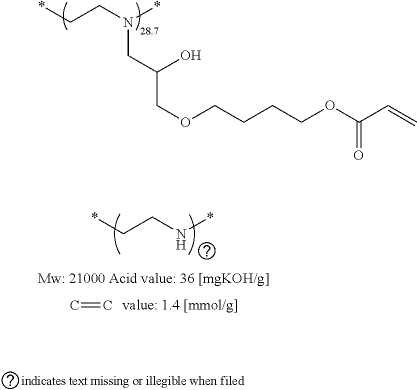

TABLE 7

| | | | | | Characteristics | | | | | |
|---|---|---|---|---|---|---|---|---|---|---|
| | | | | | | Acid | | | | |
| | | | | | | value | C = | | | |
| | Structure | | | | | [mg- | C value | | | |
| | A-1-1 | | | | | KOH | [mmol | Molar ratio [mol%] | | |
| | | C = C group structure | A-1-2 | A-1-3 | Mw | /g] | /g] | A-1-1 | A-1-2 | A-1-3 |
| P-46 | 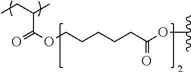 | 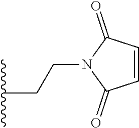 [SMILES: *CCN1C(=O)C=CC1=O] | 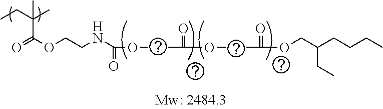 | 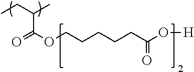 | 21000 | 78 | 0.7 | 32% | 5% | 63% |
| P-47 | 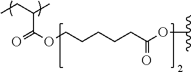 | 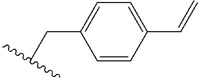 [SMILES: *Cc1ccc(C=C)cc1] | 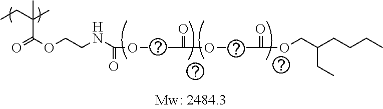 | 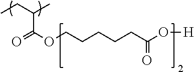 | 18000 | 78 | 0.7 | 32% | 5% | 63% |
| P-48 | 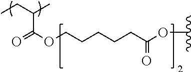 | 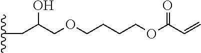 [SMILES: *CC(O)COCCCCOC(=O)C=C] | 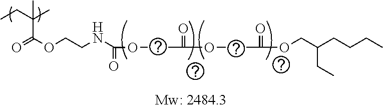 | 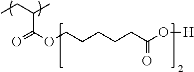 | 22000 | 24 | 0.7 | 52% | 16% | 32% |
| P-49 | 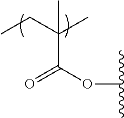 | 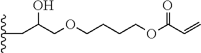 [SMILES: *CC(O)COCCCCOC(=O)C=C] | 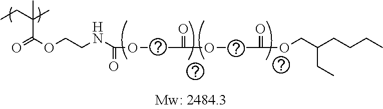 | 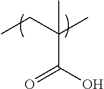 | 21000 | 104 | 0.47 | 25% | 9% | 66% |
| P-50 | 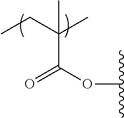 | 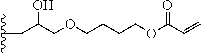 [SMILES: *CC(O)COCCCCOC(=O)C=C] | 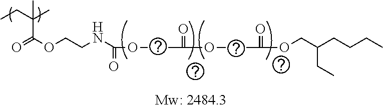 | 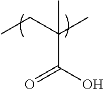 | 20000 | 158 | 0.7 | 18% | 5% | 75% |
| P-51 | 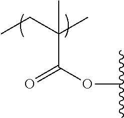 | 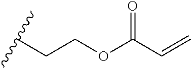 [SMILES: *CCOC(=O)C=C] | 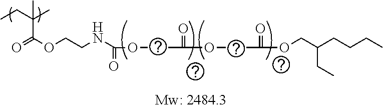 | 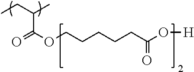 | 22000 | 78 | 1.4 | 48% | 5% | 47% |
| P-52 | 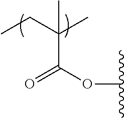 | 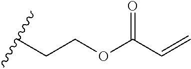 [SMILES: *CCOC(=O)C=C] | 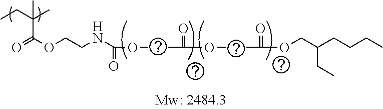 | 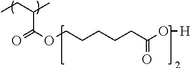 | 18000 | 78 | 2.1 | 58% | 2% | 39% |
| P-53 | 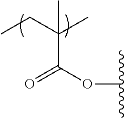 | 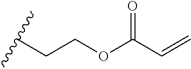 [SMILES: *CCOC(=O)C=C] | 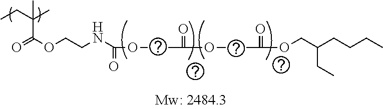 | 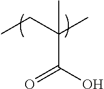 | 18000 | 78 | 3.0 | 67% | 3% | 31% |

Specific examples of the above-described compound (SP-1) include compounds having the following structures.

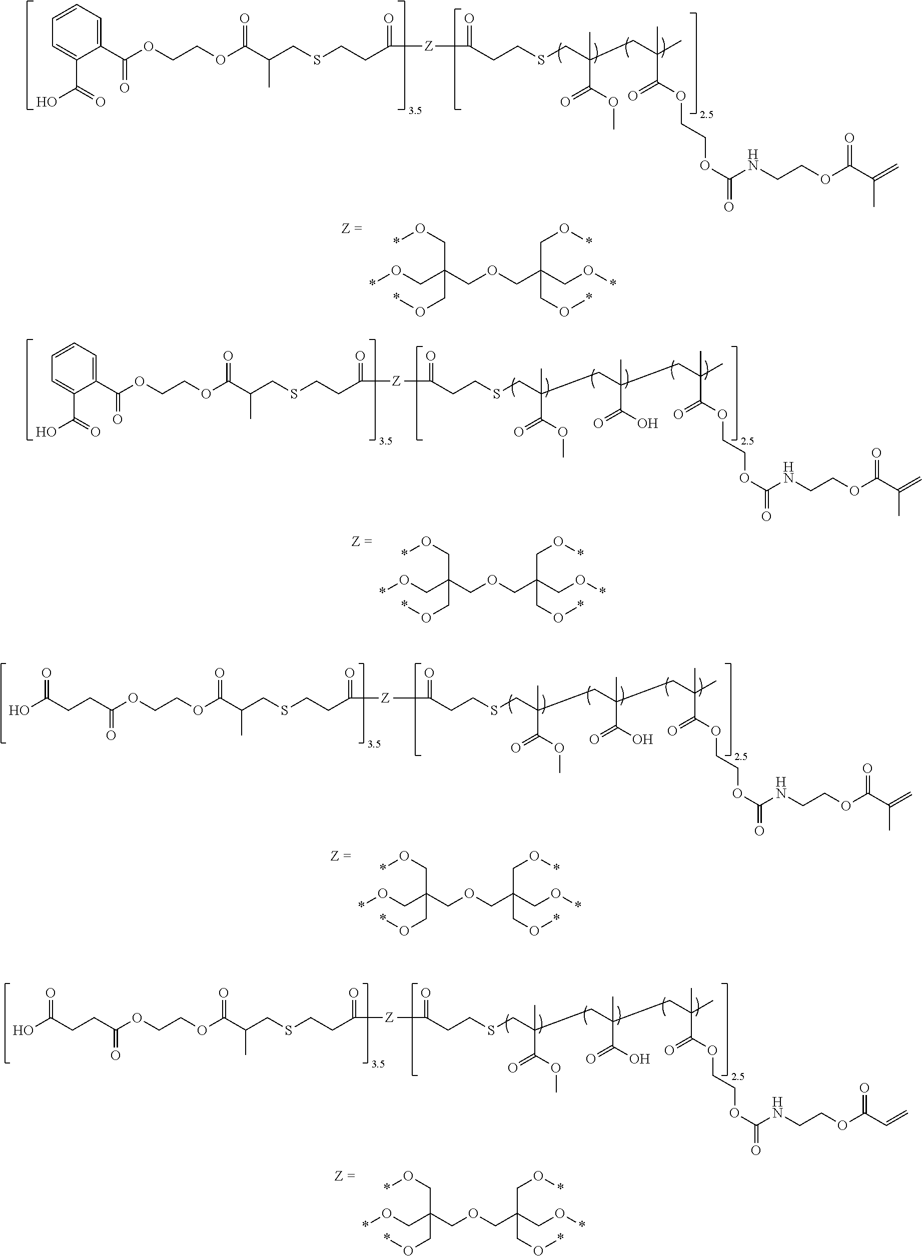

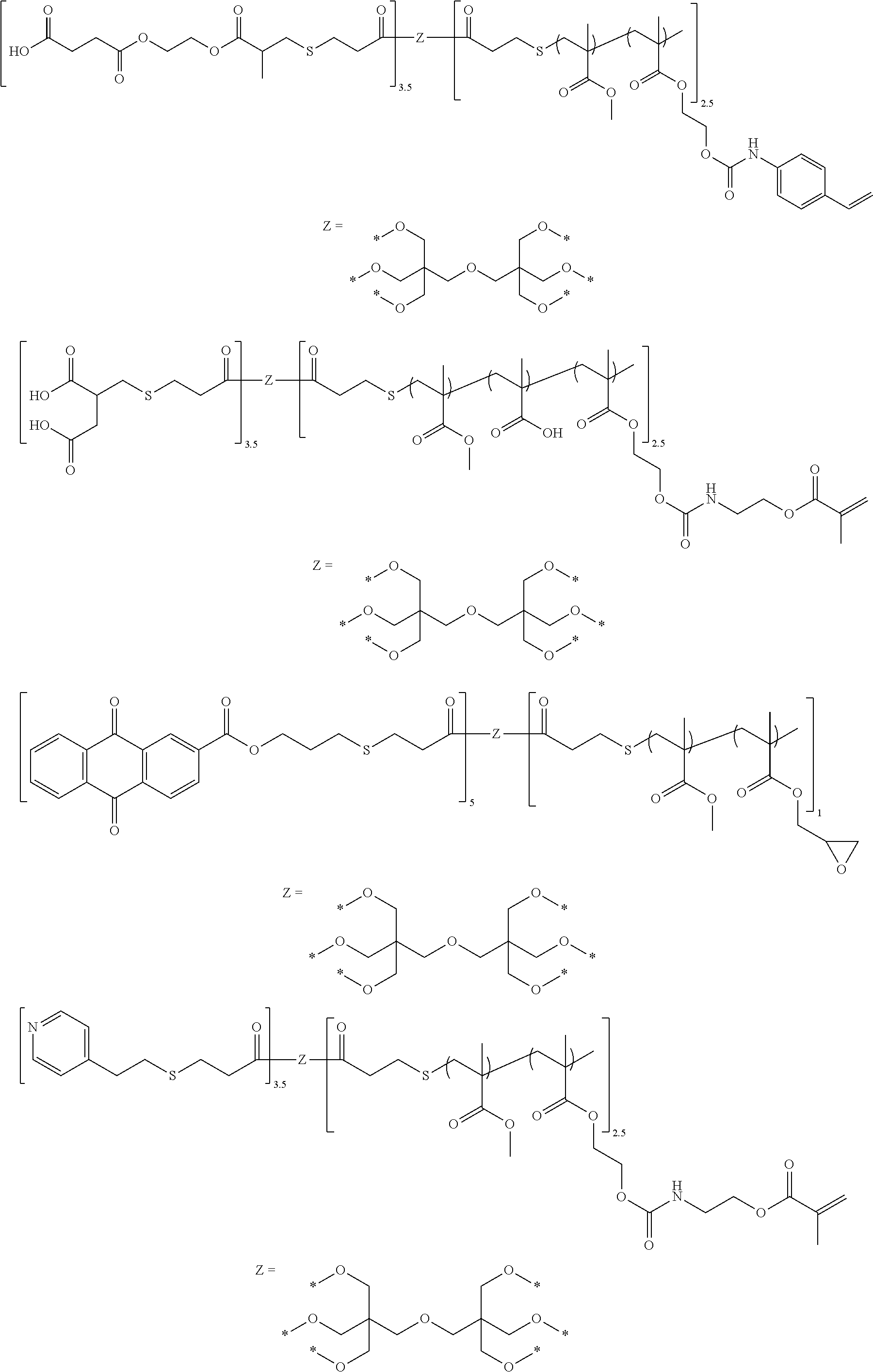

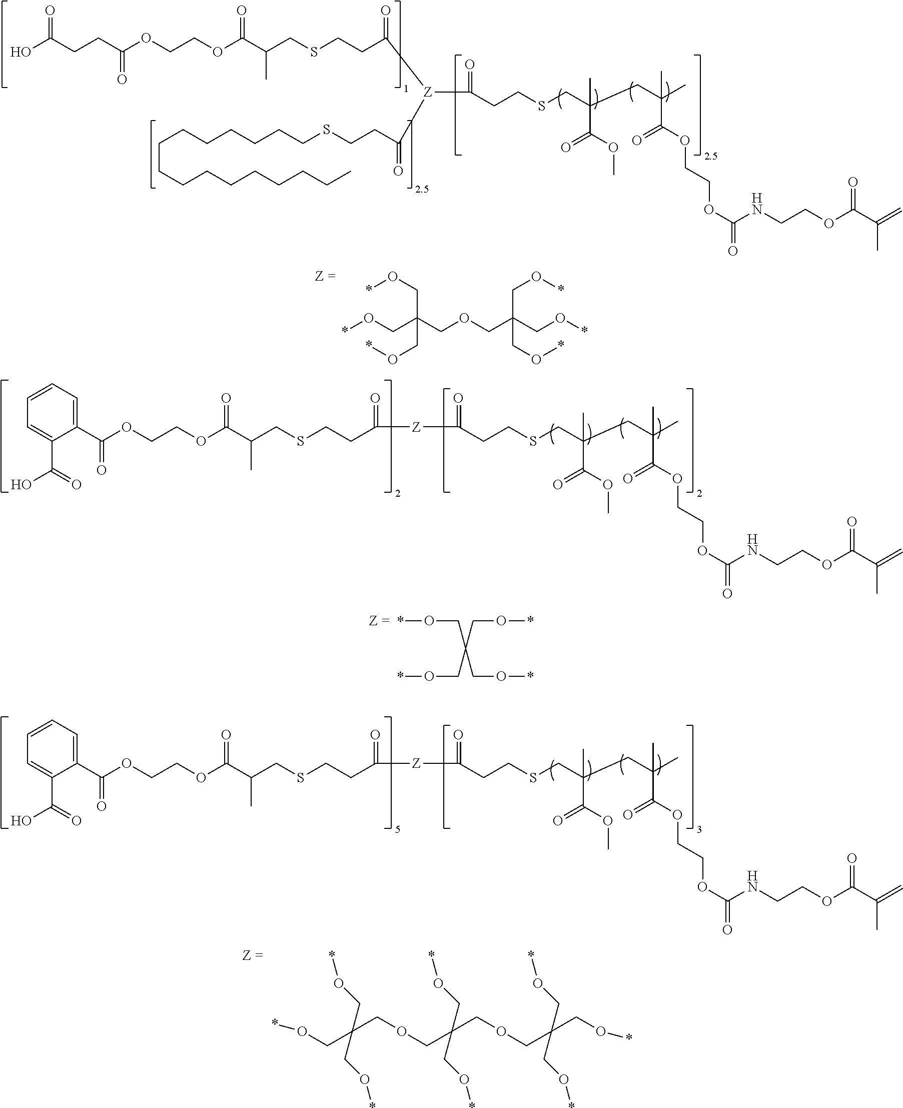

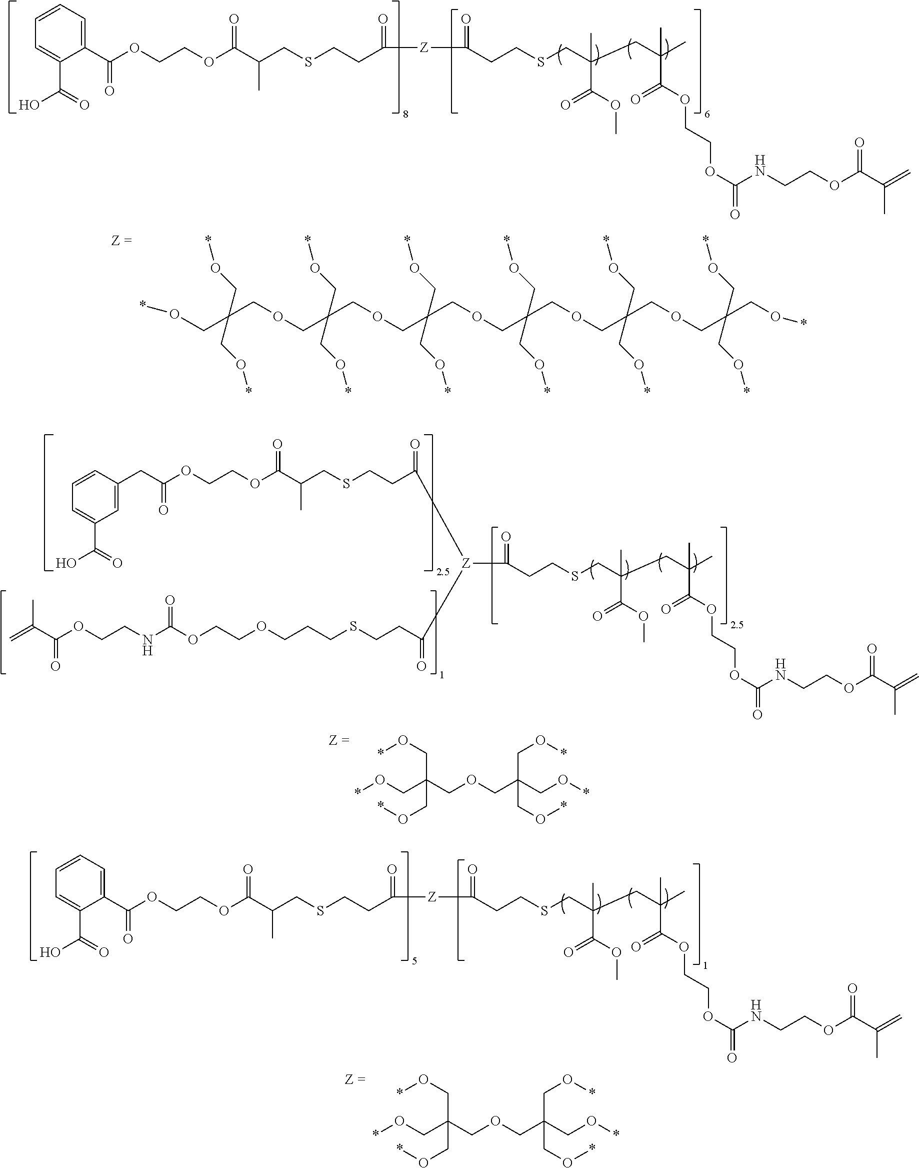

In addition, specific examples of the polymerizable resin include compounds having the following structures and compounds described in Examples later.

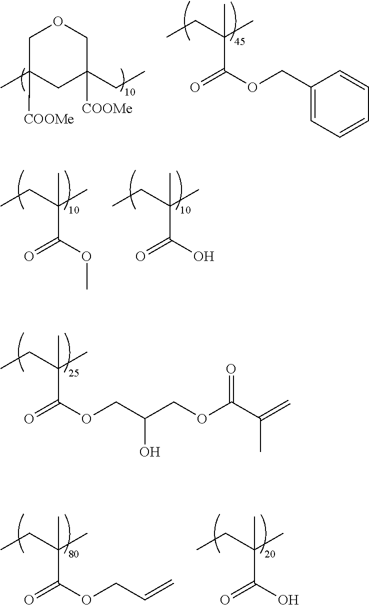

(Compound having Epoxy Group)

In the present invention, as a compound having an epoxy group (hereinafter, also referred to as an epoxy compound) which is used as the curable compound, an compound having two or more epoxy groups in one molecule is preferably used. The upper limit of epoxy groups of the epoxy compound is preferably 100 or less, more preferably 10 or less, and still more preferably 5 or less.

The epoxy equivalent (=the molecular weight of the compound having an epoxy group/the number of epoxy groups) of the epoxy compound is preferably 500 g/eq or less, more preferably 100 to 400 g/eq, and still more preferably 100 to 300 g/eq.

The epoxy compound may be a low-molecular-weight compound (for example, a molecular weight of less than 1000) or a high-molecular-weight compound (macromolecule) (for example, having a molecular weight of 1000 or more, and in a case of a polymer, having a weight-average molecular weight of 1000 or more). The molecular weight (in a case of the polymer, the weight-average molecular weight) of the epoxy compound is preferably 200 to 100000 and more preferably 500 to 50000. The upper limit of the molecular weight (in a case of the polymer, the weight-average molecular weight) is preferably 3000 or less, more preferably 2000 or less, and still more preferably 1500 or less.

As the epoxy compound, compounds described in paragraphs “0034” to “0036” of JP2013-011869A, paragraphs “0147” to “0156” of JP2014-043556A, and paragraphs “0085” to “0092” of JP2014-089408A can also be used. The contents thereof are incorporated herein by reference. With regard to a commercially available product of the epoxy compound, examples of a bisphenol A type epoxy resin include jER825, jER827, jER828, jER834, jER1001, jER1002, jER1003, jER1055, jER1007, jER1009, and jER1010 (all of which are manufactured by Mitsubishi Chemical Corporation), and EPICLON 860, EPICLON 1050, EPICLON 1051, and EPICLON 1055 (all of which are manufactured by DIC Corporation); examples of a bisphenol F type epoxy resin include jER806, jER807, jER4004, jER4005, jER4007, and jER4010 (all of which are manufactured by Mitsubishi Chemical Corporation), EPICLON 830 and EPICLON 835 (both of which are manufactured by DIC Corporation), and LCE-21 and RE-602S (both of which are manufactured by Nippon Kayaku Co., Ltd.); examples of a phenol novolak type epoxy resin include jER152, jER154, jER157S70, and jER157S65 (all of which are manufactured by Mitsubishi Chemical Corporation), and EPICLON N-740, EPICLON N-770, and EPICLON N-775 (all of which are manufactured by DIC Corporation); examples of a cresol novolak type epoxy resin include EPICLON N-660, EPICLON N-665, EPICLON N-670, EPICLON N-673, EPICLON N-680, EPICLON N-690, and EPICLON N-695 (all of which are manufactured by DIC Corporation), and EOCN-1020 (manufactured by Nippon Kayaku Co., Ltd.); and examples of an aliphatic epoxy resin include ADEKA RESIN EP-4080S, ADEKA RESIN EP-4085S, and ADEKA RESIN EP-4088S (all of which are manufactured by ADEKA Corporation), CELLOXIDE 2021P, CELLOXIDE 2081, CELLOXIDE 2083, CELLOXIDE 2085, EHPE 3150, EPOLEAD PB 3600, and EPOLEAD PB 4700 (all of which are manufactured by Daicel Corporation), and DENACOL EX-212L, DENACOL EX-214L, DENACOL EX-216L, DENACOL EX-321L, and DENACOL EX-850L (all of which are manufactured by Nagase ChemteX Corporation). Other examples thereof include ADEKA RESIN EP-4000S, ADEKA RESIN EP-4003S, ADEKA RESIN EP-4010S, and ADEKA RESIN EP-4011S (all of which manufactured by ADEKA Corporation), NC-2000, NC-3000, NC-7300, XD-1000, EPPN-501, and EPPN-502 (all of which are manufactured by ADEKA Corporation), and jER1031S (manufactured by Mitsubishi Chemical Corporation).

The content of the curable compound in the total solid content of the coloring composition is preferably 1 to 50 mass %. The lower limit is preferably 3 mass % or more, more preferably 5 mass % or more, and still more preferably 10 mass % or more. The upper limit is preferably 45 mass % or less and more preferably 40 mass % or less.

In addition, in a case where the polymerizable monomer is used as the curable compound, the content of the polymerizable monomer in the total solid content of the coloring composition is preferably 0.1 to 40 mass %. The lower limit is preferably 1 mass % or more and more preferably 2 mass % or more. The upper limit is preferably 30 mass % or less, more preferably 20 mass % or less, and still more preferably 10 mass % or less.

In addition, in a case where the polymerizable resin is used as the curable compound, the content of the polymerizable resin in the total solid content of the coloring composition is preferably 1 to 50 mass %. The lower limit is preferably 3 mass % or more, more preferably 5 mass % or more, and still more preferably 10 mass % or more. The upper limit is preferably 45 mass % or less and more preferably 40 mass % or less.

In addition, the total content of the polymerizable monomer and the polymerizable resin in the total solid content of the coloring composition is preferably 1 to 50 mass %. The lower limit is preferably 3 mass % or more, more preferably 5 mass % or more, and still more preferably 10 mass % or more. The upper limit is preferably 45 mass % or less and more preferably 40 mass % or less. In addition, the content of the polymerizable resin in the total content of the polymerizable monomer and the polymerizable resin is preferably 70 mass % or more and more preferably 80 mass % or more.

In addition, in a case where the epoxy compound is used as the curable compound, the content of the epoxy compound in the total solid content of the coloring composition is preferably 0.1 to 40 mass %. The lower limit is, for example, more preferably 1 mass % or more and still more preferably 2 mass % or more. The upper limit is, for example, more preferably 30 mass % or less and still more preferably 20 mass % or less. The epoxy compound may be used singly or in combination of two or more thereof. In addition, in a case where the polymerizable compound and the compound having an epoxy group are used in combination, the proportion (mass ratio) between the compounds is preferably the mass of the polymerizable compound:the mass of the compound having an epoxy group=100:1 to 100:400, more preferably 100:1 to 100:100, and still more preferably 100:1 to 100:50.

A preferred aspect of the coloring composition according to the embodiment of the present invention is as follows.

An aspect that the coloring composition includes a monomer (polymerizable monomer) having an ethylenically unsaturated group, and a resin, in which a ratio M¹/B¹ of a mass M¹ of the monomer (polymerizable monomer) having an ethylenically unsaturated group included in the coloring composition to a mass B¹ of the resin included in the coloring composition is 0.35 or less, preferably 0.25 or less, and more preferably 0.15 or less.

According to the coloring composition of this aspect, a cured film having more excellent moisture resistance can be formed. Furthermore, it is also possible to suppress film shrinkage in a case of forming a cured film. In particular, in a case where the polymerizable resin is used as the resin, the above-described effects are obtained more significantly. The lower limit of the value of M/B¹ described above is preferably 0.01 or more, more preferably 0.04 or more, and still more preferably 0.07 or more. The mass B¹ of the resin is the total content of the polymerizable resin and other resins described later. In a case where the coloring composition does not include other resins, the mass B¹ of the resin is the mass of the polymerizable resin. In addition, in a case where the coloring composition does not include the polymerizable resin, the mass B¹ of the resin is the mass of other resins.

In addition, in the above-described aspect, the total content of the polymerizable monomer and the resin in the total solid content of the coloring composition is preferably 1 to 50 mass %. The lower limit is preferably 3 mass % or more, more preferably 5 mass % or more, and still more preferably 10 mass % or more. The upper limit is preferably 45 mass % or less and more preferably 40 mass % or less.

<<Other Resins>>

The coloring composition according to the embodiment of the present invention can further contain a resin including no curable group (hereinafter, also referred to as other resins). The other resins are blended in, for example, an application for dispersing particles such as a pigment in a composition or an application as a binder. Mainly, a resin which is used for dispersing particles such as a pigment is also referred to as a dispersant. However, such applications of the resin are merely exemplary, and the resin can also be used for other purposes in addition to such applications.

The weight-average molecular weight (Mw) of the other resins is preferably 2000 to 2000000. The upper limit is preferably 1000000 or less and more preferably 500000 or less. The lower limit is preferably 3000 or more and more preferably 5000 or more.

Examples of the other resins include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof.

The other resins may have an acid group. Examples of the acid group include a carboxyl group, a phosphoric acid group, a sulfo group, and a phenolic hydroxy group, and a carboxyl group is preferable. Among these acid groups, one kind may be used alone, or two or more kinds may be used in combination. The resin having an acid group can also be used as an alkali-soluble resin.

The resin having an acid group is preferably a polymer having a carboxyl group in the side chain. Specific examples thereof include methacrylic acid copolymers, acrylic acid copolymers, itaconic acid copolymers, crotonic acid copolymers, maleic acid copolymers, partially esterified maleic acid copolymers, alkali-soluble phenol resins such as novolak resin, acidic cellulose derivatives having a carboxyl group in the side chain, and resins in which an acid anhydride is added to a polymer having a hydroxy group. In particular, a copolymer of a (meth)acrylic acid and another monomer copolymerizable therewith is suitable as the alkali-soluble resin. Examples of another monomer copolymerizable with the (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, and glycidyl (meth)acrylate. Examples of the vinyl compound include styrene, α-methylstyrene, vinyltoluene, acrylonitrile, vinyl acetate, N-vinylpyrrolidone, a polystyrene macromonomer, and a polymethyl methacrylate macromonomer. In addition, examples of other monomer include the N-position-substituted maleimide monomers described in JP1998-300922A (JP-H10-300922A), such as N-phenylmaleimide and N-cyclohexylmaleimide. Such other monomers copolymerizable with (meth)acrylic acids may be used singly or in combination of two or more kinds thereof.

As the resin having an acid group, a benzyl (meth)acrylate/(meth)acrylic acid copolymer, a benzyl (meth)acrylate/(meth)acrylic acid/2-hydroxyethyl (meth)acrylate copolymer, or a multicomponent copolymer formed of benzyl (meth)acrylate/(meth)acrylic acid/other monomers can be preferably used. In addition, a copolymer obtained by copolymerizing 2-hydroxyethyl (meth)acrylate, the 2-hydroxypropyl (meth)acrylate/polystyrene macromonomer/benzyl methacrylate/methacrylic acid copolymer described in JP1995-140654A (JP-H07-140654A), a 2-hydroxy-3-phenoxypropylacrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer, and the like can also be preferably used.

The resin having an acid group is also preferably a polymer including a repeating unit derived from a monomer component having the ether dimer.

The resin having an acid group may include a repeating unit which is derived from a compound represented by Formula (X).

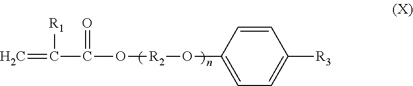

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

With regard to the resin having an acid group, reference can be made to the description in paragraphs “0558” to “0571” of JP2012-208494A (paragraphs “0685” to “0700” of the corresponding US2012/0235099A) and the description in paragraphs “0076” to “0099” of JP2012-198408A, the contents of which are incorporated herein by reference. In addition, as the resin having an acid group, a commercially available product can also be used.

The acid value of the resin having an acid group is preferably 30 to 200 mgKOH/g. The lower limit is preferably 50 mgKOH/g or more and more preferably 70 mgKOH/g or more. The upper limit is preferably 150 mgKOH/g or less and more preferably 120 mgKOH/g or less.

The coloring composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total content of the acid group and the basic group is 100 mol %. The basic group in the basic dispersant is preferably an amino group.

It is preferable that the resin used as a dispersant includes a repeating unit having an acid group. By the resin, which is used as the dispersant, including the repeating unit having an acid group, in a case where a pattern is formed using a photolithography method, the amount of residues generated in a base of a pixel can be reduced.

It is also preferable that the resin used as a dispersant is a graft resin. Examples of the graft resin include the resin having the repeating unit represented by Formula (A-1-2), which is described in the section of polymerizable resin described above. With regard to details of the graft resin, reference can be made to the description in paragraphs “0025” to “0094” of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs “0102” to “0166” of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraphs “0196” to “0209” of JP2013-043962A.

It is also preferable that the resin used as a dispersant is a resin (hereinafter, also referred to as a resin Ac) having an aromatic carboxyl group. The resin Ac may include the aromatic carboxyl group in the main chain of the repeating unit, or in the side chain of the repeating unit, but it is preferable that the aromatic carboxyl group is included in the main chain of the repeating unit. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (b-101) or a repeating unit represented by Formula (b-110).

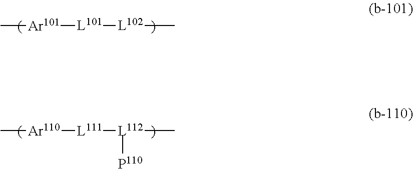

In Formula (b-101), Ar¹⁰¹ represents a group including an aromatic carboxyl group, L¹⁰¹ represents —COO— or —CONH—, and L¹⁰² represents a divalent linking group.

In Formula (b-110), Ar¹¹⁰ represents a group including an aromatic carboxyl group, L¹¹¹ represents —COO— or —CONH—, L¹¹² represents a trivalent linking group, and P¹¹⁰ represents a polymer chain.

Specific examples of the resin Ac include compounds described in JP2017-156652A, the contents of which are incorporated herein by reference.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. In addition, pigment dispersants described in paragraphs “0041” to “0130” of JP2014-130338A can also be used, the contents of which are incorporated herein by reference. In addition, as the dispersant, compounds described in JP2018-150498A, JP2017-100116A, JP2017-100115A, JP2016-108520A, JP2016-108519A, and JP2015-232105A may be used. The resin described as a dispersant can be used for an application other than the dispersant. For example, the resin can also be used as a binder.

In a case where the coloring composition according to the embodiment of the present invention includes other resins, the content of the other resins in the total solid content of the coloring composition according to the embodiment of the present invention is preferably 30 mass % or less, more preferably 20 mass % or less, and still more preferably 10 mass % or less. In addition, the coloring composition according to the embodiment of the present invention may substantially include no other resins. The case where the coloring composition according to the embodiment of the present invention substantially includes no other resins means that the content of the other resins in the total solid content of the coloring composition according to the embodiment of the present invention is preferably 0.1 mass % or less, more preferably 0.05 mass % or less, and particularly preferably 0 mass %.

In addition, the total content of the above-described curable compound and the other resins is preferably 1 to 50 mass % with respect to the total solid content of the coloring composition according to the embodiment of the present invention. The lower limit is preferably 3 mass % or more, more preferably 5 mass % or more, and still more preferably 10 mass % or more. The upper limit is preferably 45 mass % or less and more preferably 40 mass % or less.

<<Photopolymerization Initiator>>

It is preferable that the coloring composition according to the embodiment of the present invention includes a photopolymerization initiator. In particular, in a case where the compound having an ethylenically unsaturated group is used as the curable compound, it is preferable that the coloring composition according to the embodiment of the present invention further includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. In addition, as the photopolymerization initiator, compounds described in paragraphs “0065” to “0111” of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF). Examples of a commercially available product of the α-aminoketone compound include IRGACURE-907, IRGACURE-369, IRGACURE-379, and IRGACURE-379EG (all of which are manufactured by BASF). Examples of a commercially available product of the acylphosphine compound include RGACURE-819 and DAROCUR-TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in W2015/152153A, the compounds described in WO2017/051680A, the compounds described in JP2017-198865A, and the compounds described in paragraphs “0025” to “0038” of W2017/164127A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one,3-(4-toluenesulfonyloxy)iminobutane-2-one, and 2-ethoxycarbonyloxyimino-1-phenylpropane-1-one. Examples of a commercially available product thereof include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A. The content thereof is incorporated herein by reference.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The content thereof is incorporated herein by reference.

In the present invention, an oxime compound having a nitro group can be used as the photopolymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A. In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

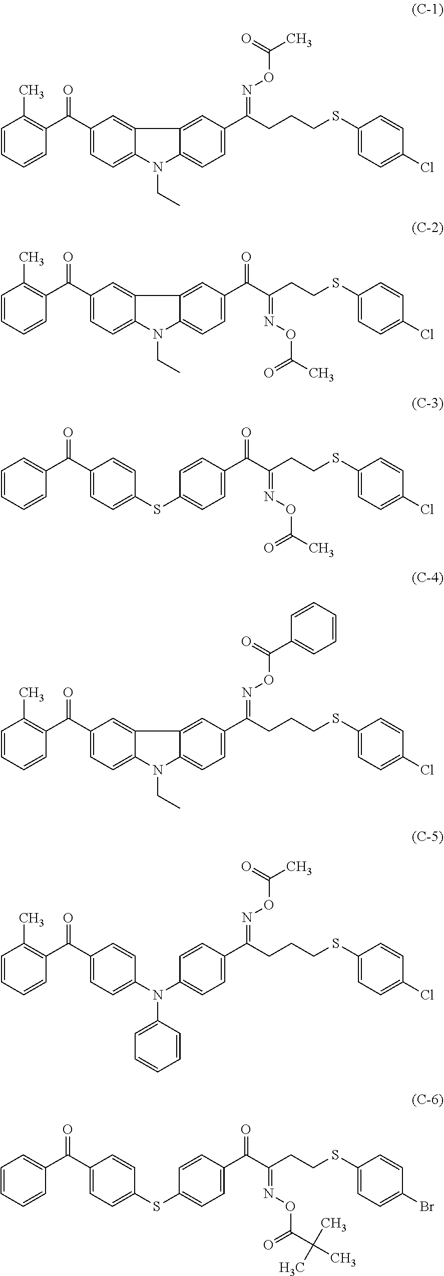 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

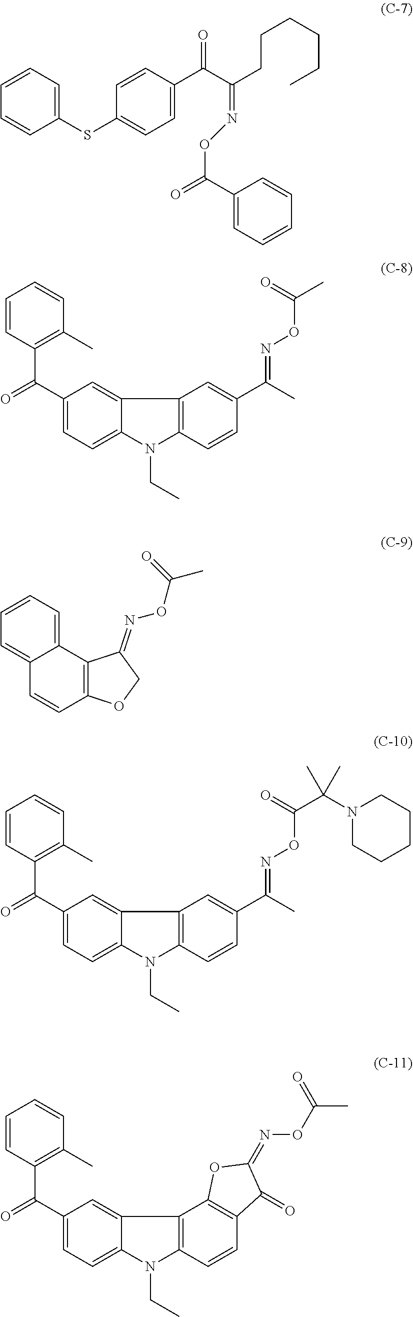

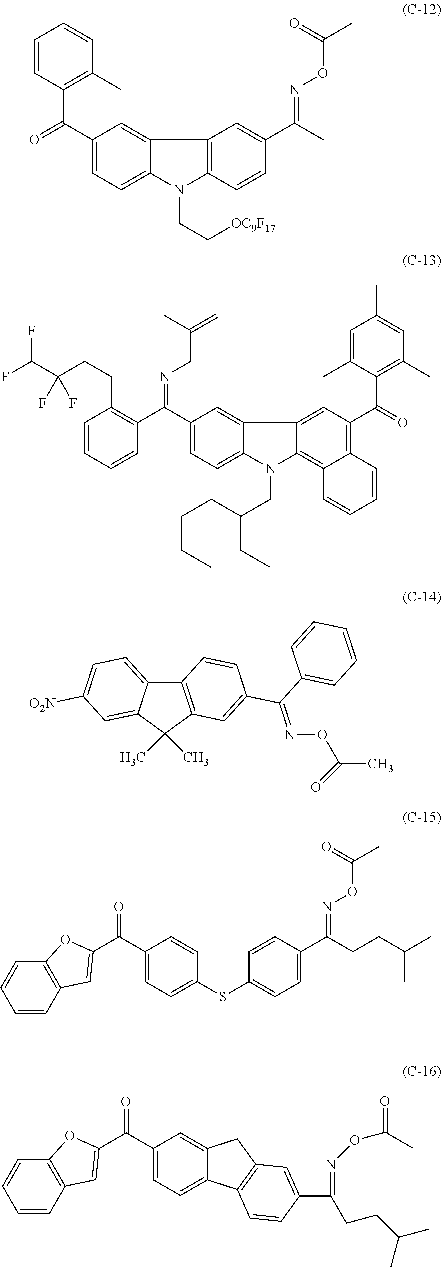

The oxime compound is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, the molar absorption coefficient of the oxime compound at a wavelength of 365 nm or at a wavelength of 405 nm is preferably high, more preferably 1,000 to 300,000, still more preferably 2,000 to 300,000, and particularly preferably 5,000 to 200,000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or more functional photoradical polymerization initiator include dimers of the oxime compounds described in JP2010-527339A, JP2011-524436A, WO2015/004565A, paragraphs “0407” to “0412” of JP2016-532675A, and paragraphs “0039” to “0055” of WO2017/033680A; the compound (E) and compound (G) described in JP2013-522445A; Cmpd 1 to 7 described in WO016/034963A; the oxime ester photoinitiators described in paragraph “0007” of JP2017-523465A; the photoinitiators described in paragraphs “0020” to “0033” of JP2017-167399A; the photopolymerization initiator (A) described in paragraphs “0017” to “0026” of JP2017-151342A; and the oxime ester photoinitiators described in JP6469669.

The content of the photopolymerization initiator in the total solid content of the coloring composition according to the embodiment of the present invention is preferably 0.1 to 30 mass %. The lower limit is preferably 0.5 mass % or more and more preferably 1 mass % or more. The upper limit is preferably 20 mass % or less and more preferably 15 mass % or less. In the coloring composition according to the embodiment of the present invention, the photopolymerization initiator may be used singly or in combination of two or more kinds thereof. In a case where two or more kinds thereof are used, the total content thereof is preferably within the above-described range.

<<Pigment Derivative>>

The coloring composition according to the embodiment of the present invention can contain a pigment derivative. Examples of the pigment derivative include a compound having a structure in which a part of the pigment is replaced with an acid group or a basic group. As the pigment derivative, compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraph “0082” of WO2017/038252A, paragraph “0171” of JP2015-151530A, and the like can be used, the contents of which are incorporated herein by reference.

The content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is within the above-described range, dispersibility of the pigment can be enhanced, and aggregation of the pigment can be efficiently suppressed. The pigment derivative may be used singly or in combination of two or more kinds thereof. In a case of using two or more kinds thereof, the total content thereof is preferably within the above-described range.

<<Silane Coupling Agent>>

The coloring composition according to the embodiment of the present invention can contain a silane coupling agent. According to this aspect, adhesiveness of a cured film to be obtained with a support can be improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraphs “0018” to “0036” of JP2009-288703A and the compounds described in paragraphs “0056” to “0066” of JP2009-242604A, the contents of which are incorporated herein by reference.

The content of the silane coupling agent in the total solid content of the coloring composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

<<Solvent>>

The coloring composition according to the embodiment of the present invention can contain a solvent. Examples of the solvent include an organic solvent. Basically, the solvent is not particularly limited as long as it satisfies the solubility of the respective components and the application properties of the coloring composition. Examples of the organic solvent include an ester solvent, a ketone solvent, an alcohol solvent, an amide solvent, an ether solvent, and a hydrocarbon solvent. With regard to details thereof, reference can be made to the description in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, a solvent having a low metal content is preferably used. For example, the metal content in the solvent is preferably 10 mass parts per billion (ppb) or less. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the solvent in the coloring composition is preferably 10 to 95 mass %, more preferably 20 to 90 mass %, and still more preferably 30 to 90 mass %.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or coloring composition produced by mixing these compounds.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, t-butyl catechol, benzoquinone, 4,4′-thiobis(3-methyl-6-tert-butylphenol), 2,2′-methylenebis(4-methyl-6-t-butylphenol), and an N-nitrosophenylhydroxyamine salt (an ammonium salt, a cerous salt, or the like). Among these, p-methoxyphenol is preferable. The content of the polymerization inhibitor in the total solid content of the coloring composition is preferably 0.0001 to 5 mass %.

<<Surfactant>>

The coloring composition according to the embodiment of the present invention can contain a surfactant. As the surfactant, various surfactants such as a fluorine surfactant, a nonionic surfactant, a cationic surfactant, an anionic surfactant, or a silicon-based surfactant can be used. With regard to the surfactant, reference can be made to the description in paragraphs “0238” to “0245” of WO2015/166779A, the contents of which are incorporated herein by reference.

In the present invention, it is preferable that the surfactant is a fluorine surfactant. By containing a fluorine surfactant in the coloring composition, liquid characteristics (particularly, fluidity) are further improved, and liquid saving properties can be further improved. In addition, it is possible to form a film with a small thickness unevenness.

The fluorine content in the fluorine surfactant is preferably 3 to 40 mass %, more preferably 5 to 30 mass %, and particularly preferably 7 to 25 mass %. The fluorine surfactant in which the fluorine content is within the above-described range is effective in terms of the evenness of the thickness of the coating film or liquid saving properties and the solubility of the surfactant in the coloring composition is also good.

Examples of the fluorine surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine atom-containing vinyl ether compound having a fluorinated alkyl group or a fluorinated alkylene ether group, and a hydrophilic vinyl ether compound can be preferably used. With regard to such a fluorine surfactant, reference can be made to the description in JP2016-216602A, the contents of which are incorporated herein by reference.

As the fluorine surfactant, a block polymer can also be used. Examples thereof include compounds described in JP2011-089090A. As the fluorine surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. For example, the following compound can also be used as the fluorine surfactant used in the present invention.

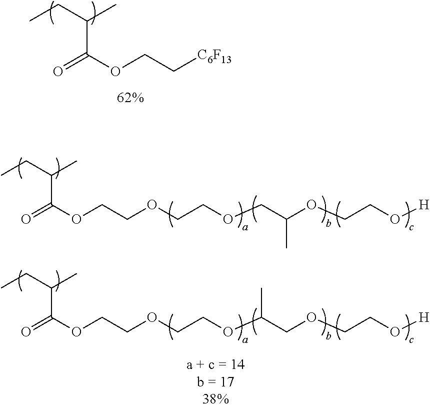

The weight-average molecular weight of the compound is preferably 3000 to 50000 and, for example, 14000. In the compound, “%” representing the proportion of a repeating unit is mol %.

In addition, as the fluorine surfactant, a fluorine-containing polymer including a repeating unit having an ethylenically unsaturated group in the side chain can be used. Specific examples thereof include compounds described in paragraphs “0050” to “0090” and paragraphs “0289” to “0295” of JP2010-164965A, and for example, MEGAFACE RS-101, RS-102, RS-718K, and RS-72-K manufactured by DIC Corporation. As the fluorine surfactant, compounds described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

The content of the surfactant in the total solid content of the coloring composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used.

The content of the ultraviolet absorber in the total solid content of the coloring composition is preferably 0.01 to 10 mass % and more preferably 0.01 to 5 mass %. In the present invention, the ultraviolet absorber may be used singly or in combination of two or more kinds thereof. In a case where two or more kinds thereof are used, the total content thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraphs “0023” to “0048” of JP6268967B can also be used.

The content of the antioxidant in the total solid content of the coloring composition is preferably 0.01 to 20 mass % and more preferably 0.3 to 15 mass %. In the present invention, the antioxidant may be used singly or in combination of two or more kinds thereof. In a case where two or more kinds thereof are used, the total content thereof is preferably within the above-described range.

<<Other Components>>

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraphs “0183” and later of JP2012-003225A (corresponding to paragraph “0237” of US2013/0034812A) and paragraphs “0101” to “0104” and “0107” to “0109” of JP2008-250074A, the content of which is incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

In addition, in order to adjust the refractive index of the film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure, and in this case, the core portion may be hollow.

In addition, the coloring composition according to the embodiment of the present invention may include a light-resistance improver. Examples of the light-resistance improver include the compounds described in paragraphs “0036” and “0037” of JP2017-198787A, the compounds described in paragraphs “0029” to “0034” of JP2017-146350A, the compounds described in paragraphs “0036” and “0037”, and “0049” to “0052” of JP2017-129774A, the compounds described in paragraphs “0031” to “0034”, “0058”, and “0059” of JP2017-129674A, the compounds described in paragraphs “0036” and “0037”, and “0051” to “0054” of JP2017-122803A, the compounds described in paragraphs “0025” to “0039” of WO2017/164127A, the compounds described in paragraphs “0034” to “0047” of JP2017-186546A, the compounds described in paragraphs “0019” to “0041” of JP2015-025116A, the compounds described in paragraphs “0101” to “0125” of JP2012-145604A, the compounds described in paragraphs “0018” to “0021” of JP2012-103475A, the compounds described in paragraphs “0015” to “0018” of JP2011-257591A, the compounds described in paragraphs “0017” to “0021” of JP2011-191483A, the compounds described in paragraphs “0108” to “0116” of JP2011-145668A, and the compounds described in paragraphs “0103” to “0153” of JP2011-253174A.

For example, in a case where a film is formed by application, the viscosity (25° C.) of the coloring composition according to the embodiment of the present invention is preferably 1 to 100 mPa×s. The lower limit is more preferably 2 mPa×s or more and still more preferably 3 mPa×s or more. The upper limit is more preferably 50 mPa×s or less, still more preferably 30 mPa×s or less, and particularly preferably 15 mPa×s or less.

In the coloring composition according to the embodiment of the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described free metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the coloring composition according to the embodiment of the present invention, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of halogen include F, Cl, Br, I, and anions thereof. Examples of a method for reducing free metals and halogens in the coloring composition include washing with ion exchange water, filtration, ultrafiltration, and purification with an ion exchange resin.

It is also preferable that the coloring composition according to the embodiment of the present invention does not include terephthalic acid ester.

<Storage Container>

A storage container of the coloring composition according to the embodiment of the present invention is not particularly limited, and a known storage container can be used. In addition, as the storage container, in order to suppress infiltration of impurities into the raw materials or the coloring composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351A.

In addition, for the coloring composition according to the embodiment of the present invention or a composition used for producing an image sensor, for the purpose of preventing metal elution from the container inner wall, improving storage stability of the composition, and suppressing the alteration of components, it is also preferable that the inner wall of the storage container is formed of glass, stainless steel, or the like.

<Method for Producing Coloring Composition>

The coloring composition according to the embodiment of the present invention can be produced by mixing the above-described components with each other. During the production of the coloring composition, all the components may be dissolved or dispersed in a solvent at the same time to produce the coloring composition. Optionally, two or more solutions or dispersion liquids in which the respective components are appropriately blended may be prepared, and the solutions or dispersion liquids may be mixed with each other during use (during application) to produce the coloring composition.

In addition, in the production of the coloring composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph “0022” of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the production of the coloring composition, it is preferable that the coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 m, more preferably 0.01 to 3.0 m, and still more preferably 0.05 to 0.5 m. In a case where the pore size of the filter is within the above-described range, fine foreign matters can be more reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Cured Film>

The cured film according to an embodiment of the present invention is a cured film obtained from the above-described coloring composition according to the embodiment of the present invention. The cured film according to the embodiment of the present invention can be used for a color filter or the like. Specifically, the cured film according to the embodiment of the present invention can be preferably used as a colored layer (pixel) of a color filter, and more specifically, the cured film according to the embodiment of the present invention can be preferably used as a red-colored layer (red pixel) of a color filter. The thickness of the cured film according to the embodiment of the present invention can be appropriately adjusted according to the purpose. For example, the thickness of the film is preferably 20 m or less, more preferably 10 m or less, and still more preferably 5 m or less. The lower limit of the thickness of the film is preferably 0.1 m or more, more preferably 0.2 m or more, and still more preferably 0.3 m or more.

<Color Filter>

Next, the color filter according to an embodiment of the present invention will be described. The color filter according to the embodiment of the present invention has the cured film according to the embodiment of the present invention. More preferably, the color filter according to the embodiment of the present invention has the cured film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the cured film according to the embodiment of the present invention can be appropriately adjusted depending on the purposes. The thickness of the film is preferably 20 m or less, more preferably 10 m or less, and still more preferably 5 m or less. The lower limit of the thickness of the film is preferably 0.1 m or more, more preferably 0.2 m or more, and still more preferably 0.3 m or more.

In the color filter according to the embodiment of the present invention, the width of the pixel is preferably 0.5 to 20.0 m. The lower limit is preferably 1.0 m or more and more preferably 2.0 m or more. The upper limit is preferably 15.0 m or less and more preferably 10.0 m or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω×cm or more and more preferably 10¹¹Ω×cm or more. The upper limit is not specified, but is preferably, for example, 10¹⁴Ω×cm or less. The volume resistivity value of the pixel can be measured, for example, using an ultrahigh resistance meter 5410 (manufactured by Advantest Corporation).

In addition, in the color filter according to the embodiment of the present invention, a protective layer may be provided on the surface of the cured film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 m and still more preferably 0.1 to 5 m. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, optionally, an additive such as organic or inorganic fine particles, an absorber of a specific wavelength (for example, ultraviolet rays, near-infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 to 70 mass % and still more preferably 1 to 60 mass % with respect to the total weight of the protective layer.

In addition, as the protective layer, the protective layers described in paragraphs “0073” to “0092” of JP2017-151176A can also be used.

The color filter may have a base layer. The base layer can also be formed using, for example, a composition obtained by removing a colorant from the above-described coloring composition according to the embodiment of the present invention. The surface contact angle of the base layer is preferably 20 to 70 in a case of being measured with diiodomethane. In addition, the surface contact angle of the base layer is preferably 300 to 800 in a case of being measured with water. In a case where the surface contact angle of the base layer is within the above-described range, wettability of the resin composition is good. The surface contact angle of the base layer can be adjusted by, for example, adding a surfactant.

In addition, in the green pixel of the color filter, green color may be formed in a combination of C. I. Pigment Green 7, C. I. Pigment Green 36, C. I. Pigment Yellow 139, and C. I. Pigment Yellow 185, or in a combination of C. I. Pigment Green 58, C. I. Pigment Yellow 150, and C. I. Pigment Yellow 185.

<Method for Producing Color Filter>

Next, the method for producing the color filter according to the embodiment of the present invention will be described. The color filter according to the embodiment of the present invention can be produced through a step of forming a coloring composition layer on a support using the above-described coloring composition according to the embodiment of the present invention, and a step of forming a pattern on the coloring composition layer by a photolithography method or a dry etching method.

(Photolithography Method)

First, a case of forming a pattern by a photolithography method to produce a color filter will be described. Pattern formation by a photolithography method preferably includes a step of forming a coloring composition layer on a support using the coloring composition according to the embodiment of the present invention, a step of patternwise exposing the coloring composition layer, and a step of removing an unexposed area of the coloring composition layer by development to form a pattern (pixel). Optionally, a step (pre-baking step) of baking the coloring composition layer and a step (post-baking step) of baking the developed pattern (pixel) may be provided.

In the step of forming a coloring composition according to the embodiment of the present invention, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and a metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet-Infinite Possibilities in Patent-” (published in February, 2005, S.B. Research Co., Ltd.) and methods described in JP2003-262716A, JP2003-185831A, JP2003-261827A, JP2012-126830A, and JP2006-169325A. In addition, with regard to the method of applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

<<Exposure Step>>

Next, the coloring composition layer is patternwise exposed (exposing step). For example, the coloring composition layer can be patternwise exposed using a stepper exposure device or a scanner exposure device through a mask having a predetermined mask pattern. As a result, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the unexposed area of the coloring composition layer is removed by development to form a pattern (pixel). The unexposed area of the coloring composition layer can be removed by development using a developer. Thus, the coloring composition layer of the unexposed area in the exposure step is eluted into the developer, and as a result, only a photocured portion remains. As the developer, an organic alkaline developer causing no damage on a base of element, circuit, or the like is desirable. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

As the developer, an alkaline aqueous solution (alkaline developer) obtained by diluting an alkaline agent with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heat treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be performed by the method described in KR10-2017-122130A.

(Dry Etching Method)

Next, a case of forming a pattern by a dry etching method to produce a color filter will be described. Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of patternwise exposing the photoresist layer and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heat treatment after exposure and a heat treatment after development (post-baking treatment) are performed. The details of the pattern formation by the dry etching method can be found in paragraphs “0010” to “0067” of JP2013-064993A, the content of which is incorporated herein by reference.

<Solid-State Imaging Element>

The solid-state imaging element according to the embodiment of the present invention has the cured film according to the embodiment of the present invention. The configuration of the solid-state imaging element according to the embodiment of the present invention is not particularly limited as long as the solid-state imaging element is configured to include the cured film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each coloring pixel is embedded in a space partitioned in, for example, a lattice shape by a partition wall. The partition wall in this case preferably has a low refractive index for each coloring pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera, a monitoring camera, and the like, in addition to a digital camera or electronic equipment (mobile phones or the like) having an imaging function.

<Image Display Device>

The image display device according to the embodiment of the present invention has the cured film according to the embodiment of the present invention. Examples of the image display device include a liquid crystal display device or an organic electroluminescence display device. The definitions of image display devices or the details of the respective image display devices are described in, for example, “Electronic Display Device (written by Akio Sasaki, Kogyo Chosakai Publishing Co., Ltd., published in 1990)”, “Display Device (written by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Measurement of Weight-Average Molecular Weight (Mw)>

The weight-average molecular weight (Mw) of a measurement sample was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 L (sample concentration: 0.1 mass %)

Device name: HLC-8220GPC manufactured by Tosoh Corporation

Detector: refractive index (RI) detector

Calibration curve base resin: polystyrene resin

<Method for Measuring Acid Value>

The measurement sample was dissolved in a mixed solvent of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×V_{S}×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the measurement sample (expressed in terms of solid contents)

<Preparation of Dispersion Liquid>

Raw materials described in the following tables were mixed to obtain a mixed solution. The obtained mixed solution was subjected to a dispersion treatment by using Ultra apex mill (trade name) manufactured by Kotobuki Industries Co., Ltd. as a circulation type dispersion apparatus (beads mill) to obtain a dispersion liquid. The solid content of the obtained dispersion liquid was 17.50 mass %.

TABLE 8

| | Coloring material | | Dispersant | | Solvent | |
|---|---|---|---|---|---|---|
| | | Part by | | Part by | | Part by |
| | Type | mass | Type | mass | Type | mass |
| Pigment | Pigment R1 | 12.96 | Dispersant 1 | 4.54 | Solvent S1 | 82.50 |
| dispersion | | | | | | |
| liquid R1 | | | | | | |
| Pigment | Pigment R1 | 12.96 | Dispersant 2 | 4.54 | Solvent S1 | 82.50 |
| dispersion | | | | | | |
| liquid R2 | | | | | | |
| Pigment | Pigment R1 | 12.96 | Dispersant 3 | 4.54 | Solvent S1 | 82.50 |
| dispersion | | | | | | |
| liquid R3 | | | | | | |
| Pigment | Pigment R1 | 12.96 | Dispersant 4 | 4.54 | Solvent S1 | 82.50 |
| dispersion | | | | | | |
| liquid R4 | | | | | | |
| Pigment | Pigment R1 | 12.96 | Dispersant 5 | 4.54 | Solvent S1 | 82.50 |
| dispersion | | | | | | |
| liquid R5 | | | | | | |
| Pigment | Pigment R2 | 12.96 | Dispersant 2 | 4.54 | Solvent S1 | 82.50 |
| dispersion | | | | | | |
| liquid R6 | | | | | | |
| Pigment | Pigment R3 | 12.96 | Dispersant 2 | 4.54 | Solvent S1 | 82.50 |
| dispersion | | | | | | |
| liquid R7 | | | | | | |
| Pigment | Pigment R4 | 12.96 | Dispersant 2 | 4.54 | Solvent S1 | 82.50 |
| dispersion | | | | | | |
| liquid R8 | | | | | | |
| Pigment | Pigment R5 | 12.96 | Dispersant 2 | 4.54 | Solvent S1 | 82.50 |
| dispersion | | | | | | |
| liquid R9 | | | | | | |
| Pigment | Pigment R6 | 12.96 | Dispersant 2 | 4.54 | Solvent S1 | 82.50 |
| dispersion | | | | | | |
| liquid R10 | | | | | | |
| Pigment | Pigment R7 | 12.96 | Dispersant 2 | 4.54 | Solvent S1 | 82.50 |
| dispersion | | | | | | |
| liquid R11 | | | | | | |
| Pigment | Pigment R8 | 12.96 | Dispersant 2 | 4.54 | Solvent S1 | 82.50 |
| dispersion | | | | | | |
| liquid R12 | | | | | | |
| Pigment | Pigment R9 | 12.96 | Dispersant 2 | 4.54 | Solvent S1 | 82.50 |
| dispersion | | | | | | |
| liquid R13 | | | | | | |
| Pigment | Pigment CR1 | 12.96 | Dispersant 1 | 4.54 | Solvent S1 | 82.50 |
| dispersion | | | | | | |
| liquid CR1 | | | | | | |
| Pigment | Pigment CR1 | 12.96 | Dispersant 2 | 4.54 | Solvent S1 | 82.50 |
| dispersion | | | | | | |
| liquid CR2 | | | | | | |
| Pigment | Pigment CR2 | 12.96 | Dispersant 2 | 4.54 | Solvent S1 | 82.50 |
| dispersion | | | | | | |
| liquid CR3 | | | | | | |

TABLE 9

| | Coloring material | | Dispersant | | Solvent | |
|---|---|---|---|---|---|---|
| | | Part by | | Part by | | Part by |
| | Type | mass | Type | mass | Type | mass |
| Pigment | Pigment Y1 | 12.96 | Dispersant 2 | 4.54 | Solvent S1 | 82.50 |
| dispersion | | | | | | |
| liquid Y1 | | | | | | |
| Pigment | Pigment Y2 | 12.96 | Dispersant 2 | 4.54 | Solvent S1 | 82.50 |
| dispersion | | | | | | |
| liquid Y2 | | | | | | |
| Pigment | Pigment Y3 | 12.96 | Dispersant 2 | 4.54 | Solvent S1 | 82.50 |
| dispersion | | | | | | |
| liquid Y3 | | | | | | |
| Pigment | Pigment Y4 | 12.96 | Dispersant 2 | 4.54 | Solvent S1 | 82.50 |
| dispersion | | | | | | |
| liquid Y4 | | | | | | |

The materials described in the above tables are as follows.

Pigments R1 to R9: compounds having the following structures; the pigment Riis C. I. Pigment Red 272.

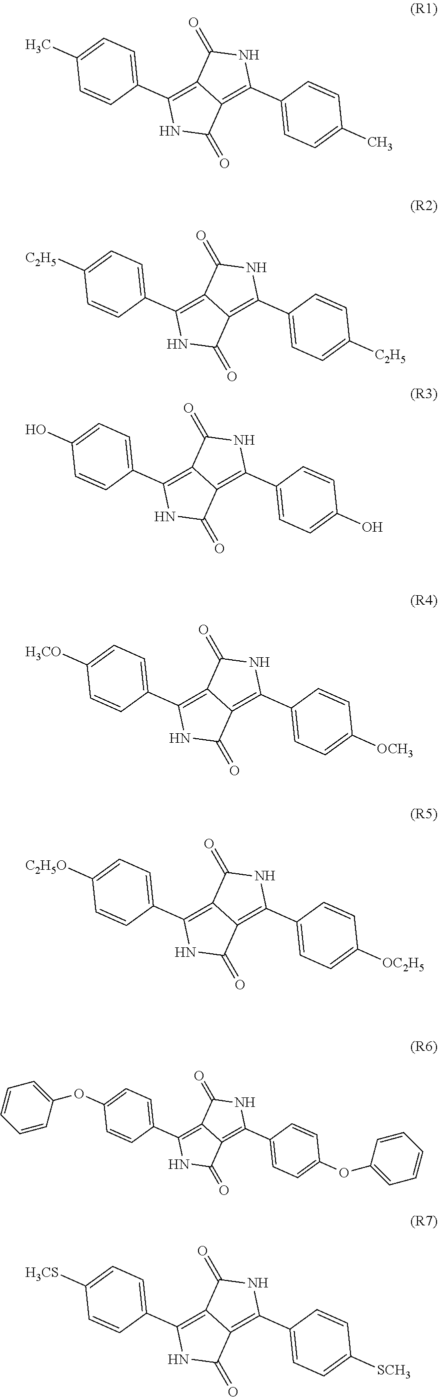

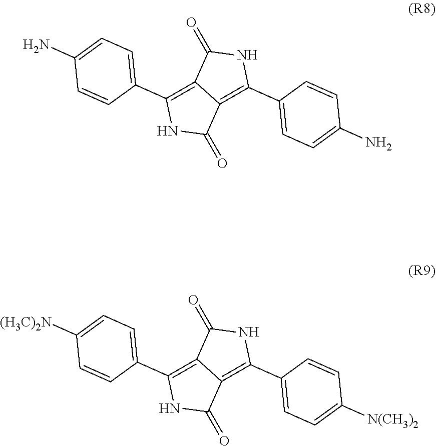

Pigment CR1: compound having the following structure; the pigment CR1 is C. I. Pigment Red 254.

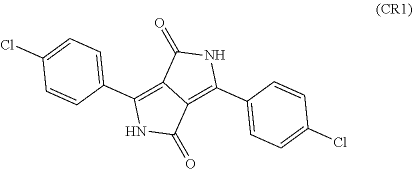 [SMILES: O=C1NC(c2ccc(Cl)cc2)=C2C(=O)NC(c3ccc(Cl)cc3)=C12]

Pigment CR2: compound having the following structure; the pigment CR2 is C. I. Pigment Orange 71.

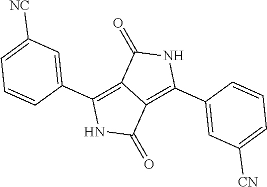 [SMILES: N#Cc1cccc(C2=C3C(=O)NC(c4cccc(C#N)c4)=C3C(=O)N2)c1]

Pigment Y1: C. I. Pigment Yellow 138

Pigment Y2: C. I. Pigment Yellow 139

Pigment Y3: C. I. Pigment Yellow 150

Pigment Y4: C. I. Pigment Yellow 185

(Dispersant)

Dispersant 1: compound having the following structure (the numerical value described together with the main chain indicates a molar ratio, and the numerical value described together with the side chain indicates the number of repeating units; Mw: 20000, C═C value: 0.0 mmol/g, acid value: 75 mgKOH/g)

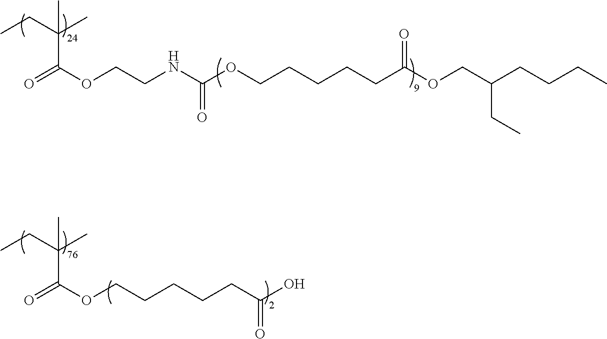

Dispersant 2: compound having the following structure (the numerical value described together with the main chain indicates a molar ratio, and the numerical value described together with the side chain indicates the number of repeating units; Mw: 20000, C═C value: 0.4 mmol/g, acid value: 70 mgKOH/g)

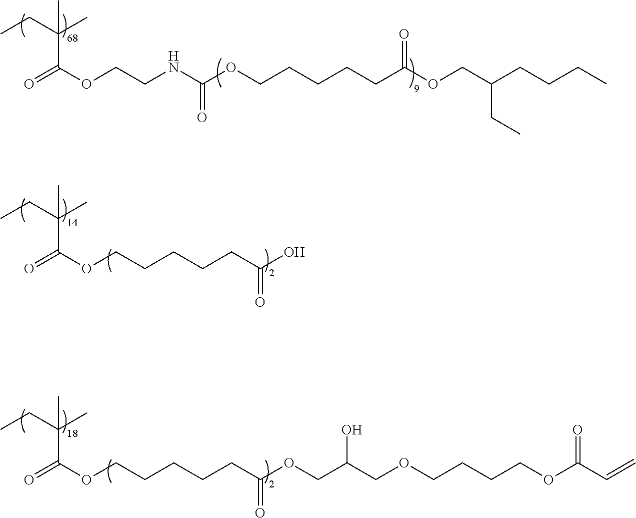

Dispersant 3: compound having the following structure (the numerical value described together with the main chain indicates a molar ratio, and the numerical value described together with the side chain indicates the number of repeating units; Mw: 20000, C═C value: 0.0 mol/g, acid value: 50 mgKOH/g)

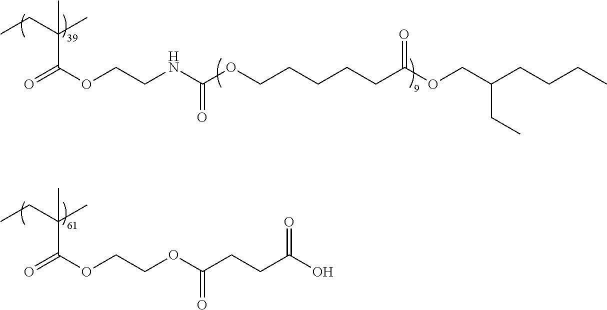

Dispersant 4: compound having the following structure (the numerical value described together with the main chain indicates a molar ratio, and the numerical value described together with the side chain indicates the number of repeating units; Mw: 20000, C═C value: 0.0 mol/g, acid value: 50 mgKOH/g)

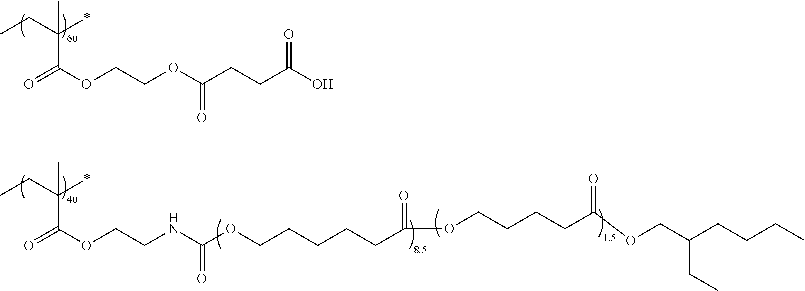

Dispersant 5: compound having the following structure (the numerical value described together with the main chain indicates a molar ratio, and the numerical value described together with the side chain indicates the number of repeating units; Mw: 20000, C═C value: 0.7 mol/g, acid value: 72 mgKOH/g)

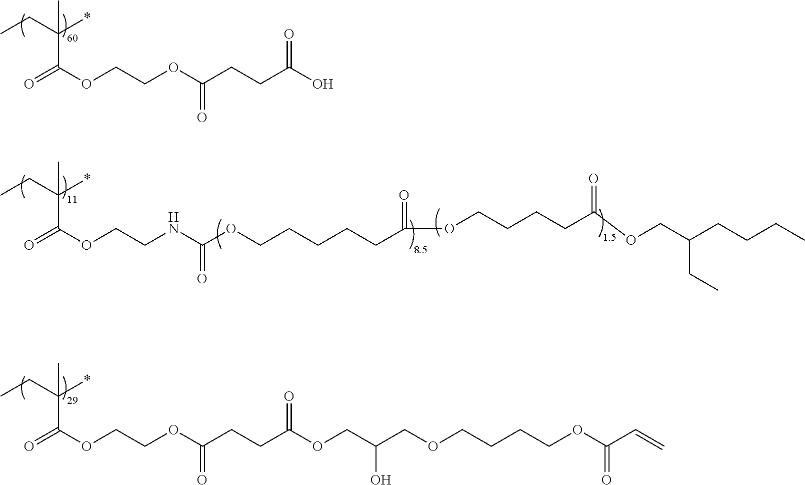

(Solvent)

Solvent S1: propylene glycol monomethyl ether acetate (PGMEA)

<Preparation of Coloring Composition>

The raw materials described in the following table were mixed to prepare coloring compositions of Examples and Comparative Examples.

TABLE 10

| | Pigment dispersion | | Pigment dispersion | | | | Polymerizable | | | | Photopolymerization | | | | Polymerization | | | |
|---|---|---|---|---|---|---|---|---|---|---|---|---|---|---|---|---|---|---|
| | liquid 1 | | liquid 2 | | Resin | | monomer | | Epoxy compound | | initiator | | Surfactant | | inhibitor | | Solvent | |
| | | Part by | | Part by | | Part by | | Part by | | Part by | | Part by | | Part by | | Part by | | Part by |
| | Type | mass | Type | mass | Type | mass | Type | mass | Type | mass | Type | mass | Type | mass | Type | mass | Type | mass |
| Example 1 | Pigment | 60.00 | Pigment | 10.00 | Resin | 1.25 | Monomer | 0.63 | Epoxy | 0.32 | Initiator I1 | 0.45 | Surfactant | 0.0417 | Polymerization | 0.0006 | Solvent | 27.31 |
| | dispersion | | dispersion | | B1 | | M1 | | compound E1 | | | | F1 | | inhibitor P1 | | S1 | |
| | liquid R1 | | liquid Y1 | | | | | | | | | | | | | | | |
| Example 2 | Pigment | 60.00 | Pigment | 10.00 | Resin | 1.25 | Monomer | 0.63 | Epoxy | 0.32 | Initiator I1 | 0.45 | Surfactant | 0.0417 | Polymerization | 0.0006 | Solvent | 27.31 |
| | dispersion | | dispersion | | B1 | | M1 | | compound E1 | | | | F1 | | inhibitor P1 | | S1 | |
| | liquid R2 | | liquid Y1 | | | | | | | | | | | | | | | |
| Example 3 | Pigment | 60.00 | Pigment | 10.00 | Resin | 1.25 | Monomer | 0.63 | Epoxy | 0.32 | Initiator I1 | 0.45 | Surfactant | 0.0417 | Polymerization | 0.0006 | Solvent | 27.31 |
| | dispersion | | dispersion | | B1 | | M1 | | compound E1 | | | | F1 | | inhibitor P1 | | S1 | |
| | liquid R3 | | liquid Y1 | | | | | | | | | | | | | | | |
| Example 4 | Pigment | 60.00 | Pigment | 10.00 | Resin | 1.25 | Monomer | 0.63 | Epoxy | 0.32 | Initiator I1 | 0.45 | Surfactant | 0.0417 | Polymerization | 0.0006 | Solvent | 27.31 |
| | dispersion | | dispersion | | B1 | | M1 | | compound E1 | | | | F1 | | inhibitor P1 | | S1 | |
| | liquid R4 | | liquid Y1 | | | | | | | | | | | | | | | |
| Example 5 | Pigment | 60.00 | Pigment | 10.00 | Resin | 1.25 | Monomer | 0.63 | Epoxy | 0.32 | Initiator I1 | 0.45 | Surfactant | 0.0417 | Polymerization | 0.0006 | Solvent | 27.31 |
| | dispersion | | dispersion | | B1 | | M1 | | compound E1 | | | | F1 | | inhibitor P1 | | S1 | |
| | liquid R5 | | liquid Y1 | | | | | | | | | | | | | | | |
| Example 6 | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 7 | Pigment | 42 00 | Pigment | 7.00 | Resin | 4.61 | Monomer | 0.95 | Epoxy | 0.32 | Initiator I2 | 0.45 | Surfactant | 0.0417 | Polymerization | 0.0006 | Solvent | 44.63 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 8 | Pigment | 60.00 | Pigment | 10.00 | Resin | 1.25 | Monomer | 0.63 | Epoxy | 0.32 | Initiator I3 | 0.45 | Surfactant | 0.0417 | Polymerization | 0.0006 | Solvent | 27.31 |
| | dispersion | | dispersion | | B2 | | M3 | | compound E1 | | | | F1 | | inhibitor P1 | | S1 | |
| | liquid R2 | | liquid Y3 | | | | | | | | | | | | | | | |
| Example 9 | Pigment | 60.00 | Pigment | 10.00 | Resin | 1.25 | Monomer | 0.63 | Epoxy | 0.32 | Initiator I3 | 0.45 | Surfactant | 0.0417 | Polymerization | 0.0006 | Solvent | 27.31 |
| | dispersion | | dispersion | | B2 | | M3 | | compound E1 | | | | F1 | | inhibitor P1 | | S1 | |
| | liquid R2 | | liquid Y4 | | | | | | | | | | | | | | | |
| Example 10 | Pigment | 60.00 | Pigment | 10.00 | Resin | 1.25 | Monomer | 0.315 | Epoxy | 0.32 | Initiator I4 | 0.45 | Surfactant | 0.0417 | Polymerization | 0.0006 | Solvent | 13.655 |
| | dispersion | | dispersion | | B2 | | M1 | 0.315 | compound E1 | | | | F1 | | inhibitor P1 | | S1 | 13.655 |
| | liquid R2 | | liquid Y2 | | | | Monomer | | | | | | | | | | Solvent | |
| | | | | | | | M3 | | | | | | | | | | S2 | |
| Example 11 | Pigment | 60.00 | Pigment | 10.00 | Resin | 1.25 | Monomer | 0.63 | Epoxy | 0.32 | Initiator I5 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 12 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R6 | | liquid Y2 | | | | | | | | | | | | | | | |
| Example 13 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R7 | | liquid Y2 | | | | | | | | | | | | | | | |
| Example 14 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R8 | | liquid Y2 | | | | | | | | | | | | | | | |
| Example 15 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R9 | | liquid Y2 | | | | | | | | | | | | | | | |
| Example 16 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R10 | | liquid Y2 | | | | | | | | | | | | | | | |
| Example 17 | Pigment | 60.00 | Pigment | 10.00 | Resin | 1.25 | Monomer | 0.63 | Epoxy | 0.32 | Initiator I2 | | Surfactant | 0.0417 | Polymerization | 0.0006 | Solvent | 27.31 |
| | dispersion | | dispersion | | B2 | | M2 | | compound E2 | | | 0.45 | F1 | | inhibitor P1 | | S1 | |
| | liquid R11 | | liquid Y2 | | | | | | | | | | | | | | | |
| Example 18 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R12 | | liquid Y2 | | | | | | | | | | | | | | | |
| Example 19 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R13 | | liquid Y2 | | | | | | | | | | | | | | | |
| Example 20 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 21 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 22 | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 23 | Pigment | 50.00 | Pigment | 8.33 | Resin | 2.42 | Monomer | 1.50 | Epoxy | 0.32 | Initiator I2 | 0.45 | Surfactant | 0.0417 | Polymerization | 0.0006 | Solvent | 36.94 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 24 | Pigment | 50.00 | Pigment | 8.33 | Resin | 3.32 | Monomer | 0.60 | Epoxy | 0.32 | Initiator I2 | 0.45 | Surfactant | 0.0417 | Polymerization | 0.0006 | Solvent | 36.94 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| Example 25 | Pigment | 60.00 | Pigment | 10.00 | Resin | 1.25 | Monomer | 0.63 | Epoxy | 0.32 | Initiator I3 | 0.225 | Surfactant | 0.0417 | Polymerization | 0.0006 | Solvent | 27.31 |
| | dispersion | | dispersion | | B2 | | M2 | | compound E2 | | Initiator I4 | 0.225 | F1 | | inhibitor P1 | | S1 | |
| | liquid R2 | | liquid Y2 | | | | | | | | | | | | | | | |
| Example 26 | Pigment | 60.00 | Pigment | 10.00 | Resin | 1.25 | Monomer | 0.63 | Epoxy | 0.32 | Initiator I5 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| | Pigment | 10.00 | | | | | | | | | | | | | | | | |
| | dispersion | | | | | | | | | | | | | | | | | |
| | liquid CR3 | | | | | | | | | | | | | | | | | |
| Example 27 | Pigment | 60.00 | Pigment | 10.00 | Resin | 1.25 | Monomer | 0.63 | Epoxy | 0.32 | Initiator I5 | 0.45 | Surfactant | 0.0417 | Polymerization | 0.0006 | Solvent | 27.31 |
| | dispersion | | dispersion | | B2 | | M2 | | compound E2 | | | | F1 | | inhibitor P1 | | S1 | |
| | liquid R2 | | liquid Y2 | | | | | | | | | | | | | | | |
| | Pigment | 5.00 | | | | | | | | | | | | | | | | |
| | dispersion | | | | | | | | | | | | | | | | | |
| | liquid CR2 | | | | | | | | | | | | | | | | | |
| | Pigment | 5.00 | | | | | | | | | | | | | | | | |
| | dispersion | | | | | | | | | | | | | | | | | |
| | liquid CR3 | | | | | | | | | | | | | | | | | |
| Comparative | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| Example 1 | dispersion | | dispersion | | B3 | | M4 | | compound E2 | | | | F1 | | inhibitor P1 | | S1 | |
| | liquid CR1 | | liquid Y2 | | | | | | | | | | | | | | | |
| Comparative | Pigment | 60.00 | Pigment | 10.00 | Resin | 1.25 | Monomer | 0.63 | Epoxy | 0.32 | Initiator I2 | 0.45 | Surfactant | 0.0417 | Polymerization | 0.0006 | Solvent | 27.31 |
| Example 2 | dispersion | | dispersion | | B3 | | M4 | | compound E2 | | | | F1 | | inhibitor P1 | | S1 | |
| | liquid CR2 | | liquid Y2 | | | | | | | | | | | | | | | |

The raw materials described in the above table are as follows.

(Resin)

Resin B1: resin having the following structure (the numerical value described together with the main chain indicates a molar ratio, Mw: 30000)

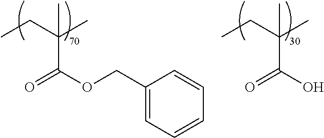

Resin B2: resin having the following structure (the numerical value described together with the main chain indicates a molar ratio, Mw: 11000)

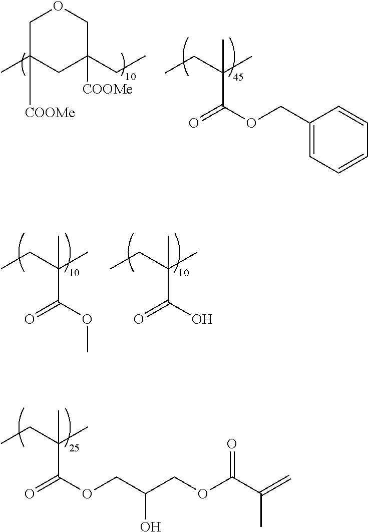

Resin B3: resin having the following structure (the numerical value described together with the main chain indicates a molar ratio, Mw: 10000)

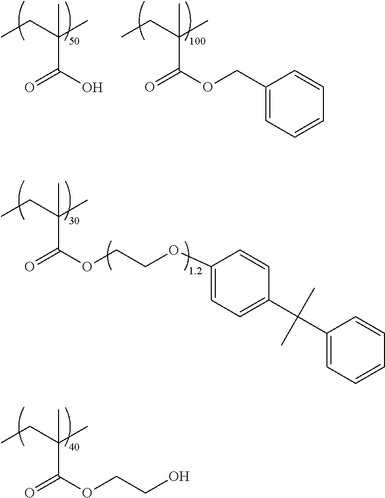

(Polymerizable Monomer)

Monomer M1: KAYARAD DPHA (manufactured by Nippon Kayaku Co., Ltd.)

Monomer M2: NK ESTER A-DPH-12E (manufactured by Shin-Nakamura Chemical Co., Ltd.)

Monomer M3: NK ESTER A-TMMT (manufactured by Shin-Nakamura Chemical Co., Ltd.)

Monomer M4: succinic acid-modified dipentaerythritol pentaacrylate

Monomer M5: dipentaerythritol hexaacrylate

Monomer M6: dipentaerythritol pentaacrylate

(Epoxy Compound)

Epoxy compound E1: EPICLON N-695 (manufactured by DIC Corporation)

Epoxy compound E2: EHPE 3150 (manufactured by Daicel Corporation)

(Photopolymerization Initiator)

Initiator I1: IRGACURE 369 (manufactured by BASF)

Initiator I2: IRGACURE OXE 01 (manufactured by BASF)

Initiator I3: IRGACURE OXE 02 (manufactured by BASF)

Initiator I4: compound having the following structure

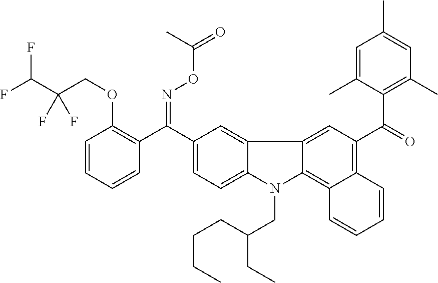 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

Initiator 15: compound having the following structure

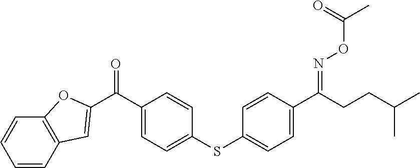 [SMILES: CC(=O)O/N=C(\CCC(C)C)c1ccc(Sc2ccc(C(=O)c3cc4ccccc4o3)cc2)cc1]

(Surfactant)

Surfactant F1: compound having the following structure (in the following formula, “%” representing the proportion of a repeating unit is mol %; Mw: 14000)

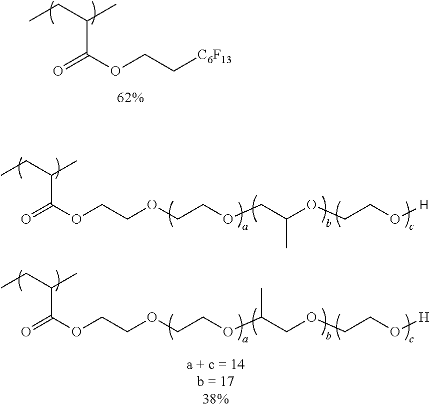

(Polymerization Inhibitor)

Polymerization inhibitor P1: p-methoxyphenol

(Solvent)

Solvent S1: propylene glycol monomethyl ether acetate (PGMEA)

Solvent S2: cyclohexanone

<Evaluation of Moisture Resistance>

CT-4000 (manufactured by Fujifilm Electronic Materials Co., Ltd.) was applied to a glass substrate by a spin coating method so that the thickness of a film was 0.1 m, and the glass substrate was heated at 220° C. for 1 hour using a hot plate to form a base layer. Each coloring composition was applied to this glass substrate with a base layer using a spin coating method, and then the glass substrate with a base layer was heated at 100° C. for 2 minutes using a hot plate to obtain a coating film. The obtained coating film was irradiated with light having a wavelength of 365 nm at an exposure dose of 500 mJ/cm². Next, the coating film was heated using a hot plate at 220° C. for 5 minutes to obtain a cured film having a film thickness of 0.5 m. Light transmittance (transmittance) of the obtained cured film in a range of 400 to 700 nm was measured by using MCPD-3000 manufactured by OTSUKA ELECTRONICS Co., LTD.

Next, the cured film produced above was allowed to stand in a constant temperature and humidity at 85° C. and 85% for 1000 hours. After performing the moisture resistance test, the transmittance of the cured film was measured, the maximum value of variation of transmittance was determined, and then the moisture resistance was evaluated based on the following standard.

In addition, the measurement of transmittance was performed 5 times for each sample, and the average value of the 3 times result except the maximum value and the minimum value was adopted. Furthermore, the maximum value of the variation of transmittance means a variation of transmittance of the cured film in a wavelength which has the largest variation of transmittance in a range of 400 to 700 nm before and after the moisture resistance test.

(Evaluation Standard)

5: maximum value of variation of transmittance is 1% or less.

4: maximum value of variation of transmittance is more than 1% and 1.5% or less.

3: maximum value of variation of transmittance is more than 1.5% and 2.0% or less.

2: maximum value of variation of transmittance is more than 2.0% and 2.5% or less.

1: maximum value of variation of transmittance is more than 2.5%.

<Evaluation of Heat Resistance>

CT-4000 (manufactured by Fujifilm Electronic Materials Co., Ltd.) was applied to a glass substrate by a spin coating method so that the thickness of a film was 0.1 μm, and the silicon wafer was heated at 220° C. for 1 hour using a hot plate to form a base layer. Each coloring composition was applied to this glass substrate with a base layer using a spin coating method, and then the glass substrate with a base layer was heated at 100° C. for 2 minutes using a hot plate to obtain a coating film. The obtained coating film was irradiated with light having a wavelength of 365 nm at an exposure dose of 500 mJ/cm². Next, the coating film was heated using a hot plate at 220° C. for 5 minutes to obtain a cured film having a film thickness of 0.5 m. Light transmittance (transmittance) of the obtained cured film in a range of 400 to 700 nm was measured by using MCPD-3000 manufactured by OTSUKA ELECTRONICS Co., LTD.

Next, the cured film produced above was heated at 265° C. for 5 minutes. The transmittance of the cured film after heating was measured, the maximum value of variation of transmittance was determined, and then the heat resistance was evaluated based on the following standard.

In addition, the measurement of transmittance was performed 5 times for each sample, and the average value of the 3 times result except the maximum value and the minimum value was adopted. Furthermore, the maximum value of the variation of transmittance means a variation of transmittance of the cured film in a wavelength which has the largest variation of transmittance in a range of 400 to 700 nm before and after heating.

(Evaluation Standard)

5: maximum value of variation of transmittance is 1% or less.

4: maximum value of variation of transmittance is more than 1% and 1.5% or less.

3: maximum value of variation of transmittance is more than 1.5% and 2.0% or less.

2: maximum value of variation of transmittance is more than 2.0% and 2.5% or less.

1: maximum value of variation of transmittance is more than 2.5%.

TABLE 11

| | Evaluation | |
|---|---|---|
| | Moisture | Heat |
| | resistance | resistance |
| Example 1 | 4 | 2 |
| Example 2 | 4 | 4 |
| Example 3 | 4 | 2 |
| Example 4 | 4 | 2 |
| Example 5 | 4 | 4 |
| Example 6 | 5 | 5 |
| Example 7 | 5 | 4 |
| Example 8 | 4 | 4 |
| Example 9 | 4 | 4 |
| Example 10 | 4 | 4 |
| Example 11 | 4 | 4 |
| Example 12 | 4 | 4 |
| Example 13 | 4 | 4 |
| Example 14 | 4 | 4 |
| Example 15 | 4 | 4 |
| Example 16 | 4 | 4 |
| Example 17 | 4 | 4 |
| Example 18 | 4 | 4 |
| Example 19 | 4 | 4 |
| Example 20 | 4 | 3 |
| Example 21 | 4 | 3 |
| Example 22 | 4 | 3 |
| Example 23 | 5 | 4 |
| Example 24 | 5 | 5 |
| Example 25 | 4 | 4 |
| Example 26 | 3 | 4 |
| Example 27 | 3 | 4 |
| Comparative | 1 | 1 |
| Example 1 | | |
| Comparative | 1 | 1 |
| Example 2 | | |

As shown in the table, by using the coloring compositions of Examples, a cured film having excellent moisture resistance and heat resistance could be produced. In addition, the cured films obtained from the coloring compositions of Examples 1 to 17, and Examples 20 to 27 had preferred spectral characteristics as a red-colored layer.

In each example, the same effect can be obtained by using the polymerization inhibitor and surfactant described in the specification instead of the polymerization inhibitor P1 and the surfactant F1.

The following raw materials were mixed and stirred to be uniform, and then the mixture was filtered through a filter having a pore size of 0.1 m to produce a base material A.

| | |
|---|---|
| Resin B1 | 5.5 parts by mass |
| Resin B4 | 5.5 parts by mass |
| Monomer M1 | 10.5 parts by mass |
| Initiator I6 | 0.5 parts by mass |
| Epoxy compound E1 | 0.5 parts by mass |
| Solvent S1 | 37.5 parts by mass |
| Solvent S2 | 12.7 parts by mass |
| Solvent S3 | 27.3 parts by mass |

Resin B1, Monomer M1, Epoxy compound E1, Solvent S1, Solvent S2: above-described materials

Resin B4: “KS Resist 106” manufactured by OSAKA ORGANIC CHEMICAL INDUSTRY LTD. (acrylic polymer in which 2-methacryloyloxyethyl isocyanate is added to a hydroxyl group of a polymer side chain and a carbon-carbon double bond is introduced into the polymer side chain)

Initiator I6: 2-(1,3-benzodioxol-5-ylmethyl)-4,6-bis (trichloromethyl)-1,3,5-triazine

Solvent S3: ethyl 3-ethoxypropionate

Evaluation of moisture resistance and evaluation of heat resistance were performed by the same method as described above, except that, in the above-described evaluation of moisture resistance and evaluation of heat resistance, the base material applied to the glass substrate was changed from CT-4000 (manufactured by Fujifilm Electronic Materials Co., Ltd.) to the above-described base material A. As a result, the same results as those shown in Table 11 could be obtained.

<Synthesis of Dispersant 11>

75 parts by mass of methyl methacrylate, 75 parts by mass of n-butyl acrylate, and 68.1 parts by mass of propylene glycol monomethyl ether acetate (PGMEA) were charged into a reaction vessel equipped with gas inlet pipe, thermometer, condenser, and stirrer, and the inside of the reaction vessel was replaced with nitrogen gas. The inside of the reaction vessel was heated to 70° C., 9 parts by mass of 3-mercapto-1,2-propanediol was added thereto, 0.18 parts by mass of azobisisobutyronitrile (AIBN) was further added thereto, and the mixture was reacted for 12 hours. It was confirmed by solid content measurement that 95% thereof was reacted. Subsequently, 14.6 parts by mass of pyromellitic acid anhydride, 105.5 parts by mass of PGMEA, and 0.3 parts by mass of 1,8-diazabicyclo-[5.4.0]-7-undecene (DBU) as a reaction catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust the concentration of solid contents to be 50%, thereby obtaining a dispersant 11 having an acid value of 41 mgKOH/g and a weight-average molecular weight of 8800.

<Synthesis of Dispersant 12>

A dispersant 12 having an acid value of 30 mgKOH/g and a weight-average molecular weight of 9100 was obtained in the same method as in the synthesis of the dispersant 11, except that the acid anhydride used and the amount of the acid anhydride added were changed to 8.3 parts by mass of trimellitic acid anhydride.

<Synthesis of Dispersant 13>

8 parts by mass of 3-mercapto-1,2-propanediol, 12 parts by mass of pyromellitic acid, 80 parts by mass of propylene glycol monomethyl ether acetate (PGMEA), and 0.2 parts by mass of monobutyltin oxide as a reaction catalyst were charged into a reaction vessel equipped with gas inlet pipe, thermometer, condenser, and stirrer, the inside of the reaction vessel was replaced with nitrogen gas, and the mixture was reacted at 120° C. for 5 hours (first step). It was confirmed by acid value measurement that 95% or more of the acid anhydride was half-esterified. Next, 30 parts by mass of methyl methacrylate, 10 parts by mass of t-butyl acrylate, 10 parts by mass of ethyl acrylate, 5 parts by mass of methacrylic acid, 10 parts by mass of benzyl methacrylate, and 35 parts by mass of 2-hydroxyethyl methacrylate were charged thereto, the inside of the reaction vessel was heated to 80° C., 1 part by mass of 2,2′-azobis(2,4-dimethylvaleronitrile) was added thereto, and the mixture was reacted for 12 hours (second step). It was confirmed by solid content measurement that 95% thereof was reacted. Next, the inside of the reaction vessel was replaced with air, 38 parts by mass of 2-methacryloyloxyethyl isocyanate and 0.1 parts by mass of hydroquinone were charged thereto, and the mixture was reacted at 70° C. for 4 hours (third step). After confirming by IR measurement that the peak of 2270 cm⁻¹ based on the isocyanate group disappeared, the reaction solution was cooled, and the solid content was adjusted with PGMEA, thereby obtaining a solution of a dispersant 13 having a solid content of 40%. The acid value of the obtained dispersant 13 was 40 mgKOH/g and the weight-average molecular weight was 12,000.

The structural formulae of the synthesized dispersants 11 to 13 are shown below.

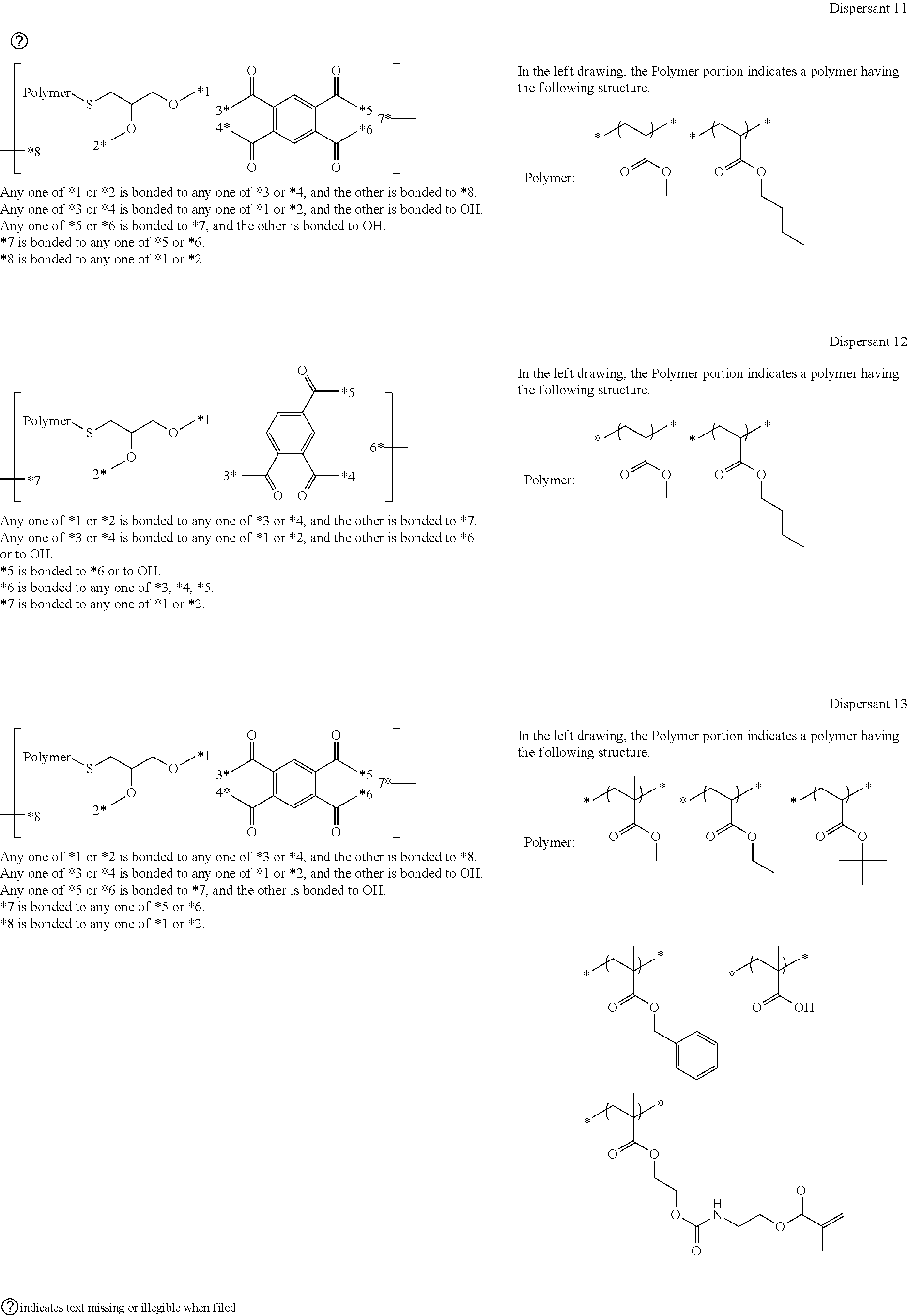

<Adjustment of DIspersion Liquid>

Raw materials described in the following table were mixed to obtain a mixed solution. The obtained mixed solution was subjected to a dispersion treatment by using Ultra apex mill (trade name) manufactured by Kotobuki Industries Co., Ltd. as a circulation type dispersion apparatus (beads mill) to obtain a dispersion liquid. The solid content of the obtained dispersion liquid was 17.50 mass %.

In addition, regarding pigment dispersion liquids R101 to 111 and Y101 adjusted as follows, in a case where the viscosity immediately after preparation and the viscosity after 6 months at room temperature were measured, it was confirmed that the viscosity did not fluctuate with time and the dispersion stability was excellent.

TABLE 12

| | Coloring material | | Dispersant | | Dispersion aid | | Solvent | |
|---|---|---|---|---|---|---|---|---|
| | | Part by | | Part by | | Part by | | Part by |
| | Type | mass | Type | mass | Type | mass | Type | mass |
| Pigment dispersion liquid R101 | Pigment R1 | 12.96 | Dispersant 11 | 4.54 | | | Solvent S1 | 82.50 |
| Pigment dispersion liquid R102 | Pigment R1 | 12.96 | Dispersant 12 | 4.54 | | | Solvent S1 | 82.50 |
| Pigment dispersion liquid R103 | Pigment R1 | 12.96 | Dispersant 13 | 4.54 | | | Solvent S1 | 82.50 |
| Pigment dispersion liquid R104 | Pigment R1 | 12.96 | Dispersant 13 | 4.54 | Dispersion aid 1 | 1.30 | Solvent S1 | 81.20 |
| Pigment dispersion liquid R105 | Pigment R1 | 12.96 | Dispersant 13 | 4.54 | Dispersion aid 2 | 1.30 | Solvent S1 | 81.20 |
| Pigment dispersion liquid R106 | Pigment R1 | 12.96 | Dispersant 13 | 4.54 | Dispersion aid 3 | 1.30 | Solvent S1 | 81.20 |
| Pigment dispersion liquid R107 | Pigment R1 | 12.96 | Dispersant 13 | 4.54 | Dispersion aid 4 | 1.30 | Solvent S1 | 81.20 |
| Pigment dispersion liquid R108 | Pigment R1 | 12.96 | Dispersant 13 | 4.54 | Dispersion aid 5 | 1.30 | Solvent S1 | 81.20 |
| Pigment dispersion liquid R109 | Pigment R1 | 12.96 | Dispersant 13 | 4.54 | Dispersion aid 6 | 1.30 | Solvent S1 | 81.20 |
| Pigment dispersion liquid R110 | Pigment R1 | 1.30 | Dispersant 13 | 4.54 | Dispersion aid 7 | 1.30 | Solvent S1 | 81.20 |
| | Pigment CR4 | 11.66 | | | | | | |
| Pigment dispersion liquid R111 | Pigment R1 | 0.65 | Dispersant 13 | 4.54 | | | Solvent S1 | 82.50 |
| | Pigment CR1 | 12.31 | | | | | | |
| Pigment dispersion liquid Y101 | Pigment Y2 | 12.96 | Dispersant 13 | 4.54 | | | Solvent S1 | 82.50 |

The raw materials described in the above table are as follows.

Pigments R1, CR1, Y2: pigments R1, CR1, and Y2 described above

Pigment CR4: C. I. Pigment Red 122

Dispersants 11 to 13: dispersants 11 to 13 synthesized as described above

Dispersion aids 1 to 7: compounds represented by the following formulae

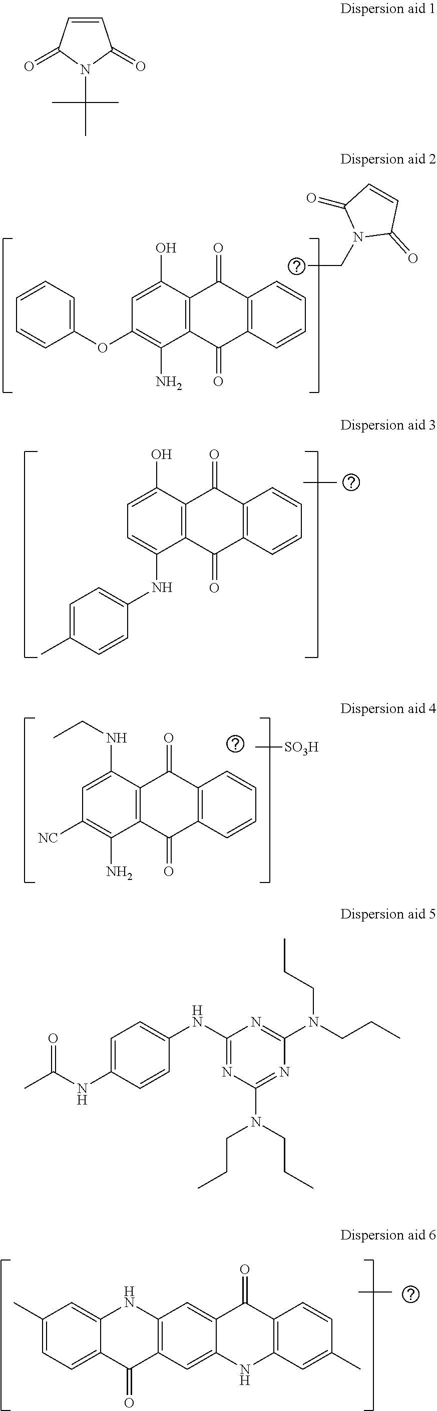

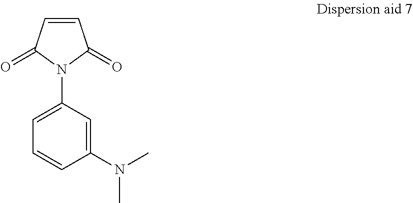 [SMILES: CN(C)c1cccc(N2C(=O)C=CC2=O)c1]

Solvent S1: solvent S1 described above

<Preparation of Coloring Composition>

Raw materials described in the following table were mixed to prepare a coloring composition.

TABLE 13

| | Pigment dispersion | | Pigment dispersion | | | | Polymerizable | | | | Photopolymerization | | | | Polymerization | | | |
|---|---|---|---|---|---|---|---|---|---|---|---|---|---|---|---|---|---|---|
| | liquid 1 | | liquid 2 | | Resin | | monomer | | Epoxy compound | | initiator | | Surfactant | | inhibitor | | Solvent | |
| | | Part by | | Part by | | Part by | | Part by | | Part by | | Part by | | Part by | | Part by | | Part by |
| | Type | mass | Type | mass | Type | mass | Type | mass | Type | mass | Type | mass | Type | mass | Type | mass | Type | mass |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 101 | dispersion | | dispersion | | B2 | | M2 | | compound | | | | F1 | | inhibitor P1 | | S1 | |
| | liquid R101 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 102 | dispersion | | dispersion | | B2 | | M2 | | compound | | | | F1 | | inhibitor P1 | | S1 | |
| | liquid R102 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 103 | dispersion | | dispersion | | B2 | | M2 | | compound | | | | F1 | | inhibitor P1 | | S1 | |
| | liquid R103 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 104 | dispersion | | dispersion | | B2 | | M1 | | compound | | | | F1 | | inhibitor P1 | | S1 | |
| | liquid R104 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I3 | 0.225 | Surfactant | 0.0417 | Polymerization | 0.0006 | Solvent | 36.94 |
| 105 | dispersion | | dispersion | | B2 | | M2 | | compound | | Initiator I4 | 0.225 | F1 | | inhibitor P1 | | S1 | |
| | liquid R105 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 106 | dispersion | | dispersion | | B2 | | M1 | | compound | | | | F1 | | inhibitor P1 | | S1 | |
| | liquid R106 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 107 | dispersion | | dispersion | | B2 | | M1 | | compound | | | | F1 | | inhibitor P1 | | S1 | |
| | liquid R107 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 108 | dispersion | | dispersion | | B2 | | M1 | | compound | | | | F1 | | inhibitor P1 | | S1 | |
| | liquid R108 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 109 | dispersion | | dispersion | | B2 | | M1 | | compound | | | | F1 | | inhibitor P1 | | S1 | |
| | liquid R109 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 110 | dispersion | | dispersion | | B2 | | M1 | | compound | | | | F1 | | inhibitor P1 | | S1 | |
| | liquid R110 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 111 | dispersion | | dispersion | | B2 | | M1 | | compound | | | | F1 | | inhibitor P1 | | S1 | |
| | liquid R111 | | liquid Y101 | | | | | | E2 | | | | | | | | | |
| Example | Pigment | 58.33 | | | Resin | 3.12 | Monomer | 0.80 | Epoxy | 0.32 | Initiator I2 | 0.45 | Surfactant | 0.0417 | Polymerization | 0.0006 | Solvent | 36.94 |
| 112 | dispersion | | | | B2 | | M1 | | compound | | | | F1 | | inhibitor P1 | | S1 | |
| | liquid R112 | | | | | | | | E2 | | | | | | | | | |
| Example | Pigment | 50.00 | Pigment | 8.33 | Resin | 3.12 | Monomer | 0.80 | Epoxy | 0.32 | Initiator I2 | 0.45 | Surfactant | 0.0417 | Polymerization | 0.0006 | Solvent | 36.94 |
| 113 | dispersion | | dispersion | | B2 | | M7 | | compound | | | | F1 | | inhibitor P1 | | S1 | |
| | liquid R113 | | liquid Y101 | | | | | | E2 | | | | | | | | | |
| Example | Pigment | 50.00 | Pigment | 8.33 | Resin | 3.12 | Monomer | 0.80 | Epoxy | 0.32 | Initiator I6 | 0.45 | Surfactant | 0.0417 | Polymerization | 0.0006 | Solvent | 36.94 |
| 114 | dispersion | | dispersion | | B2 | | M1 | | compound | | | | F1 | | inhibitor P1 | | S1 | |
| | liquid R114 | | liquid Y101 | | | | | | E2 | | | | | | | | | |

The raw materials described in the above table are as follows.

Pigment dispersion liquids R101 to R111, Pigment dispersion liquid Y101, Resin B2, Monomer M1, Monomer M2, Epoxy compound E2, Initiator I2, Initiator I3, Initiator I4, Surfactant F1, Polymerization inhibitor P1, Solvent S1: pigment dispersion liquids R101 to R111, pigment dispersion liquid Y101, resin B2, monomer M1, monomer M2, epoxy compound E2, initiator 12, initiator 13, initiator 14, surfactant F1, polymerization inhibitor P1, and solvent S1 described above

Monomer M7: “KAYARAD DPCA-20” manufactured by Nippon Kayaku Co., Ltd. (polymerizable monomer represented by the following formula)

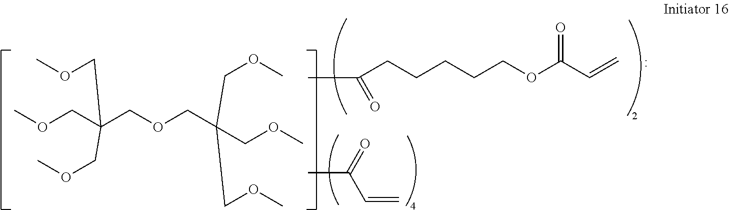

2-(1,3-benzodioxol-5-ylmethyl)-4,6-bis (trichloromethyl)-1,3,5-triazine

Moisture resistance and heat resistance were evaluated by the same method as in Example 1. The results are shown in the table below.

TABLE 14

| | Evaluation | |
|---|---|---|
| | Moisture | Heat |
| | resistance | resistance |
| Example 101 | 5 | 4 |
| Example 102 | 5 | 4 |
| Example 103 | 5 | 5 |
| Example 104 | 4 | 5 |
| Example 105 | 5 | 5 |
| Example 106 | 5 | 5 |
| Example 107 | 5 | 5 |
| Example 108 | 5 | 5 |
| Example 109 | 5 | 5 |
| Example 111 | 5 | 5 |
| Example 112 | 5 | 5 |
| Example 113 | 5 | 5 |
| Example 114 | 5 | 5 |

As shown in the table, by using the coloring compositions of Examples, a cured film having excellent moisture resistance and heat resistance could be produced.

<Adjustment of Dispersion Liquid>

Raw materials described in the following table were mixed to obtain a mixed solution. The obtained mixed solution was subjected to a dispersion treatment by using Ultra apex mill (trade name) manufactured by Kotobuki Industries Co., Ltd. as a circulation type dispersion apparatus (beads mill) to obtain a dispersion liquid. The solid content of the obtained dispersion liquid was 17.50 mass %.

TABLE 15

| | Coloring material | | Dispersant | | Solvent | |
|---|---|---|---|---|---|---|
| | Type | Part by mass | Type | Part by mass | Type | Part by mass |
| Pigment dispersion | Pigment CR1 | 12.96 | Dispersant 13 | 4.54 | Solvent S1 | 82.50 |
| liquid R201 | | | | | | |
| Pigment dispersion | Pigment CR5 | 12.96 | Dispersant 13 | 4.54 | Solvent S1 | 82.50 |
| liquid R202 | | | | | | |
| Pigment dispersion | Pigment CR6 | 12.96 | Dispersant 13 | 4.54 | Solvent S1 | 82.50 |
| liquid R203 | | | | | | |
| Pigment dispersion | Pigment CR7 | 12.96 | Dispersant 13 | 4.54 | Solvent S1 | 82.50 |
| liquid R204 | | | | | | |
| Pigment dispersion | Pigment CR8 | 12.96 | Dispersant 13 | 4.54 | Solvent S1 | 82.50 |
| liquid R205 | | | | | | |
| Pigment dispersion | Pigment CR9 | 12.96 | Dispersant 13 | 4.54 | Solvent S1 | 82.50 |
| liquid R206 | | | | | | |
| Pigment dispersion | Pigment CR10 | 12.96 | Dispersant 13 | 4.54 | Solvent S1 | 82.50 |
| liquid R207 | | | | | | |
| Pigment dispersion | Pigment R1 | 12.96 | Dispersant 5 | 4.54 | Solvent S1 | 82.50 |
| liquid R208 | | | | | | |
| Pigment dispersion | Pigment CR1 | 12.96 | Dispersant 5 | 4.54 | Solvent S1 | 82.50 |
| liquid R209 | | | | | | |
| Pigment dispersion | Pigment CR5 | 12.96 | Dispersant 5 | 4.54 | Solvent S1 | 82.50 |
| liquid R210 | | | | | | |
| Pigment dispersion | Pigment CR6 | 12.96 | Dispersant 5 | 4.54 | Solvent S1 | 82.50 |
| liquid R211 | | | | | | |
| Pigment dispersion | Pigment CR7 | 12.96 | Dispersant 5 | 4.54 | Solvent S1 | 82.50 |
| liquid R212 | | | | | | |
| Pigment dispersion | Pigment CR8 | 12.96 | Dispersant 5 | 4.54 | Solvent S1 | 82.50 |
| liquid R213 | | | | | | |
| Pigment dispersion | Pigment CR9 | 12.96 | Dispersant 5 | 4.54 | Solvent S1 | 82.50 |
| liquid R214 | | | | | | |
| Pigment dispersion | Pigment CR10 | 12.96 | Dispersant 5 | 4.54 | Solvent S1 | 82.50 |
| liquid R215 | | | | | | |
| Pigment dispersion | Pigment Y2 | 12.96 | Dispersant 5 | 4.54 | Solvent S1 | 82.50 |
| liquid Y201 | | | | | | |

The raw materials described in the above table are as follows.

Pigments R1, CR1, Y2: pigments R1, CR1, and Y2 described above

Pigment CR5: C. I. Pigment Red 255

Pigment CR6C. I. Pigment Red 264

Pigment CR7C. I. Pigment Red 269

Pigment CR8C. I. Pigment Red 291

Pigment CR9C. I. Pigment Red 295

Pigment CR10: C. I. Pigment Red 296

Dispersants 5, 13: dispersants 5 and 13 described above

Solvent S1: solvent S1 described above

<Preparation of Coloring Composition>

Raw materials described in the following tables were mixed to prepare a coloring composition.

TABLE 16

| | Pigment dispersion | | Pigment dispersion | | Pigment dispersion | | | |
|---|---|---|---|---|---|---|---|---|
| | liquid 1 | | liquid 2 | | liquid 3 | | Resin | |
| | | Part by | | Part by | | Part by | | Part by |
| | Type | mass | Type | mass | Type | mass | Type | mass |
| Example | Pigment | 40.92 | Pigment | 18.10 | Pigment | 17.06 | Resin | 0.46 |
| 201 | dispersion | | dispersion | | dispersion | | B3 | |
| | liquid R103 | | liquid R201 | | liquid Y101 | | | |
| Example | Pigment | 40.92 | Pigment | 29.63 | Pigment | 5.53 | Resin | 0.46 |
| 202 | dispersion | | dispersion | | dispersion | | B3 | |
| | liquid R103 | | liquid R201 | | liquid Y101 | | | |
| Example | Pigment | 52.45 | Pigment | 18.10 | Pigment | 5.53 | Resin | 0.46 |
| 203 | dispersion | | dispersion | | dispersion | | B3 | |
| | liquid R103 | | liquid R201 | | liquid Y101 | | | |
| Example | Pigment | 40.93 | Pigment | 30.39 | Pigment | 8.23 | Resin | 0.08 |
| 204 | dispersion | | dispersion | | dispersion | | B3 | |
| | liquid R103 | | liquid R201 | | liquid Y101 | | | |
| Example | Pigment | 40.93 | Pigment | 30.39 | Pigment | 8.23 | Resin | 0.08 |
| 205 | dispersion | | dispersion | | dispersion | | B3 | |
| | liquid R103 | | liquid R202 | | liquid Y101 | | | |
| Example | Pigment | 52.12 | Pigment | 19.20 | Pigment | 8.23 | Resin | 0.08 |
| 206 | dispersion | | dispersion | | dispersion | | B3 | |
| | liquid R103 | | liquid R203 | | liquid Y101 | | | |
| Example | Pigment | 58.31 | Pigment | 10.13 | Pigment | 11.11 | Resin | 0.08 |
| 207 | dispersion | | dispersion | | dispersion | | B3 | |
| | liquid R103 | | liquid R204 | | liquid Y101 | | | |
| Example | Pigment | 40.93 | Pigment | 30.39 | Pigment | 8.23 | Resin | 0.08 |
| 208 | dispersion | | dispersion | | dispersion | | B3 | |
| | liquid R103 | | liquid R205 | | liquid Y101 | | | |
| Example | Pigment | 40.93 | Pigment | 30.39 | Pigment | 8.23 | Resin | 0.08 |
| 209 | dispersion | | dispersion | | dispersion | | B3 | |
| | liquid R103 | | liquid R206 | | liquid Y101 | | | |
| Example | Pigment | 40.93 | Pigment | 30.39 | Pigment | 8.23 | Resin | 0.08 |
| 210 | dispersion | | dispersion | | dispersion | | B3 | |
| | liquid R103 | | liquid R207 | | liquid Y101 | | | |
| Example | Pigment | 40.92 | Pigment | 18.10 | Pigment | 17.06 | Resin | 0.46 |
| 211 | dispersion | | dispersion | | dispersion | | B2 | |
| | liquid R208 | | liquid R209 | | liquid Y201 | | | |
| Example | Pigment | 40.92 | Pigment | 29.63 | Pigment | 5.53 | Resin | 0.46 |
| 212 | dispersion | | dispersion | | dispersion | | B2 | |
| | liquid R208 | | liquid R209 | | liquid Y201 | | | |
| Example | Pigment | 52.45 | Pigment | 18.10 | Pigment | 5.53 | Resin | 0.46 |
| 213 | dispersion | | dispersion | | dispersion | | B2 | |
| | liquid R208 | | liquid R209 | | liquid Y201 | | | |
| Example | Pigment | 40.93 | Pigment | 30.39 | Pigment | 8.23 | Resin | 0.08 |
| 214 | dispersion | | dispersion | | dispersion | | B2 | |
| | liquid R208 | | liquid R209 | | liquid Y201 | | | |
| Example | Pigment | 40.93 | Pigment | 30.39 | Pigment | 8.23 | Resin | 0.08 |
| 215 | dispersion | | dispersion | | dispersion | | B2 | |
| | liquid R208 | | liquid R210 | | liquid Y201 | | | |
| Example | Pigment | 52.12 | Pigment | 19.20 | Pigment | 8.23 | Resin | 0.08 |
| 216 | dispersion | | dispersion | | dispersion | | B2 | |
| | liquid R208 | | liquid R211 | | liquid Y201 | | | |
| Example | Pigment | 58.31 | Pigment | 10.13 | Pigment | 11.11 | Resin | 0.08 |
| 217 | dispersion | | dispersion | | dispersion | | B2 | |
| | liquid R208 | | liquid R212 | | liquid Y201 | | | |
| Example | Pigment | 40.93 | Pigment | 30.39 | Pigment | 8.23 | Resin | 0.08 |
| 218 | dispersion | | dispersion | | dispersion | | B2 | |
| | liquid R208 | | liquid R213 | | liquid Y201 | | | |
| Example | Pigment | 40.93 | Pigment | 30.39 | Pigment | 8.23 | Resin | 0.08 |
| 219 | dispersion | | dispersion | | dispersion | | B2 | |
| | liquid R208 | | liquid R214 | | liquid Y201 | | | |
| Example | Pigment | 40.93 | Pigment | 30.39 | Pigment | 8.23 | Resin | 0.08 |
| 220 | dispersion | | dispersion | | dispersion | | B2 | |
| | liquid R208 | | liquid R215 | | liquid Y201 | | | |

TABLE 17

| | Polymerizable | | | | Photopolymerization | | | | Polymerization | | | |
|---|---|---|---|---|---|---|---|---|---|---|---|---|
| | monomer | | Epoxy compound | | initiator | | Surfactant | | inhibitor | | Solvent | |
| | | Part by | | Part by | | Part by | | Part by | | Part by | | Part by |
| | Type | mass | Type | mass | Type | mass | Type | mass | Type | mass | Type | mass |
| Example | Monomer | 0.54 | Epoxy compound | 0.32 | Initiator I3 | 0.30 | Surfactant | 0.0417 | Polymerization | 0.0003 | Solvent | 22.29 |
| 201 | M1 | | E2 | | | | F1 | | inhibitor P1 | | S1 | |
| Example | Monomer | 0.54 | Epoxy compound | 0.32 | Initiator I3 | 0.30 | Surfactant | 0.0417 | Polymerization | 0.0003 | Solvent | 22.29 |
| 202 | M1 | | E2 | | | | F1 | | inhibitor P1 | | S1 | |
| Example | Monomer | 0.54 | Epoxy compound | 0.32 | Initiator I3 | 0.30 | Surfactant | 0.0417 | Polymerization | 0.0003 | Solvent | 22.29 |
| 203 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 204 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 205 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 206 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 207 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 208 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 209 | M1 | | E2 | | | | F1 | | inhibitor P1 | | S1 | |
| Example | Monomer | 0.51 | Epoxy compound | 0.15 | Initiator I3 | 0.29 | Surfactant | 0.0417 | Polymerization | 0.0003 | Solvent | 19.44 |
| 210 | M1 | | E2 | | | | F1 | | inhibitor P1 | | S1 | |
| Example | Monomer | 0.54 | Epoxy compound | 0.32 | Initiator I4 | 0.30 | Surfactant | 0.0417 | Polymerization | 0.0003 | Solvent | 22.29 |
| 211 | M1 | | E2 | | | | F1 | | inhibitor P1 | | S1 | |
| Example | Monomer | 0.54 | Epoxy compound | 0.32 | Initiator I4 | 0.30 | Surfactant | 0.0417 | Polymerization | 0.0003 | Solvent | 22.29 |
| 212 | M1 | | E2 | | | | F1 | | inhibitor P1 | | S1 | |
| Example | Monomer | 0.54 | Epoxy compound | 0.32 | Initiator I4 | 0.30 | Surfactant | 0.0417 | Polymerization | 0.0003 | Solvent | 22.29 |
| 213 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 214 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 215 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 216 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 217 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 218 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 219 | M1 | | E2 | | | | F1 | | inhibitor P1 | | S1 | |
| Example | Monomer | 0.51 | Epoxy compound | 0.15 | Initiator I4 | 0.29 | Surfactant | 0.0417 | Polymerization | 0.0003 | Solvent | 19.44 |
| 220 | M1 | | E2 | | | | F1 | | inhibitor P1 | | S1 | |

The raw materials described in the above tables are as follows.

Pigment dispersion liquid R103, Pigment dispersion liquids R201 to R215, Pigment dispersion liquid Y101, Pigment dispersion liquid Y201, Resin B2, Resin B3, Monomer M1, Epoxy compound E2, Initiator 13, Initiator 14, Surfactant F1, Polymerization inhibitor P1, Solvent S1. pigment dispersion liquid R103, pigment dispersion liquids R201 to R215, pigment dispersion liquid Y101, pigment dispersion liquid Y201, resin B2, resin B3, monomer M1, epoxy compound E2, initiator 13, initiator 14, surfactant F1, polymerization inhibitor P1, and solvent S1 described above

Moisture resistance and heat resistance were evaluated by the same method as in Example 1. The results are shown in the table below.

TABLE 18

| | Evaluation | |
|---|---|---|
| | Moisture | Heat |
| | resistance | resistance |
| Example 201 | 4 | 4 |
| Example 202 | 4 | 4 |
| Example 203 | 5 | 4 |
| Example 204 | 4 | 5 |
| Example 205 | 4 | 5 |
| Example 206 | 5 | 5 |
| Example 207 | 5 | 5 |
| Example 208 | 4 | 5 |
| Example 209 | 4 | 5 |
| Example 210 | 4 | 5 |
| Example 211 | 4 | 4 |
| Example 212 | 4 | 4 |
| Example 213 | 5 | 4 |
| Example 214 | 4 | 5 |
| Example 215 | 4 | 5 |
| Example 216 | 5 | 5 |
| Example 217 | 5 | 5 |
| Example 218 | 4 | 5 |
| Example 219 | 4 | 5 |
| Example 220 | 4 | 5 |

As shown in the table, by using the coloring compositions of Examples, a cured film having excellent moisture resistance and heat resistance could be produced.

### Test Example

<Preparation of Composition for forming Partition Wall>

(Compositions A to C)

After mixing the raw materials described in the following table, filtration was performed using DFA4201NIEY (0.45 μm nylon filter) manufactured by Nihon Pall Corporation to prepare compositions A to C.

TABLE 19

| | | Particle | | Solvent | | | |
|---|---|---|---|---|---|---|---|
| | | liquid | Surfactant | Solvent A1 | Solvent A2 | Solvent A3 | |
| Composition | Type | P1 | F1 | A1-1 | A2-1 | A3-1 | A3-2 |
| A | Formulation | 10 | 0.02 | 75 | 8 | 4 | 3 |
| | amount | | | | | | |
| | (part by mass) | | | | | | |
| Composition | Type | P1 | F1 | A1-1 | A2-2 | A3-1 | A3-2 |
| B | Formulation | 10 | 0.02 | 75 | 8 | 4 | 3 |
| | amount | | | | | | |
| | (part by mass) | | | | | | |
| Composition | Type | P1 | F1 | A1-1 | A2-3 | A3-1 | A3-2 |
| C | Formulation | 10 | 0.02 | 75 | 8 | 4 | 3 |
| | amount | | | | | | |
| | (part by mass) | | | | | | |

(Particle Liquid)

P1: beaded colloidal silica particle liquid (solution of silica particles in which a plurality of spherical silica particles are bonded by a bonding portion such as metal oxide-containing silica); the number of formulation amount is a solid content of SiO₂ in the beaded colloidal silica particle liquid.

(Surfactant)

F1: surfactant F1 described above

(Solvent)

A1-: PGMEA

A2-1: 1,4-butanediol diacetate

A2-2: 1,6-hexanediol diacetate

A2-3: propylene carbonate

A3-1: ethanol, methanol, or a mixture thereof

A3-2: water

<Production of Solid-State Imaging Element>

Using any of the above-described compositions A to C, a partition wall was formed on the silicon wafer as shown in FIG. 1 of JP2017-028241A.

The silicon wafer on which the partition wall is formed was coated with a Green composition using a spin coating method so that the thickness of a film after post-baking was 1.0 m. Next, the coating film was heated using a hot plate at 100° C. for 2 minutes. Next, using an i-ray stepper exposure device FPA-3000 i5+ (manufactured by Canon Inc.), exposure was performed with light having a wavelength of 365 nm at an exposure dose of 1000 mJ/cm² through a mask having a dot pattern of 2 m square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the Green composition was patterned by heating (post-baking) at 200° C. for 5 minutes using a hot plate. Likewise, a Red composition and a Blue composition were sequentially patterned to form red, green, and blue-colored patterns

(Bayer Pattern).

As the Red composition, the coloring composition of Example 1 was used. The Green composition and the Blue composition will be described later.

The Bayer pattern refers to a pattern, as disclosed in the specification of U.S. Pat. No. 3,971,065A, in which a 2×2 array of color filter element having one Red element, two Green elements, and one Blue element is repeated.

The obtained color filter was incorporated into a solid-state imaging element according to a known method. The solid-state imaging element had a suitable image recognition ability. In addition, the solid-state imaging element had excellent image recognition ability compared to a case where the partition wall was not provided.

Regarding the composition A, even in a case where the partition wall is formed by using a composition for forming a partition wall, which is prepared by replacing the solvent A2 with cyclohexanol acetate, dipropylene glycol dimethyl ether, propylene glycol diacetate, dipropylene glycol methyl-n-propyl ether, dipropylene glycol methyl ether acetate, 1,3-butylene glycol diacetate, 3-methoxybutyl acetate, ethylene glycol monobutyl ether acetate, diethylene glycol monoethyl ether acetate, diethylene glycol monobutyl ether acetate, triacetin, 3-methoxybutanol, diethylene glycol monoethyl ether, or n-propyl alcohol, the same effects were obtained.

The Green composition and the Blue composition are as follows.

(Green Composition)

The following components were mixed and stirred, and the obtained mixture was filtered through a nylon filter (manufactured by Nihon Pall Corporation) having a pore size of 0.45 μm to prepare a Green composition.

Green pigment dispersion liquid . . . 73.7 parts by mass

Resin 101 . . . 0.3 parts by mass

Polymerizable compound 101 . . . 1.2 parts by mass

Photopolymerization initiator 101 . . . 0.6 parts by mass

Surfactant 101 . . . 4.2 parts by mass

PGMEA . . . 19.5 parts by mass

(Blue Composition)

The following components were mixed and stirred, and the obtained mixture was filtered through a nylon filter (manufactured by Nihon Pall Corporation) having a pore size of 0.45 μm to prepare a Blue composition.

Blue pigment dispersion liquid . . . 44.9 parts by mass

Resin 101 . . . 2.1 parts by mass

Polymerizable compound 101 . . . 1.5 parts by mass

Polymerizable compound 102 . . . 0.7 parts by mass

Photopolymerization initiator 101 . . . 0.8 parts by mass

Surfactant 101 . . . 4.2 parts by mass

PGMEA 45.8 parts by mass

The raw materials used for the Green composition and the Blue composition are as follows.

Green Pigment Dispersion Liquid

6.4 parts by mass of C. I. Pigment Green 36, 5.3 parts by mass of C. I. Pigment Yellow 150, 5.2 parts by mass of a dispersant (Disperbyk-161, manufactured by BYK Chemie), 83.1 parts by mass of PGMEA were mixed with each other to obtain a mixed solution, and the mixed solution was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times. As a result, a Green pigment dispersion liquid was obtained.

Blue Pigment Dispersion Liquid

9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times. As a result, a Blue pigment dispersion liquid was obtained.

Polymerizable compound 101: KAYARAD DPHA (manufactured by Nippon Kayaku Co., Ltd.)

Polymerizable compound 102: compound having the following structure

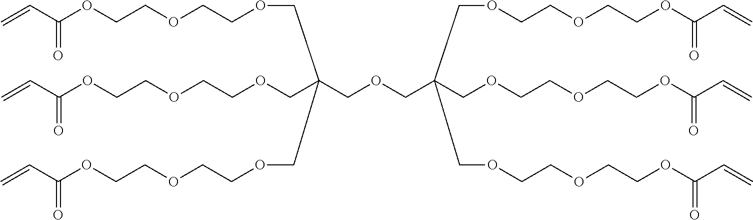 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 101: resin having the following structure (acid value: 70 mgKOH/g, Mw=11000; a ratio in a structural unit is a molar ratio)

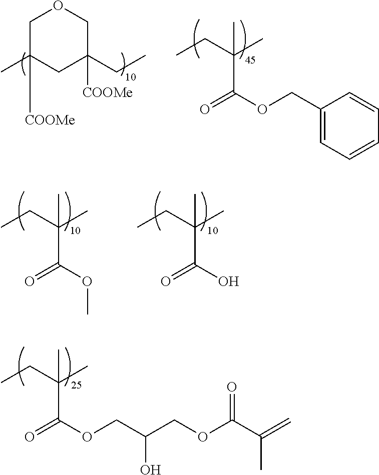

Photopolymerization Initiator 101: IRGACURE-OXE 01 (manufactured by BASF)

Surfactant 101: 1 mass % PGMEA solution of the following mixture (Mw=14000; in the following formula, “%” representing the proportion of a repeating unit is mass %)

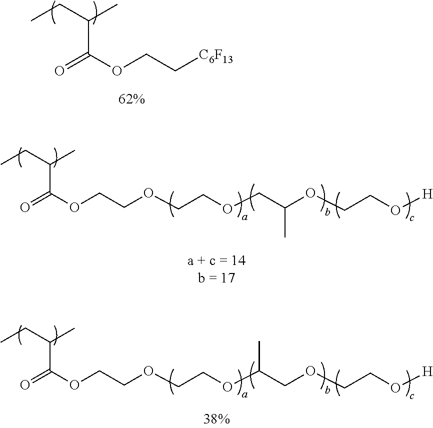

What is claimed is:

1. A coloring composition comprising:
a pigment A having a structure in which an aromatic ring group in which an electron-donating group is introduced into an aromatic ring is bonded to a diketopyrrolopyrrole skeleton; and
a compound having a curable group,
wherein a content of the pigment A in a total solid content of the coloring composition is 35 mass % or more.

2. The coloring composition according to claim 1,
wherein the electron-donating group is at least one selected from a hydroxy group, an alkyl group, an alkoxy group, an alkylthio group, an aryloxy group, or an amino group.

3. The coloring composition according to claim 1,
wherein the aromatic ring group is a group represented by Formula (AR-1), 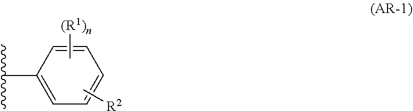
in the formula, R¹ represents a substituent,
R² represents an electron-donating group,
n represents an integer of 0 to 4, and
a wave line represents a bonding site to the diketopyrrolopyrrole skeleton.

4. The coloring composition according to claim 1,
wherein the pigment A is a compound represented by Formula (1), 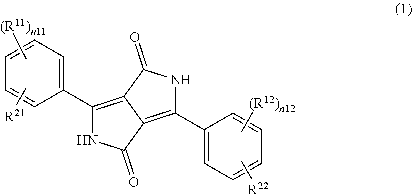
in the formula, R¹¹ and R¹² each independently represent a substituent,
R²¹ and R²² each independently represent an electron-donating group, and
n11 and n12 each independently represent an integer of 0 to 4.

5. The coloring composition according to claim 1,
wherein the pigment A is a compound represented by Formula (2), 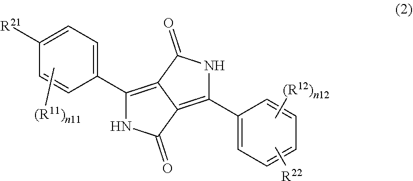
in the formula, R¹¹ and R¹² each independently represent a substituent,
R²¹ and R²² each independently represent an electron-donating group, and
n11 and n12 each independently represent an integer of 0 to 4.

6. The coloring composition according to claim 1,
wherein the pigment A includes Color Index Pigment Red 272.

7. The coloring composition according to claim 1, further comprising:
a yellow colorant selected from an isoindoline compound, an azo compound, and a quinophthalone compound.

8. The coloring composition according to claim 7,
wherein the yellow colorant is at least one selected from Color Index Pigment Yellow 139 or Color Index Pigment Yellow 150.

9. The coloring composition according to claim 1,
wherein the compound having a curable group includes at least one compound selected from a compound having an ethylenically unsaturated group or a compound having an epoxy group.

10. The coloring composition according to claim 1,
wherein the compound having a curable group includes a resin having an ethylenically unsaturated group.

11. The coloring composition according to claim 1, further comprising:
a photopolymerization initiator,
wherein the compound having a curable group includes a compound having an ethylenically unsaturated group.

12. The coloring composition according to claim 1, further comprising:
a monomer having an ethylenically unsaturated group; and
a resin,
wherein a ratio M¹/B¹ of a mass M¹ of the monomer having an ethylenically unsaturated group included in the coloring composition to a mass B¹ of the resin included in the coloring composition is 0.35 or less.

13. The coloring composition according to claim 1,
wherein the content of the pigment A in the total solid content of the coloring composition is 40 mass % or more.

14. A cured film which is formed from the coloring composition according to claim 1.

15. A method for forming a pattern, comprising:
forming a coloring composition layer on a support using the coloring composition according to claim 1; and
forming a pattern on the coloring composition layer by a photolithography method or a dry etching method.

16. A color filter comprising:
the cured film according to claim 14.

17. A solid-state imaging element comprising:
the cured film according to claim 14.

18. An image display device comprising:
the cured film according to claim 14.
